(19) United States
(12) Patent Application Publication
(10) Pub. No.: US 2022/0416208 A1
(43) Pub. Date: Dec. 29, 2022

(54) ORGANIC EL ELEMENT DISPLAY DEVICE, AND ELECTRONIC APPARATUS

(71) Applicant: IDEMITSU KOSAN CO.,LTD., Chiyoda-ku, Tokyo (JP)

(72) Inventors: Emiko KAMBE, Sodegaura-shi (JP); Shota SAWANO, Sodegaura-shi (JP); Masato NAKAMURA, Sodegaura-shi (JP); Masatoshi SAITO, Sodegaura-shi (JP)

(73) Assignee: IDEMITSU KOSAN CO.,LTD., Chiyoda-ku, Tokyo (JP)

(21) Appl. No.: 17/620,171

(22) PCT Filed: Jun. 17, 2020
(86) PCT No.: PCT/JP2020/023740

§ 371 Date: Dec. 17, 2021

(30) Foreign Application Priority Data
Jun. 18, 2019 (JP) 2019-112910

(51) Int. Cl. H01L 51/52; H01L 27/32

(52) U.S. Cl. CPC H01L 51/5265; H01L 27/3211; H01L 51/5218; H01L 51/5234; H01L 27/3244; H01L 51/56

(57) ABSTRACT

An organic-EL-display device includes a blue-emitting-organic-EL-device and a red-emitting-organic-EL-device as pixels, in which each of the blue-emitting-organic and the red-emitting-organic-EL-device includes a light-reflection layer, transparent electrode, hole transporting zone, emitting layer, electron transporting zone and semitransmissive electrode in this order, the blue-emitting-organic-EL-device has a blue-emitting layer containing a fluorescent-compound FLB, the red-emitting-organic-EL-device has a red-emitting layer containing a delayed fluorescent compound DFR, the hole transporting zone is provided at a constant film-thickness in a shared manner across the blue-emitting and red-emitting organic EL devices, the red-emitting-organic-EL-device has a resonator structure whose order of interference is first-order between the light reflection layer and the semitransmissive electrode, a film-thickness of the red-emitting layer is less than 50 nm, and a sum of film-thicknesses of the transparent electrode and hole transporting zone in the blue-emitting and red-emitting organic EL devices is less than 40 nm.

### TECHNICAL FIELD

The present invention relates to an organic EL display device and an electronic device.

### BACKGROUND ART

An organic electroluminescence device (hereinafter, sometimes referred to as an organic EL device) includes an emitting layer between an anode and a cathode, where holes are injected from the anode and electrons are injected from the cathode into the emitting layer and the holes and the electrons are recombined to emit light.

An organic EL display device includes an organic EL device as a pixel. The organic EL device serving as the pixel has an emitting layer configured to emit light in a color according to an emission color.

For instance, Patent Literature 1 discloses an organic EL display device including a red-emitting organic EL device, a green-emitting organic EL device, and a blue-emitting organic EL device as pixels.

In the organic EL display device disclosed in Patent Literature 1, an emitting layer of the green-emitting organic EL device contains a delayed fluorescent material.

A fluorescent organic EL device using thermally activated delayed fluorescence (hereinafter, sometimes simply referred to as “delayed fluorescence”) has been proposed and studied.

For instance, a TADF (Thermally Activated Delayed Fluorescence) mechanism has been studied. The TADF mechanism uses such a phenomenon that inverse intersystem crossing from triplet excitons to singlet excitons thermally occurs when a material having a small energy difference (ΔST) between singlet energy level and triplet energy level is used. Thermally activated delayed fluorescence is explained in “Yuki Hando-tai no Debaisu Bussei (Device Physics of Organic Semiconductors)” (edited by ADACHI, Chihaya, published by Kodansha, issued on Apr. 1, 2012, on pages 261-268).

### CITATION LIST

### Patent Literature(s)

Patent Literature 1: JP 2010-114428 A

### SUMMARY OF THE INVENTION

### Problems to be Solved by the Invention

An organic EL device using a TADF mechanism emits light through a different mechanism from that of a typical fluorescent organic EL device. Accordingly, an organic EL display device installed with an organic EL device containing a TADF material is designed in consideration of a TADF mechanism.

An object of the invention is to provide a high-performance organic EL display device, for instance, an organic EL display device having a favorable light extraction efficiency and/or a small angular dependency of an emission color without lowering production efficiency, and to provide an electronic device including the organic EL display device.

### Means for Solving the Problems

An aspect of the invention provides an organic EL display device including: a blue-emitting organic EL device and a red-emitting organic EL device as pixels, in which each of the blue-emitting organic EL device and the red-emitting organic EL device includes in this order a light reflection layer, a transparent electrode, a hole transporting zone, an emitting layer, an electron transporting zone, and a semitransmissive electrode,

in each of the blue-emitting organic EL device and the red-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device includes a blue emitting layer as the emitting layer,

the red-emitting organic EL device includes a red emitting layer as the emitting layer,

the blue emitting layer contains a fluorescent compound FL_{B} or a phosphorescent compound PL_{B},

the red emitting layer contains a delayed fluorescent compound DF_{R},

the hole transporting zone is provided at a constant film thickness in a shared manner across the blue-emitting organic EL device and the red-emitting organic EL device,

the red-emitting organic EL device has a resonator structure whose order of interference is first-order between the light reflection layer and the semitransmissive electrode,

a film thickness of the red emitting layer is less than 50 nm, and

a sum of a film thickness of the transparent electrode and a film thickness of the hole transporting zone in each of the blue-emitting organic EL device and the red-emitting organic EL device is less than 40 nm.

Another aspect of the invention provides an organic EL display device including: a blue-emitting organic EL device and a red-emitting organic EL device as pixels, in which each of the blue-emitting organic EL device and the red-emitting organic EL device includes in this order a light reflection layer, a transparent electrode, a hole transporting zone, an emitting layer, an electron transporting zone, and a semitransmissive electrode,

in each of the blue-emitting organic EL device and the red-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device comprises a blue emitting layer as the emitting layer,

the red-emitting organic EL device includes a red emitting layer as the emitting layer,

the blue emitting layer contains a fluorescent compound FL_{B},

the red emitting layer contains a delayed fluorescent compound DF_{R},

the hole transporting zone is provided at a constant film thickness in a shared manner across the blue-emitting organic EL device and the red-emitting organic EL device,

the red-emitting organic EL device has a resonator structure whose order of interference is first-order between the light reflection layer and the semitransmissive electrode,

a film thickness of the red emitting layer is less than 50 nm, and

a sum of a film thickness of the transparent electrode and a film thickness of the hole transporting zone in each of the blue-emitting organic EL device and the red-emitting organic EL device is less than 40 nm.

Still another aspect of the invention provides an organic EL display device including: a blue-emitting organic EL device, a green-emitting organic EL device, and a red-emitting organic EL device as pixels, in which each of the blue-emitting organic EL device, the green-emitting organic EL device, and the red-emitting organic EL device includes in this order a light reflection layer, a transparent electrode, a hole transporting zone, an emitting layer, an electron transporting zone, and a semitransmissive electrode,

in each of the blue-emitting organic EL device, the green-emitting organic EL device, and the red-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device includes a blue emitting layer as the emitting layer,

the green-emitting organic EL device includes a green emitting layer as the emitting layer,

the red-emitting organic EL device includes a red emitting layer as the emitting layer,

the blue emitting layer contains a fluorescent compound FL_{B} or a phosphorescent compound PL_{B},

the red emitting layer contains a delayed fluorescent compound DF_{R},

the hole transporting zone is provided at a constant film thickness in a shared manner across the blue-emitting organic EL device, the green-emitting organic EL device, and the red-emitting organic EL device,

the red-emitting organic EL device has a resonator structure whose order of interference is first-order between the light reflection layer and the semitransmissive electrode,

a film thickness of the red emitting layer is less than 50 nm, and

a sum of a film thickness of the transparent electrode and a film thickness of the hole transporting zone in each of the blue-emitting organic EL device, the green-emitting organic EL device, and the red-emitting organic EL device is less than 40 nm.

A further aspect of the invention provides an organic EL display device including: a blue-emitting organic EL device, a green-emitting organic EL device, and a red-emitting organic EL device as pixels, in which each of the blue-emitting organic EL device, the green-emitting organic EL device, and the red-emitting organic EL device includes in this order a light reflection layer, a transparent electrode, a hole transporting zone, an emitting layer, an electron transporting zone, and a semitransmissive electrode,

in each of the blue-emitting organic EL device, the green-emitting organic EL device, and the red-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device includes a blue emitting layer as the emitting layer,

the green-emitting organic EL device includes a green emitting layer as the emitting layer,

the red-emitting organic EL device includes a red emitting layer as the emitting layer,

the blue emitting layer comprises a fluorescent compound FL_{B},

the red emitting layer contains a delayed fluorescent compound DF_{R},

the hole transporting zone is provided at a constant film thickness in a shared manner across the blue-emitting organic EL device, the green-emitting organic EL device, and the red-emitting organic EL device,

the red-emitting organic EL device has a resonator structure whose order of interference is first-order between the light reflection layer and the semitransmissive electrode,

a film thickness of the red emitting layer is less than 50 nm, and

a sum of a film thickness of the transparent electrode and a film thickness of the hole transporting zone in each of the blue-emitting organic EL device, the green-emitting organic EL device, and the red-emitting organic EL device is less than 40 nm.

A still further aspect of the invention provides an organic EL display device including: a blue-emitting organic EL device and a green-emitting organic EL device as pixels, in which each of the blue-emitting organic EL device and the green-emitting organic EL device includes in this order a light reflection layer, a transparent electrode, a hole transporting zone, an emitting layer, an electron transporting zone, and a semitransmissive electrode,

in each of the blue-emitting organic EL device and the green-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device includes a blue emitting layer as the emitting layer,

the green-emitting organic EL device includes a green emitting layer as the emitting layer,

the blue emitting layer contains a fluorescent compound FL_{B} or a phosphorescent compound PL_{B},

the green emitting layer contains a delayed fluorescent compound DF_{G},

the hole transporting zone is provided at a constant film thickness in a shared manner across the blue-emitting organic EL device and the green-emitting organic EL device,

the green-emitting organic EL device comprises a resonator structure whose order of interference is first-order between the light reflection layer and the semitransmissive electrode,

a film thickness of the green emitting layer is less than 40 nm, and

a sum of a film thickness of the transparent electrode and a film thickness of the hole transporting zone in each of the blue-emitting organic EL device and the green-emitting organic EL device is less than 40 nm.

A still further aspect of the invention provides an organic EL display device including: a blue-emitting organic EL device and a green-emitting organic EL device as pixels, in which

each of the blue-emitting organic EL device and the green-emitting organic EL device includes in this order a light reflection layer, a transparent electrode, a hole transporting zone, an emitting layer, an electron transporting zone, and a semitransmissive electrode,

in each of the blue-emitting organic EL device and the green-emitting organic EL device,

the light reflection layer is in direct contact with the transparent electrode,

the transparent electrode is in direct contact with the hole transporting zone,

the hole transporting zone is in direct contact with the emitting layer,

the emitting layer is in direct contact with the electron transporting zone,

the electron transporting zone is in direct contact with the semitransmissive electrode,

the blue-emitting organic EL device includes a blue emitting layer as the emitting layer,

the green-emitting organic EL device includes a green emitting layer as the emitting layer,

the blue emitting layer comprises a fluorescent compound FL_{B},

the green emitting layer comprises a delayed fluorescent compound DF_{G},

the hole transporting zone is provided at a constant film thickness in a shared manner across the blue-emitting organic EL device and the green-emitting organic EL device,

the green-emitting organic EL device comprises a resonator structure whose order of interference is first-order between the light reflection layer and the semitransmissive electrode,

a film thickness of the green emitting layer is less than 40 nm, and

a sum of a film thickness of the transparent electrode and a film thickness of the hole transporting zone in each of the blue-emitting organic EL device and the green-emitting organic EL device is less than 40 nm.

A still further aspect of the invention provides an electronic device including the organic electroluminescence device according to any one of the above aspects of the invention.

According to any one of the above aspects of the invention, a high-performance organic EL display device can be provided. According to any one of the above aspects of the invention, an electronic device including the organic electroluminescence device can be provided.

### BRIEF EXPLANATION OF DRAWINGS

FIG. 1 schematically shows an exemplary structure of an organic EL display device according to a first exemplary embodiment.

FIG. 2 schematically shows a device of measuring transient PL.

FIG. 3 shows an example of a decay curve of the transient PL.

FIG. 4 shows a relationship between energy levels and energy transfer of a delayed fluorescent compound and a fluorescent compound in a red emitting layer.

FIG. 5 schematically shows an exemplary arrangement of an organic EL display device according to a second exemplary embodiment.

FIG. 6 shows a relationship between energy levels and energy transfer of a delayed fluorescent compound and a fluorescent compound in a green emitting layer.

FIG. 7 schematically shows an exemplary arrangement of an organic EL display device according to a third exemplary embodiment.

FIG. 8 shows a relationship between energy levels and energy transfer of a delayed fluorescent compound, a fluorescent compound, and a compound as a third component in a red emitting layer in an organic EL display device according to a fourth exemplary embodiment.

FIG. 9 shows a relationship between energy levels and energy transfer of a delayed fluorescent compound, a fluorescent compound, and a compound as a third component in a green emitting layer in an organic EL display device according to a fifth exemplary embodiment.

### DESCRIPTION OF EMBODIMENT(S)

### First Exemplary Embodiment

### Organic EL Display Device

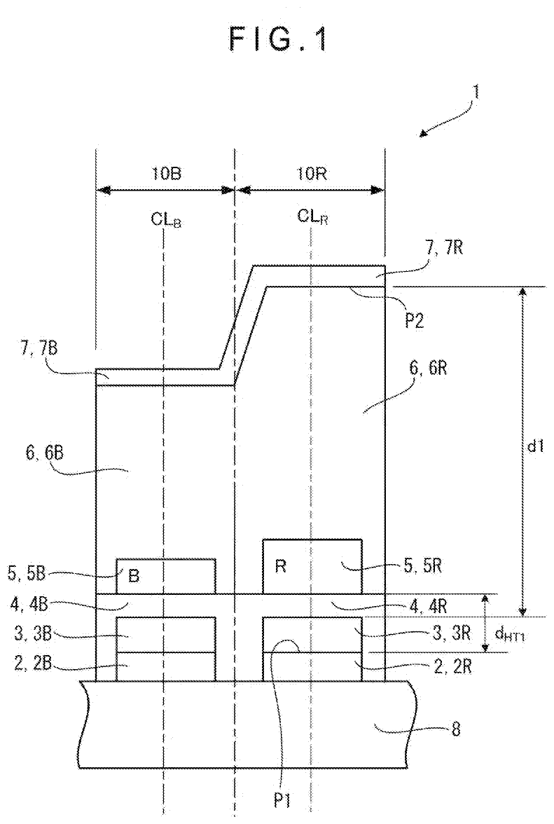

An exemplary arrangement of an organic EL display device according to a first exemplary embodiment will be described with reference to FIG. 1.

FIG. 1 shows an organic EL display device 1.

The organic EL display device 1 includes a blue-emitting organic EL device 10B and a red-emitting organic EL device 10R as pixels.

Each of the blue-emitting organic EL device 10B and the red-emitting organic EL device 10R includes a light reflection layer 2, a transparent electrode 3, a hole transporting zone 4, an emitting layer 5, an electron transporting zone 6, and a semitransmissive electrode 7. The hole transporting zone 4, the emitting layer 5 and the electron transporting zone 6 are herein sometimes referred to as an organic layer.

Each of the blue-emitting organic EL device 10B and the red-emitting organic EL device 10R includes the light reflection layer 2, the transparent electrode 3, the hole transporting zone 4, the emitting layer 5, the electron transporting zone 6, and the semitransmissive electrode 7 in this order. In the organic EL display device 1, the blue-emitting organic EL device 10B and the red-emitting organic EL device 10R as pixels are disposed in parallel on a substrate 8.

In each of the blue-emitting organic EL device 10B and the red-emitting organic EL device 10R, the transparent electrode 3 is in direct contact with the hole transporting zone 4, the hole transporting zone 4 is in direct contact with the emitting layer 5, the emitting layer 5 is in direct contact with the electron transporting zone 6, and the electron transporting zone 6 is in direct contact with the semitransmissive electrode 7.

The organic EL display device 1 includes the blue-emitting organic EL device 10B as a blue pixel and the red-emitting organic EL device 10R as a red pixel. A voltage is applied to each pixel independently. In the organic EL display device 1, the blue pixel and the red pixel can be selectively made emit light. The organic EL display device 1 may have a plurality of units each consisting of one blue pixel and one red pixel. In this case, the plurality of units each consisting of one blue pixel and one red pixel may be repeatedly arranged on the substrate. Moreover, each pixel in each unit may be plural. For example, one blue pixel and two red pixels may form one unit. It should be noted that the organic EL display device of the exemplary embodiment may have a pixel emittable in a color other than the blue pixel and the red pixel.

### Red-Emitting Organic EL Device

The red-emitting organic EL device 10R includes a red emitting layer 5R as the emitting layer 5. In FIG. 1, the red emitting layer 5R is denoted by R.

The red-emitting organic EL device 10R includes a light reflection layer 2R, a transparent electrode 3R, a hole transporting zone 4R, a red emitting layer 5R, an electron transporting zone 6R, and a semitransmissive electrode 7R respectively corresponding to the light reflection layer 2, the transparent electrode 3, the hole transporting zone 4, the emitting layer 5, the electron transporting zone 6, and the semitransmissive electrode 7.

The red emitting layer 5R is interposed between the hole transporting zone 4R and the electron transporting zone 6R.

The red emitting layer 5R is in direct contact with the hole transporting zone 4R and further also in direct contact with the electron transporting zone 6R.

A film thickness of the red emitting layer 5R is less than 50 nm. The film thickness of the red emitting layer 5R is preferably 15 nm or more.

The film thickness of the red emitting layer 5R is larger than that of the blue emitting layer 5B.

### Measurement Method of Film Thickness of Layer or Zone

A film thickness of each of the layers or the zones contained in the organic EL device can be measured as follows.

A central portion of an organic EL device having a layer or a zone (i.e., measurement target) is cut in a perpendicular direction (i.e., a thickness direction of an organic layer) to a plane where the layer or the zone of the measurement target is formed. The cut surface of the central portion is observed with a transmission electron microscope (TEM) to measure a film thickness of the layer or the zone.

For instance, when measuring a film thickness of the red emitting layer 5R of the red-emitting organic EL device 10R, a central portion of the red-emitting organic EL device 10R having a layer or a zone (i.e., measurement target) is cut in a perpendicular direction (i.e., a thickness direction of the red emitting layer 5R) to a plane where the layer or the zone of the red emitting layer 5R is formed. The cut surface of the central portion is observed with a transmission electron microscope (TEM) to measure a film thickness of the red emitting layer 5R. In FIG. 1, the central portion of the red-emitting organic EL device 10R is represented by CL_{R} and a central portion of the blue-emitting organic EL device 10B is represented by CL_{B}.

It should be noted that the central portion of the organic EL device means a central portion of a shape of the organic EL device of each pixel projected through a semitransmissive electrode. When the projected shape is rectangular, the central portion of the organic EL device means an intersection of the diagonal lines of the rectangle.

Herein, when a target zone or layer includes a plurality of layers, a thickness means a sum of thicknesses of the plurality of layers.

In the organic EL display device 1 according to the exemplary embodiment, the red-emitting organic EL device 10R has a resonator structure whose order of interference is first-order between the light reflection layer 2 and the semitransmissive electrode 7. Specifically, the red-emitting organic EL device 10R has a resonator structure whose order of interference is first-order between the light reflection layer 2R and the semitransmissive electrode 7R. A distance d1 between the light reflection layer 2R and the semitransmissive electrode 7R in the red-emitting organic EL device 10R corresponds to a sum of a thickness of the hole transporting zone 4R, a thickness of the red emitting layer 5R, and a thickness of the electron transporting zone 6R.

### Resonator Structure

The resonator structure of the organic EL device will be described below.

The organic EL device of the organic EL display device 1 has a resonator structure in which emitted light is resonated between the light reflection layer 2 and the semitransmissive electrode 7 to be extracted, whereby color purity of the extracted light can be improved, and intensity of the extracted light near a central wavelength of resonance can be improved.

In a resonator structure that a reflective end surface of the light reflection layer 2 close to the emitting layer 5 is defined as a first end P1, a reflective end surface of the semitransmissive electrode 7 close to the emitting layer 5 is defined as a second end P2, and the organic layer (the hole transporting zone 4, emitting layer 5, and the electron transporting zone 6) is defined as a resonance portion, and light generated in the emitting layer 5 is resonated and extracted from the second end P2, an optical distance L between the first end P1 and the second end P2 of the resonator is set so as to satisfy the following numerical formula (OP1). It is preferable that the optical distance L is actually selected so as to be a positive minimum value that satisfies the numerical formula (OP1).

$$\begin{matrix}[ Numerical Formula 1 ] & \\ \frac{2 L ,}{λ} + \frac{Φ}{2 π} = m & ( OP1 )\end{matrix}$$

Symbols in the numerical formula (OP1) are described as follows.

L represents the optical distance between the first end P1 and the second end P2.

Φ represents a sum (Φ=Φ1+Φ2) of phase shift Φ1 of reflected light generated on the first end P1 and phase shift Φ2 of reflected light generated on the second end P2. A unit of the phase shift is rad.

λ represents a peak wavelength of a spectrum of light extracted from the second end P2.

M represents an integer to make L positive. m corresponds to the order of interference. When m is 1, the organic EL device has a resonator structure whose order of interference is first-order.

In the numerical formula (OP1), L and A only need to be represented by a common unit. The unit of L and λ is, for instance, nm.

The optical distance L is a total sum (=n₁d1+n₂d2+ . . . ) of optical film thicknesses (=refractive index (n)×film thickness (d)) of the organic layer between the light reflection layer 2 and the semitransmissive electrode 7. It should be noted that, when the emitted light actually reflects at the light reflection layer 2 and the semitransmissive electrode 7, the sum Φ of the phase shifts changes depending on a combination of electrode materials and organic materials of which reflective interfaces are formed.

In the organic EL display device 1, it is preferable that an optical distance L₁ between the maximum emission position of the emitting layer 5 and the first end P1 satisfies a numerical formula (OP2) and an optical distance L₂ between the maximum emission position and the second end P2 satisfies a numerical formula (OP3). Herein, the maximum emission position refers to a position where the luminous intensity is the largest in an emitting region. For instance, when the emitting layer 5 emits light on both the interface close to the light reflection layer 2 and the interface close to the semitransmissive electrode 7, the maximum emission position is defined by the interface having the larger luminous intensity between the interfaces.

$$\begin{matrix}[ Numerical Formula 2 ] & \\ \begin{matrix}{L}_{1} = t \\ \frac{2 t {L}_{1}}{λ} =\end{matrix} \begin{matrix}{L}_{1} + {a}_{1} \\ - \frac{{Φ}_{1}}{2 π} + {m}_{1}\end{matrix} & ( OP2 )\end{matrix}$$

Symbols in the numerical formula (OP2) are described as follows.

tL₁ represents an optical theoretical distance between the first end P1 and the maximum emission position.

a₁ represents a correction amount based on an emission distribution in the emitting layer 5.

λ represents a peak wavelength of a spectrum of light to be extracted.

Φ₁ represents a phase shift of reflected light generated on the first end P1. A unit of Φ₁ is rad.

m₁ is 0 or an integer. In the organic EL display device 1, m₁ is 0. A position of the optical distance L₁ when m₁ is 0 corresponds to “zero-order interference position” viewed from the light reflection layer 2.

$$\begin{matrix}[ Numerical Formula 3 ] & \\ \begin{matrix}{L}_{2} = t \\ \frac{2 t {L}_{2}}{λ} =\end{matrix} \begin{matrix}{L}_{2} + {a}_{2} \\ - \frac{{Φ}_{2}}{2 π} + {m}_{2}\end{matrix} & ( OP3 )\end{matrix}$$

Symbols in the numerical formula (OP3) are described as follows.

tL₂ represents an optical theoretical distance between the second end P2 and the maximum emission position.

a₂ represents a correction amount based on the emission distribution in the emitting layer 5.

λ represents a peak wavelength of a spectrum of light to be extracted.

Φ₂ represents a phase shift of reflected light generated on the second end P2. A unit of Φ₂ is rad.

m₂ is 0 or an integer. m₂ is preferably 1.

It is more preferable that m₁ is 0 and m₂ is 1. A position of the optical distance L₂ when m₂ is 1 corresponds to “first-order interference position” viewed from the semitransmissive electrode 7.

The numerical formula (OP2) represents conditions for realizing a relationship that, when a light toward the light reflection layer 2, which is among the light generated in the emitting layer 5, is reflected on the first end P1 to return, a phase of the return light and a phase at the time of emission become the same and therefore the return light and a light toward the semitransmissive electrode 7, which is among the light generated in the emitting layer 5, enhance each other.

The numerical formula (OP3) represents conditions for realizing a relationship that, when a light toward the semitransmissive electrode 7, which is among the light generated in the emitting layer 5, is reflected on the second end P2 to return, a phase of the return light and a phase at the time of emission become the same and therefore the return light and a light toward the light reflection layer 2, which is among the light generated in the emitting layer 5, enhance each other.

The organic EL display device 1 of the exemplary embodiment can be designed so that m₁ and m₂ in the numerical formulae (OP2) and (OP3) satisfy m₂>m₁ by forming the film thickness of the electron transporting zone 6 thicker than the film thickness of the hole transporting zone 4. By designing so that m₂>m₁, a viewing angle of the organic EL display device 1 can be improved.

The optical theoretical distance tL₁ in the numerical formula (OP2) and the optical theoretical distance tL₂ in the numerical formula (OP3) are theoretical values showing that, when the emission region is considered not to spread, an amount of phase change on the first end P1 or the second end P2 is offset by an amount of phase change due to light progress, so that the phase of the return light and the phase at the time of emission become the same. However, since the emission region usually spreads, the correction amounts a₁ and a₂ based on the emission distribution are added to the numerical formula (OP2) and numerical formula (OP3), respectively.

Although the correction amounts a₁ and a₂ differ depending the emission distribution, when the maximum emission position is on the interface of the emitting layer 5 close to the semitransmissive electrode 7 and the emission distribution spreads from the maximum emission position toward the light reflection layer 2, or when the maximum emission position is on the interface of the emitting layer 5 close to the light reflection layer 2 and the emission distribution spreads from the maximum emission position toward the semitransmissive electrode 7, the correction amounts a₁ and a₂ can be calculated by a numerical formula (OP4) below.

$$\begin{matrix}[ Numerical Formula 4 ] & \\ \begin{matrix}{a}_{1} = b ( l o {g}_{e} ( s ) ) \\ {a}_{2} = - {a}_{1}\end{matrix} & ( OP4 )\end{matrix}$$

Symbols in the numerical formula (OP4) are described as follows.

b is a value within a range of 2n≤b≤6n when the emission distribution in the emitting layer 5 spreads from the maximum emission position toward the light reflection layer 2. b is a value within a range of −6n≤b≤−2n when the emission distribution in the emitting layer 5 spreads from the maximum emission position toward the semitransmissive electrode 7.

s represents a physical property value (1/e decay distance) relating to the emission distribution in the emitting layer 5.

n is an average refractive index between the first end P1 and the second end P2 at the peak wavelength A of the spectrum of the light to be extracted.

The above description is of the resonator structure of the organic EL display device.

In the organic EL display device 1 according to the exemplary embodiment, the red-emitting organic EL device 10R has a resonator structure. In the description of the above resonator structure, as for the red-emitting organic EL device 10R having the resonator structure, the light reflection layer 2, the semitransmissive electrode 7, the hole transporting zone 4, the emitting layer 5, and the electron transporting zone 6 can be read as the light reflection layer 2R, the semitransmissive electrode 7R, the hole transporting zone 4R, the red emitting layer 5R, and the electron transporting zone 6R, respectively.

### Red-Emitting Layer

The red emitting layer 5R contains a delayed fluorescent compound DF_{R}.

In an exemplary embodiment, it is preferable that the red emitting layer 5R further contains a fluorescent compound FL_{R}. Herein, a “fluorescent compound” is a compound exhibiting no delayed fluorescence. Accordingly, the fluorescent compound FL_{R} is a compound exhibiting no delayed fluorescence.

When the red emitting layer 5R contains the delayed fluorescent compound DF_{R} and the fluorescent compound FL_{R}, the singlet energy S₁(DF_{R}) of the delayed fluorescent compound DF_{R} and the singlet energy S₁(FL_{R}) of the fluorescent compound FL_{R} preferably satisfy a relationship of Numerical Formula 1A.

S₁(DF_{R})>S₁(FL_{R}) (Numerical Formula 1A)

When the red emitting layer 5R contains the fluorescent compound FL_{R}, the compound FL_{R} is preferably a red fluorescent compound.

In the red emitting layer 5R, the fluorescent compound FL_{R} is preferably a dopant material (also referred to as a guest material, emitter or luminescent material), and the delayed fluorescent compound DF_{R} is preferably a host material (also referred to as a matrix material).

The red emitting layer 5R preferably does not contain a phosphorescent material.

The red emitting layer 5R preferably does not contain a heavy metal complex and a phosphorescent rare-earth metal complex. Examples of the heavy-metal complex herein include iridium complex, osmium complex, and platinum complex.

It is also preferable that the red emitting layer 5R does not contain a metal complex.

### Content Ratio of Compound in Red Emitting Layer

In the red emitting layer 5R of the exemplary embodiment, the content ratio of the fluorescent compound FL_{R} is preferably in a range from 0.01 mass % to 10 mass %, and the content ratio of the delayed fluorescent compound DF_{R} is preferably in a range from 80 mass % to 99.99 mass %. The upper limit of the total content ratios of the fluorescent compound FL_{R} and the delayed fluorescent compound DF_{R} in the red emitting layer 5R is 100 mass %. It should not be excluded that in the exemplary embodiment, the red emitting layer 5R contains a material other than the fluorescent compound FL_{R} and the delayed fluorescent compound DF_{R}.

The red emitting layer 5R may contain a single type of the fluorescent compound FL_{R} or may contain two or more types of the fluorescent compound FL_{R}. The red emitting layer 5R may contain a single type of the delayed fluorescent compound DF_{R} or may contain two or more types of the delayed fluorescent compound DF_{R}.

Herein, the red light emission refers to a light emission in which a main peak wavelength of fluorescence spectrum is in a range from 600 nm to 660 nm.

When the fluorescent compound FL_{R} is a red fluorescent compound, a main peak wavelength of the fluorescent compound FL_{R} is preferably in a range from 600 nm to 660 nm, more preferably in a range from 600 nm to 640 nm, further preferably in a range from 600 nm to 630 nm.

Herein, the main peak wavelength means a peak wavelength of an emission spectrum exhibiting a maximum luminous intensity among fluorescence spectra measured in a toluene solution in which a measurement target compound is dissolved at a concentration ranging from 10⁻⁶ mol/l to 10⁻⁵ mol/l. A spectrophotofluorometer (F-7000 manufactured by Hitachi High-Tech Science Corporation) is used as a measurement device.

### Delayed Fluorescence

Delayed fluorescence is explained in “Yuki Hando-tai no Debaisu Bussei (Device Physics of Organic Semiconductors)” (edited by ADACHI, Chihaya, published by Kodansha, on pages 261-268). This document describes that, if an energy gap ΔE₁₃ of a fluorescent material between a singlet state and a triplet state is reducible, a reverse energy transfer from the triplet state to the singlet state, which usually occurs at a low transition probability, would occur at a high efficiency to express thermally activated delayed fluorescence (TADF). Further, a mechanism of generating delayed fluorescence is explained in FIG. 10.38 in the document. The delayed fluorescent compound DF_{R} in the exemplary embodiment is preferably a compound exhibiting thermally activated delayed fluorescence generated in such a mechanism.

In general, emission of delayed fluorescence can be confirmed by measuring the transient PL (Photo Luminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton. Therefore, the luminous intensity derived from delayed fluorescence can be determined.

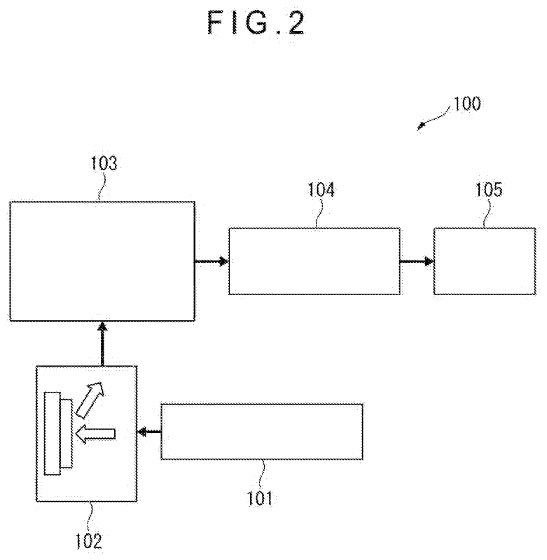

FIG. 2 shows a schematic diagram of an exemplary device for measuring the transient PL. An example of a method of measuring a transient PL using FIG. 2 and an example of behavior analysis of delayed fluorescence will be described.

A transient PL measuring device 100 in FIG. 2 includes: a pulse laser 101 capable of radiating a light having a predetermined wavelength; a sample chamber 102 configured to house a measurement sample; a spectrometer 103 configured to divide a light radiated from the measurement sample; a streak camera 104 configured to provide a two-dimensional image; and a personal computer 105 configured to import and analyze the two-dimensional image. A device for measuring the transient PL is not limited to the device described in the exemplary embodiment.

The sample to be housed in the sample chamber 102 is obtained by doping a matrix material with a doping material at a concentration of 12 mass % and forming a thin film on a quartz substrate.

The thin film sample housed in the sample chamber 102 is radiated with a pulse laser from the pulse laser 101 to excite the doping material. Emission is extracted in a direction of 90 degrees with respect to a radiation direction of the excited light. The extracted emission is divided by the spectrometer 103 to form a two-dimensional image in the streak camera 104. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

For instance, a thin film sample A was manufactured as described above from a reference compound H1 as the matrix material and a reference compound D1 as the doping material and was measured in terms of the transient PL.

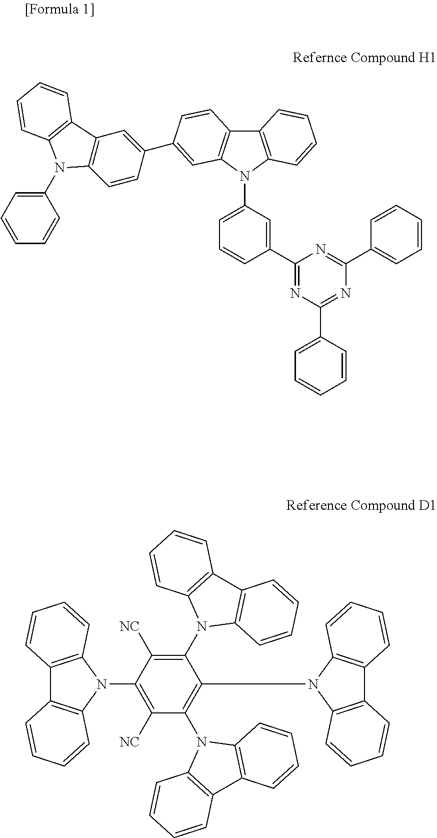 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

Herein, the decay curve was analyzed with respect to the above thin film sample A and a thin film sample B. The thin film sample B was manufactured in the same manner as described above from a reference compound H2 as the matrix material and the reference compound D1 as the doping material.

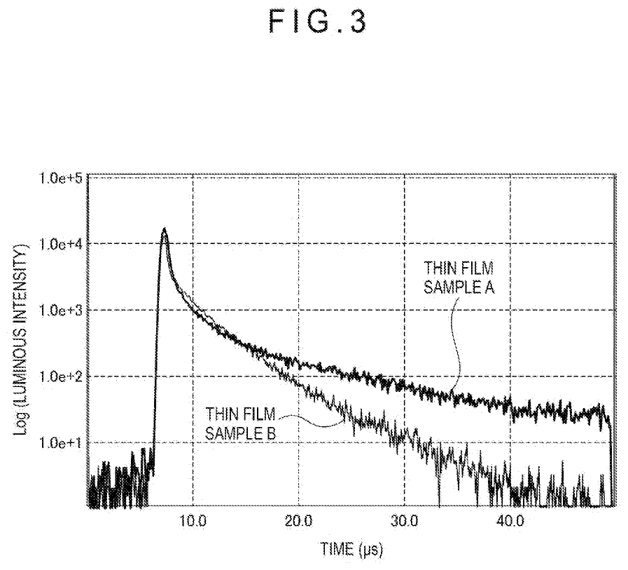

FIG. 3 shows decay curves obtained from transient PL obtained by measuring the thin film samples A and B.

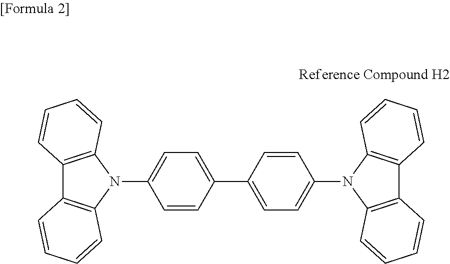 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by inverse energy transfer via a triplet state can be estimated. In a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using a device different from one described in Reference Document 1 or one shown in FIG. 2.

In the exemplary embodiment, a sample manufactured by a method shown below is used for measuring delayed fluorescence of the compound DF_{R}. For instance, the compound DF_{R} is dissolved in toluene to prepare a dilute solution with an absorbance of 0.05 or less at the excitation wavelength to eliminate the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (manufactured by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using a device different from one described in Reference Document 1 or one shown in FIG. 2.

In the exemplary embodiment, provided that an amount of Prompt emission of a measurement target compound (compound DF_{R}) is denoted by X_{P} and an amount of Delay emission is denoted by X_{D}, a value of X_{D}/X_{P} is preferably 0.05 or more.

The amounts of Prompt emission and Delay emission and a ratio of the amounts thereof in compounds other than the compound DF_{R} herein are measured in the same manner as those of the compound DF_{R}.

### TADF Mechanism

In the red-emitting organic EL device 10R of the exemplary embodiment, the compound DF_{R} is preferably a compound having a small ΔST(DF_{R}), so that inverse intersystem crossing from the triplet energy level of the compound DF_{R} to the singlet energy level thereof is easily caused by a heat energy given from the outside. An energy state conversion mechanism to perform spin exchange from the triplet state of electrically excited excitons within the organic EL device to the singlet state by inverse intersystem crossing is referred to as a TADF mechanism.

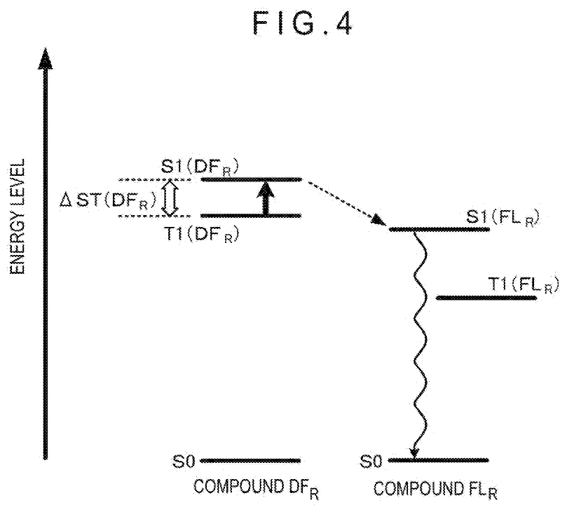

FIG. 4 shows an example of a relationship between energy levels of the compound DF_{R} and the compound FL_{R} in the red emitting layer 5R. Symbols in FIG. 4 are described as follows.

S0 represents a ground state.

S1(DF_{R}) represents the lowest singlet state of the compound DF_{R}.

T1(DF_{R}) represents the lowest triplet state of the compound DF_{R}.

S1(FL_{R}) represents the lowest singlet state of the compound FL_{R}.

T1(FL_{R}) represents the lowest triplet state of the compound FL_{R}.

A dashed arrow directed from S1(DF_{R}) to S1(FL_{R}) in FIG. 4 represents Förster energy transfer from the lowest singlet state of the compound DF_{R} to the lowest singlet state of the compound FL_{R}. In the exemplary embodiment, a difference between the lowest singlet state S1 and the lowest triplet state T1 is defined as ΔST. As shown in FIG. 4, when a compound having a small ΔST(DF_{R}) is used as the compound DF_{R}, inverse intersystem crossing from the lowest triplet state T1(DF_{R}) to the lowest singlet state S1(DF_{R}) can be caused by a heat energy. Subsequently, Förster energy transfer from the lowest singlet state S1(DF_{R}) of the compound DF_{R} to the compound FL_{R} occurs to generate the lowest singlet state S1(FL_{R}). Consequently, fluorescence from the lowest singlet state S1(FL_{R}) of the compound FL_{R} can be observed. It is inferred that the internal quantum efficiency can be theoretically raised up to 100% also by using delayed fluorescence by the TADF mechanism.

### Relationship Between Triplet Energy and Energy Gap at 77 [K]

Here, a relationship between a triplet energy and an energy gap at 77 [K] will be described. In the exemplary embodiment, the energy gap at 77 [K] is different from a typical triplet energy in some aspects.

The triplet energy is measured as follows. Firstly, a solution in which a compound (measurement target) is dissolved in an appropriate solvent is encapsulated in a quartz glass tube to prepare a sample. A phosphorescent spectrum (ordinate axis: phosphorescent luminous intensity, abscissa axis: wavelength) of the sample is measured at a low temperature (77 [K]). A tangent is drawn to the rise of the phosphorescent spectrum close to the short-wavelength region. The triplet energy is calculated by a predetermined conversion equation based on a wavelength value at an intersection of the tangent and the abscissa axis.

Here, the thermally activated delayed fluorescent compound among the compounds of the exemplary embodiment is preferably a compound having a small ΔST. When ΔST is small, intersystem crossing and inverse intersystem crossing are likely to occur even at a low temperature (77 K), so that the singlet state and the triplet state coexist. As a result, the spectrum to be measured in the same manner as the above includes emission from both the singlet state and the triplet state. Although it is difficult to distinguish the emission from the singlet state from the emission from the triplet state, the value of the triplet energy is basically considered dominant.

Accordingly, in the exemplary embodiment, the triplet energy is measured by the same method as a typical triplet energy T, but a value measured in the following manner is referred to as an energy gap T_{77K} in order to differentiate the measured energy from the typical triplet energy in a strict meaning. The measurement target compound is dissolved in EPA (diethylether:isopentane:ethanol=5:5:2 in volume ratio) at a concentration of 10 μmol/L, and the obtained solution is encapsulated in a quartz cell to provide a measurement sample. A phosphorescent spectrum (ordinate axis: phosphorescent luminous intensity, abscissa axis: wavelength) of the sample is measured at a low temperature (77 K). A tangent is drawn to the rise of the phosphorescent spectrum close to the short-wavelength region. An energy amount is calculated by a conversion equation below based on a wavelength value λ_{edge} [nm] at an intersection of the tangent and the abscissa axis and is defined as an energy gap T_{77K} at 77 K.

T_{77K} [eV]=1239.85/λedge Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any device for phosphorescence measurement is usable. A combination of a cooling unit, a low temperature container, an excitation light source and a light-receiving unit may be used for phosphorescence measurement.

### Lowest Singlet Energy S₁

A method of measuring the lowest singlet energy S₁ with use of a solution (occasionally referred to as a solution method) is exemplified by a method below.

A toluene solution in which a measurement target compound is dissolved at a concentration of 10 μmol/l is prepared and is encapsulated in a quartz cell to provide a measurement sample. Absorption spectrum (ordinate axis: absorption intensity, abscissa axis: wavelength) of the sample is measured at the normal temperature (300 K). A tangent is drawn to the fall of the absorption spectrum on the long-wavelength side, and a wavelength value λedge (nm) at an intersection of the tangent and the abscissa axis is assigned to a conversion equation (F2) below to calculate the lowest singlet energy.

S₁ [eV]=1239.85/λedge Conversion Equation (F2):

Any device for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the exemplary embodiment, a difference (S₁-T_{77K}) between the lowest singlet state S₁ and energy gap T_{77K} at 77K is defined as ΔST.

In the exemplary embodiment, a difference ΔST(DF_{R}) between the lowest singlet energy S₁(DF_{R}) of the delayed fluorescent compound DF_{R} and an energy gap T_{77K}(DF_{R}) at 77K of the delayed fluorescent compound DF_{R} is preferably less than 0.3 eV, more preferably less than 0.2 eV, further preferably less than 0.1 eV. In other words, ΔST(DF_{R}) preferably satisfies a relationship of a numerical formula 10, a numerical formula 11, or a numerical formula 12 below.

ΔST(DF_{R})=S₁(DF_{R})−T_{77K}(DF_{R})<0.3 eV (Numerical Formula 10)

ΔST(DF_{R})=S₁(DF_{R})−T_{77K}(DF_{R})<0.2 eV (Numerical Formula 11)

ΔST(DF_{R})=S₁(DF_{R})−T_{77K}(DF_{R})<0.1 eV (Numerical Formula 12)

### Blue-Emitting Organic EL Device

The blue-emitting organic EL device 10B includes a blue emitting layer 5B as the emitting layer 5. In FIG. 1, the blue emitting layer 5B is denoted by B.

The blue-emitting organic EL device 10B includes a light reflection layer 2B, a transparent electrode 38, a hole transporting zone 4B, the blue emitting layer 5B, an electron transporting zone 6B, and a semitransmissive electrode 7B respectively corresponding to the light reflection layer 2, the transparent electrode 3, the hole transporting zone 4, the emitting layer 5, the electron transporting zone 6, and the semitransmissive electrode 7.

The blue emitting layer 5B is interposed between the hole transporting zone 4B and the electron transporting zone 6B.

The blue emitting layer 5B is in direct contact with the hole transporting zone 4B and further also in direct contact with the electron transporting zone 6B.

The film thickness of the blue emitting layer 5B is preferably 15 nm or more. The film thickness of the blue emitting layer 5B is preferably 30 nm or less. The film thickness of each of the blue emitting layer 5B and the red emitting layer 5R can be measured in the same manner as the measurement method of the film thickness of the hole transporting zone 4.

The blue emitting layer 5B contains the fluorescent compound FL_{B} or the phosphorescent compound PL_{B}. Herein, a “fluorescent compound” is a compound exhibiting no delayed fluorescence. Accordingly, the fluorescent compound FL_{B} is a compound exhibiting no delayed fluorescence.

The blue emitting layer 5B preferably contains the fluorescent compound FL_{B}.

The fluorescent compound FL_{B} is preferably a blue fluorescent compound. The blue fluorescent compound is not particularly limited. The phosphorescent compound PL_{B} is preferably a blue phosphorescent compound. The blue phosphorescent compound is not particularly limited.

Herein, blue light emission refers to a light emission in which a main peak wavelength of a fluorescence spectrum of a fluorescent compound and a main peak wavelength of a phosphorescent spectrum of a phosphorescent compound are in a range from 430 nm to 500 nm.

When the fluorescent compound FL_{B} is a blue fluorescent compound, the main peak wavelength of the fluorescent compound FL_{B} is preferably in a range from 430 nm to 500 nm, more preferably 430 nm or more and less than 500 nm. When the phosphorescent compound PL_{B} is a blue phosphorescent compound, the main peak wavelength of the phosphorescent compound PL_{B} is preferably in a range from 430 nm to 500 nm, more preferably 430 nm or more and less than 500 nm.

In an exemplary embodiment, it is preferable that the blue emitting layer 5B further contains a compound FH_{B}.

When the blue emitting layer 5B contains the compound FH_{B} and the fluorescent compound FL_{B}, singlet energy S₁(FL_{B}) of the compound FL_{B} and singlet energy S₁(FH_{B}) of the compound FH_{B} preferably satisfy a relationship of a numerical formula (Numerical Formula 3A).

S₁(FH_{B})>S₁(FL_{B}) (Numerical Formula 3A)

In an exemplary embodiment, it is preferable that the blue emitting layer 5B further contains a compound PH_{B}.

When the blue emitting layer 5B contains the compound PH_{B} and the phosphorescent compound PL_{B}, an energy gap T_{77K}(PL_{B}) at 77K of the compound PL_{B} and an energy gap T_{77K}(PH_{B}) at 77K of the compound PH_{B} preferably satisfy a relationship of a numerical formula (Numerical Formula 3B).

T_{77K}(PH_{B})>T_{77K}(PL_{B}) (Numerical Formula 3B)

When the blue emitting layer 5B contains the compound FH_{B} and the fluorescent compound FL_{B}, the fluorescent compound FL_{B} is preferably a dopant material (also referred to as a guest material, emitter or luminescent material), and the compound FH_{B} is preferably a host material (also referred to as a matrix material). The compound FH_{B} is not particularly limited as long as being a host material that can be used in combination with a blue fluorescent compound (dopant material), and the compound FH_{B} is exemplified by an anthracene derivative.

When the blue emitting layer 5B contains the compound PH_{B} and the phosphorescent compound PL_{B}, the phosphorescent compound PL_{B} is preferably a dopant material (also referred to as a guest material, emitter or luminescent material), and the compound PH_{B} is preferably a host material (also referred to as a matrix material). The compound PH_{B} is not particularly limited as long as being s a host material that can be used in combination with a blue phosphorescent compound (dopant material), and the compound PH_{B} is exemplified by an anthracene derivative.

### Light Reflection Layer

The light reflection layer 2 is in direct contact with the transparent electrode 3.

Reflectance on the interface of the light reflection layer 2 with the transparent electrode 3 is preferably 50% or more, more preferably 80% or more.

The light reflection layer 2 is preferably a metal layer. Metals forming the metal layer are not particularly limited. Examples of the metals include metal selected from the group consisting of gold (Au), platinum (Pt), nickel (Ni), tungsten (W), chrome (Cr), molybdenum (Mo), iron (Fe), cobalt (Co), copper (Cu), palladium (Pd), titanium (Ti), and silver (Ag), and alloys containing a plurality of types of metals selected from the group consisting of these metals. The light reflection layer 2 is exemplified by an APC layer. APC refers to an alloy of silver (Ag), palladium (Pd), and copper (Cu).

The light reflection layer 2 of the organic EL display device 1 is preferably a non-common layer. Specifically, the light reflection layer 2R and the light reflection layer 2B are each preferably a non-common layer.

Herein, a layer provided in a shared manner across a plurality of devices is occasionally referred to as a common layer. Herein, a layer not provided in a shared manner across a plurality of devices but provided to each of the organic EL devices (i.e., a layer that is not the common layer) is occasionally referred to as a non-common layer.

### Transparent Electrode

The transparent electrode 3 is interposed between the light reflection layer 2 and the hole transporting zone 4.

The transparent electrode 3 is in direct contact with the light reflection layer 2 and further also in direct contact with the hole transporting zone 4.

The transparent electrode 3 is preferably a transparent conductive film. Examples of the transparent conductive film as the transparent electrode 3 include an Indium Tin Oxide (ITO) film and an indium zinc oxide film.

Transmittance of the transparent electrode 3 is preferably 50% or more, more preferably 80% or more. The transmittance of the transparent electrode 3 is preferably 100% or less. From the viewpoint of suppressing decay due to multiple reflections, an extinction coefficient of the transparent electrode 3 is preferably 0.05 or less, more preferably 0.01 or less.

The film thickness of the transparent electrode 3 is preferably 15 nm or less.

The film thickness of the transparent electrode 3 is preferably 5 nm or more.

The film thickness of the transparent electrode 3 can be measured by the above-described “Measurement Method of Film Thickness of Layer or Zone.” Since the film thickness of the transparent electrode 3 is 15 nm or less, a film thickness of the hole transporting zone can be thickened while a sum of the film thickness of the hole transporting zone and the film thickness of the transparent electrode is kept less than 40 nm. Since the film thickness of the transparent electrode 3 is 5 nm or more, holes can be stably injected into the hole transporting zone.

The transparent electrode 3 of the organic EL display device 1 is preferably a non-common layer. Specifically, the transparent electrode 3R and the transparent electrode 3B are each preferably a non-common layer.

When the transparent electrode 3R and the transparent electrode 3B are each a non-common layer, the film thickness of the transparent electrode 3R and the film thickness of the transparent electrode 3B are each independently preferably in a range from 5 nm to 15 nm.

### Hole Transporting Zone

The hole transporting zone 4 is at least interposed between the transparent electrode 3 and the emitting layer 5.

The hole transporting zone 4 is provided at a constant film thickness in a shared manner across the blue-emitting organic EL device 10B and the red-emitting organic EL device 10R.

Herein, a zone provided in a shared manner across a plurality of devices is occasionally referred to as a common zone.

The hole transporting zone 4 is a common zone and is provided at a constant film thickness in a shared manner across the blue-emitting organic EL device 10B and the red-emitting organic EL device 10R. Since the hole transporting zone 4 is a common zone, the hole transporting zone 4 in the red-emitting organic EL device 10R and the blue-emitting organic EL device 10B can be manufactured without replacing a mask or the like. As a result, productivity of the organic EL display device 1 is improved.

The film thickness of the hole transporting zone is preferably in a range from 10 nm or more and less than 25 nm, more preferably in a range from 10 nm to 20 nm. Specifically, in the organic EL display device 1, it is preferable that the film thickness of the hole transporting zone 4B in the blue-emitting organic EL device 10B is 10 nm or more and less than 25 nm and the film thickness of the hole transporting zone 4R in the red-emitting organic EL device 10R is 10 nm or more and less than 25 nm, and it is more preferable that the film thickness of the hole transporting zone 4B is in a range from 10 nm to 20 nm and the film thickness of the hole transporting zone 4R is in a range from 10 nm to 20 nm.

The film thickness of the hole transporting zone 4 can be measured by the above-described “Measurement Method of Film Thickness of Layer or Zone.”

A sum of the film thickness of the transparent electrode 3 and the film thickness of the hole transporting zone 4 in each of the blue-emitting organic EL device 10B and the red-emitting organic EL device 10R is less than 40 nm. Specifically, a sum of the film thickness of the transparent electrode 3B and the film thickness of the hole transporting zone 4B in the blue-emitting organic EL device 10B is less than 40 nm and a sum of the film thickness of the transparent electrode 3R and the film thickness of the hole transporting zone 4R in the red-emitting organic EL device 10R is less than 40 nm. A sum of the film thickness of the transparent electrode 3 and the film thickness of the hole transporting zone 4 is denoted by d_{HT1} in FIG. 1.

That the sum of the film thickness of the transparent electrode 3 and the film thickness of the hole transporting zone 4 in each of the blue-emitting organic EL device 10B and the red-emitting organic EL device 10R is less than 40 nm can improve the viewing angle.

The sum of the film thickness of the transparent electrode 3 and the film thickness of the hole transporting zone 4 in each of the blue-emitting organic EL device 10B and the red-emitting organic EL device 10R is preferably 15 nm or more. Specifically, the sum of the film thickness of the transparent electrode 3B and the film thickness of the hole transporting zone 4B in the blue-emitting organic EL device 10B is preferably 15 nm or more and the sum of the film thickness of the transparent electrode 3R and the film thickness of the hole transporting zone 4R in the red-emitting organic EL device 10R is preferably 15 nm or more.

The hole transporting zone means a region where holes are transferred. Hole mobility μ^{H} in the hole transporting zone is preferably 10⁻⁶ [cm²/(V·s)] or more. The hole mobility μ^{H} [cm2/[V·s]] can be measured according to impedance spectroscopy disclosed in JP 2014-110348 A.

The hole transporting zone 4 is also preferably formed of only a single layer.

The hole transporting zone 4 is also preferably formed of a plurality of layers.

Examples of the layer forming the hole transporting zone 4 includes a hole injecting layer, a hole transporting layer, and an electron blocking layer.

When the hole transporting zone 4 includes a plurality of layers, each layer of the hole transporting zone 4 is a common layer provided at a constant film thickness in a shared manner across the blue-emitting organic EL device 10B and the red-emitting organic EL device 10R. Specifically, for instance, when the hole transporting zone 4 includes a hole injecting layer and a hole transporting layer, both the hole injecting layer and the hole transporting layer are the common layers.

When the hole transporting zone 4 includes a plurality of layers, all the plurality of layers of the hole transporting zone 4 also preferably contain the same compound. That “all the plurality of layers contain the same compound” means that each of the plurality of layers contains a compound having the same structure. The plurality of layers may further contain a compound other than the compound having the same structure. For instance, when the hole transporting zone 4 includes a hole injecting layer and a hole transporting layer, both the hole injecting layer and the hole transporting layer contain the same compound HTx and the hole injecting layer may further contain a compound HAx in addition to the compound HTx.

### Electron Transporting Zone

The electron transporting zone 6 is at least interposed between the emitting layer 5 and the semitransmissive electrode 7.

The electron transporting zone 6 is in direct contact with the emitting layer 5 and further also in direct contact with the semitransmissive electrode 7.

It is preferable that a film thickness of the electron transporting zone 6 (electron transporting zone 6B) in the blue-emitting organic EL device 10B is smaller than a film thickness of the electron transporting zone 6 (electron transporting zone 6R) in the red-emitting organic EL device 10R. The film thickness of each of the electron transporting zone 6B and the electron transporting zone 6R can be measured in the same manner as the measurement method of the film thickness of the hole transporting zone 4.

The electron transporting zone 6 means a region where electrons are transferred. Electron mobility μ^{E} in the electron transporting zone 6 is preferably 10$ [cm²/(V·s)] or more. The electron mobility μ^{E} [cm²/[V·s]] can be measured according to impedance spectroscopy disclosed in JP 2014-110348 A.

The electron transporting zone 6 may be formed of a single layer or a plurality of layers. Specifically, the electron transporting zone 6R in the red-emitting organic EL device 10R may be a zone formed of a single layer or a zone formed of a plurality of layers. The electron transporting zone 6B in the blue-emitting organic EL device 10B may be a zone formed of a single layer or a zone formed of a plurality of layers.

Examples of the layer forming the electron transporting zone 6 includes an electron injecting layer, an electron transporting layer, and a hole blocking layer.

### Semitransmissive Electrode

The semitransmissive electrode 7 transmits light and reflects the light at an interface with the electron transporting zone 6. The transmittance of the semitransmissive electrode 7 is preferably 50% or more.

A film thickness of the semitransmissive electrode 7 is preferably in a range from 5 nm to 30 nm.

The semitransmissive electrode 7 is preferably formed of an elemental metal or an alloy of a metal material. In the case of a metal material having a large extinction coefficient, a transmitted light amount decreases due to light absorption when light is transmitted through the semitransmissive electrode 7. In order to efficiently extract light from the semitransmissive electrode 7, it is preferable to suppress light absorption. Therefore, as the material of the semitransmissive electrode 7, it is preferable to select an elemental metal or an alloy of a metal material having a small real part refractive index. Examples of the metal material include silver, aluminum, magnesium, calcium, sodium and gold.

The semitransmissive electrode 7 is preferably a common layer having a constant film thickness provided in a shared manner across a plurality of organic EL devices. Specifically, the semitransmissive electrode 7R and the semitransmissive electrode 7B are preferably the common layer in the organic EL display device 1.

In the organic EL display device 1 of the exemplary embodiment, a reflective electrode is defined by at least the light reflection layer 2 and the transparent electrode 3. The organic EL display device 1 includes a so-called top emission type organic EL device. In each of the blue-emitting organic EL device 10B and the red-emitting organic EL device 10R in the organic EL display device 1, the reflective electrode is provided on the substrate 8 and light is extracted from the opposite semitransmissive electrode 7 across the organic layer.

In the organic EL display device 1 of the exemplary embodiment, the reflective electrode is the anode and the semitransmissive electrode 7 is the cathode.

### Capping Layer

When the organic EL display device 1 is of a top emission type, the organic EL display device 1 may include a capping layer on an upper side of the semitransmissive electrode 7 serving as the cathode.

Examples of the material of the capping layer include a polymer compound, metal oxide, metal fluoride, metal boride, silicon nitride and a silicon compound (e.g., silicon oxide).

Moreover, examples of the material of the capping layer include an aromatic amine derivative, anthracene derivative, pyrene derivative, fluorene derivative, and dibenzofuran derivative.

Further, the organic EL display device 1 may include, as the capping layer, a laminate of a plurality of layers containing the material used for the capping layer.

### Substrate

The substrate 8 is a support supporting the organic EL device serving as the pixel. Examples of a material of the substrate 8 include glass, quartz and plastic. A flexible substrate is also usable as the substrate 8. The flexible substrate is a bendable substrate. Examples of the flexible substrate include a plastic substrate made of polycarbonate, polyarylate, polyether sulfone, polypropylene, polyester, polyvinyl fluoride or polyvinyl chloride. Moreover, an inorganic vapor deposition film is also usable as the substrate 8.

### Layer Thickness

In the organic EL display device 1, the film thickness of each layer forming the organic layer contained between the reflective electrode as the anode and the semitransmissive electrode 7 is not particularly limited unless otherwise specified herein. In general, an excessively small film thickness of each layer forming the organic layer is likely to cause defects (e.g. pin holes) and an excessively large thickness thereof requires application of high voltage to deteriorate the efficiency. The film thickness of each layer forming the organic layer is typically preferably in a range from several nm to 1 μm.

### Manufacturing Method of Organic EL Display Device

A manufacturing method of the organic EL display device 1 of the exemplary embodiment will be described.

The light reflection layer 2 is laminated on the substrate 8 and patterned. In a case of a top emission type structure, a metal layer (e.g., APC layer) that is a reflective layer is used as the light reflection layer 2.

Next, the transparent electrode 3 is formed on the light reflection layer 2.

Next, the hole transporting zone 4 as a common zone is formed over the reflective electrode (anode) including the light reflection layer 2 and the transparent electrode 3. The hole transporting zone 4 in the red-emitting organic EL device 10R and the blue-emitting organic EL device 10B is formed of the same material at the same film thickness.

Next, the blue emitting layer 5B is formed to have a predetermined film thickness using a predetermined film-forming mask in a region corresponding to the transparent electrode 3B of the blue-emitting organic EL device 10B and on the hole transporting zone 4.

Similarly, the red emitting layer 5R is formed to have a predetermined film thickness using a predetermined film-forming mask in a region corresponding to the transparent electrode 3R of the red emitting layer 5R and on the hole transporting zone 4.

The blue emitting layer 5B and the red emitting layer 5R are formed different materials.

Next, the electron transporting zone 6 is formed of the same material over the blue emitting layer 5B and the red emitting layer 5R. A film thickness of the electron transporting zone 6B in the blue-emitting organic EL device 10B is different from a film thickness of the electron transporting zone 6R in the red-emitting organic EL device 10R.

Next, the semitransmissive electrode 7 is formed on the electron transporting zone 6. The capping layer may be formed on the semitransmissive electrode 7.

The organic EL display device 1 shown in FIG. 1 is manufactured as described above.

The method of forming each layer of the organic EL device included in the organic EL display device described herein is not limited except as specifically described above, but a known method such as a dry film-forming method or a wet film-forming method can be adopted. Examples of the dry film-forming include vacuum deposition, sputtering, plasma process, and ion plating. Examples of the wet film-forming include spin coating, dipping, flow coating and ink-jet.

According to the exemplary embodiment, a high-performance organic EL display device 1 can be provided. Reasons are described below.

The emitting layer of the organic EL device is formed to have a predetermined film thickness. A position in the emitting layer where light is mainly generated (sometimes referred to as the maximum emission position) differs in each emitting layer. The maximum emission position is a position in the emitting layer where holes and electrons recombine to mainly generate and deactivate excitons.

Meanwhile, the organic EL device has a “position where emissions are mutually enhanced (position in a thickness direction of the emitting layer)” caused by light interference between the electrodes. The organic EL device is designed so that the “position where emissions are mutually enhanced” overlaps with the “maximum emission position.”

The “position where emissions are mutually enhanced” is a function of the emission wavelength. Accordingly, the “position where emissions are mutually enhanced” differs in each of the organic EL devices (the blue-emitting organic EL device and the red-emitting organic EL device in the exemplary embodiment) as pixels. Typically, a total of film thicknesses also differs in each of the organic EL devices as pixels.

In such a situation, the inventors have found that the “maximum emission position” in the red emitting layer 5R containing the delayed fluorescent compound DF_{R} is different from the position conventionally considered, specifically, holes and electrons recombine locally in the region of the red emitting layer 5R close to the electron transporting zone 6R. The maximum emission position in the emitting layer containing the delayed fluorescent compound is considered to be at a side of the emitting layer close to the electron transporting zone because the delayed fluorescent compound has a strong electron trapping property.

For instance, a phosphorescent material is typically used for the red emitting layer in the red-emitting organic EL device and the green emitting layer in the green-emitting organic EL device. Also in such a phosphorescent organic EL device (hereinafter, sometimes referred to a device A), the “position where emissions are mutually enhanced” (first-order interference position) and the “maximum emission position” are designed to overlap with each other. However, since the “maximum emission position” in the emitting layer containing the delayed fluorescent compound is different from the “maximum emission position” in the phosphorescent organic EL device, when a delayed fluorescent compound is used in place of a phosphorescent material in a device arrangement which is designed for a phosphorescent organic EL device and remains unchanged, “position where emissions are mutually enhanced” (first-order interference position) and the “maximum emission position” are conventionally deviated from each other to decrease the light extraction efficiency.

An organic EL device (hereinafter, sometimes referred to as a device B) is also conceivable to have an increased film thickness of each of the hole transporting zone and the electron transporting zone in the organic EL device so that the “maximum emission position” and the “position where emissions are mutually enhanced” (first-order interference position) overlap with each other in the emitting layer containing the delayed fluorescent compound (hereinafter, sometimes referred to as a delayed fluorescent layer). With this device arrangement, the “maximum emission position” and the “position where emissions are mutually enhanced” (first-order interference position) in the delayer fluorescent layer overlap with each other to improve the light-extraction efficiency. In this arrangement, the organic EL device having the delayed fluorescent layer is subjected to steps (a step for increasing the film thickness of the hole transporting zone and a step for increasing the film thickness of the electron transporting zone) which are not performed in common with film forming steps of other organic EL device (the blue-emitting organic EL device in the exemplary embodiment). As a result, a frequency of masking in the film forming is increased, resulting in difficulty in improving productivity of the organic EL display device.

The device A and the device B are designed so that the “maximum emission position” in the emitting layer overlaps with the “first-order interference position” in the “position where emissions are mutually enhanced.” In the phosphorescent red-emitting organic EL device and the phosphorescent green-emitting organic EL device such as the device A that is a typical technique, since a full width at half maximum of an emission spectrum is large, even a device arrangement in which the “maximum emission position” and the “first-order interference position” in the phosphorescent layer overlap with each other is less problematic.

In contrast, the inventors have found that in the device arrangement in which the “maximum emission position” and the “first-order interference position” in the delayed fluorescent layer overlap with each other, since emission from the delayed fluorescent layer (particularly, emission from the emitting layer containing the delayed fluorescent compound and the fluorescent compound) has a smaller full width at half maximum of an emission spectrum than that of a phosphorescent device, angular dependency of an emission color is increased.

The emitting layer of the blue-emitting organic EL device in the device A and the device B is preferably a blue fluorescent layer containing a fluorescent compound. The inventors have found that since a blue fluorescent layer has a strong electron transportability, increasing the film thickness of the hole transporting zone as in the arrangements of the device A and the device B makes holes in the fluorescent emitting layer insufficient to shorten a lifetime of the blue-emitting organic EL device.

According to the exemplary embodiment, the organic EL display device 1 having an improved light extraction efficiency, eventually, an improved current efficiency without decreasing the production efficiency, and a small angular dependency of the emission color can be provided.

In the organic EL display device 1, the hole transporting zone 4 is provided at a constant film thickness in a shared manner across the blue-emitting organic EL device 10B and the red-emitting organic EL device 10R. Accordingly, the organic EL display device 1 can be manufactured without increasing the frequency of the masking as in the device B.

Further, the red emitting layer 5R of the red-emitting organic EL device 10R contains the delayed fluorescent compound DF_{R}. The red-emitting organic EL device 10R has a resonator structure whose order of interference is the first order. The film thickness of the red emitting layer 5R is less than 50 nm. A sum of the film thickness of the transparent electrode 3R and the film thickness of the hole transporting zone 4R in the red-emitting organic EL device 10R is less than 40 nm. As a result, in the red-emitting organic EL device 10R of the organic EL display device 1, in the red emitting layer 5R, the “maximum emission position” overlaps with a “zero-order interference position” viewed from the light reflection layer 2, resulting in a small angular dependency of the emission color and an improvement in the light extraction efficiency.

Further, it is preferable that the blue-emitting organic EL device includes the blue emitting layer 5B (fluorescent emitting layer) containing the fluorescent compound FL_{B}, and a sum of the film thickness of the transparent electrode 3B and the film thickness of the hole transporting zone 4B in the blue-emitting organic EL device 10B is less than 40 nm. As a result, in the blue-emitting organic EL device 10B of the organic EL display device 1, in the blue emitting layer 58, the “maximum emission position” overlaps with a “zero-order interference position” viewed from the light reflection layer 2, resulting in a small angular dependency of the emission color and an improvement in the light extraction efficiency. Further, it is considered that since the film thickness of the hole transporting zone 4B in the blue-emitting organic EL device 10B is thin, holes are easily injected into the blue emitting layer 5B to prolong the lifetime of the blue-emitting organic EL device 10B. Since a blue host compound typically used in the blue emitting layer has a high electron transportability, when supply of holes into the blue emitting layer is insufficient, a lifetime of the blue-emitting organic EL device tends to be shortened. It is considered that in the arrangement of the organic EL display device 1 of the exemplary embodiment, since the film thickness of the hole transporting zone 4 is made thin, the supply amount of holes into the blue emitting layer 5B is increased to improve carrier balance in the blue emitting layer 5B and improve the lifetime of the blue-emitting organic EL device 10B.

Examples of the organic EL display device include a display component (e.g., an organic EL panel module), TV, mobile phone, tablet and personal computer. Specific examples similar to the above can be given for the organic EL display device in the following exemplary embodiment(s).

### Second Exemplary Embodiment

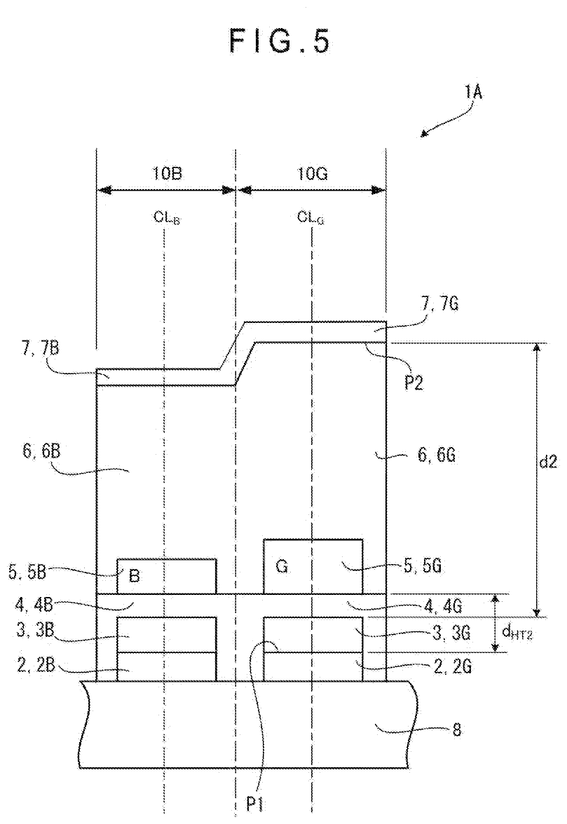

An arrangement of an example of an organic EL display device according to a second exemplary embodiment will be described with reference to FIG. 5.

FIG. 5 shows an organic EL display device 1A.

The organic EL display device 1A includes the blue-emitting organic EL device 10B and a green-emitting organic EL device 10G as pixels.

The organic EL display device 1A is different from the organic EL display device 1 of the first exemplary embodiment in having the green-emitting organic EL device 10G in place of the red-emitting organic EL device 10R, and is otherwise the same as in the first exemplary embodiment. Accordingly, the same components as those in the first exemplary embodiment are denoted by the same reference signs to simplify or omit an explanation of the components.

Each of the blue-emitting organic EL device 10B and the green-emitting organic EL device 10G includes the light reflection layer 2, transparent electrode 3, hole transporting zone 4, emitting layer 5, electron transporting zone 6, and semitransmissive electrode 7. The hole transporting zone 4, the emitting layer 5 and the electron transporting zone 6 are herein sometimes referred to as an organic layer.

Each of the blue-emitting organic EL device 10B and the green-emitting organic EL device 10G includes the light reflection layer 2, the transparent electrode 3, the hole transporting zone 4, the emitting layer 5, the electron transporting zone 6, and the semitransmissive electrode 7 in this order. In the organic EL display device 1, the blue-emitting organic EL device 10B and the green-emitting organic EL device 10G as pixels are disposed in parallel on a substrate 8.

In each of the blue-emitting organic EL device 10B and the green-emitting organic EL device 10G in the organic EL display device 1A, the transparent electrode 3 is in direct contact with the hole transporting zone 4, the hole transporting zone 4 is in direct contact with the emitting layer 5, the emitting layer 5 is in direct contact with the electron transporting zone 6, and the electron transporting zone 6 is in direct contact with the semitransmissive electrode 7.

The organic EL display device 1A includes the blue-emitting organic EL device 10B as a blue pixel and the green-emitting organic EL device 10G as a green pixel. A voltage is applied to each pixel independently. In the organic EL display device 1A, the blue pixel and the green pixel can be selectively made emit light. The organic EL display device 1A may have a plurality of units each consisting of one blue pixel and one green pixel. In this case, the plurality of units each consisting of the blue pixel and the green pixel may be repeatedly arranged on the substrate. Moreover, each pixel in each unit may be plural. For example, one blue pixel and two green pixels may form one unit. It should be noted that the organic EL display device of the exemplary embodiment may have a pixel emittable in a color other than the blue pixel and the green pixel.

### Green-Emitting Organic EL Device

The green-emitting organic EL device 10G includes a green emitting layer 5G as the emitting layer 5. In FIG. 5, the green emitting layer 5G is denoted by G.

The green-emitting organic EL device 10G includes a light reflection layer 2G, a transparent electrode 3G, a hole transporting zone 4G, a green emitting layer 5G, an electron transporting zone 6G, and a semitransmissive electrode 7G respectively corresponding to the light reflection layer 2, the transparent electrode 3, the hole transporting zone 4, the emitting layer 5, the electron transporting zone 6, and the semitransmissive electrode 7.

The green emitting layer 5G is interposed between the hole transporting zone 4G and the electron transporting zone 6G.

The green emitting layer 5G is in direct contact with the hole transporting zone 4G and further also in direct contact with the electron transporting zone 6G.

A film thickness of the green emitting layer 5G is less than 40 nm. The film thickness of the green emitting layer 5G is preferably 15 nm or more.

The film thickness of the green emitting layer 5G is larger than that of the blue emitting layer 5B. The film thickness of each of the green emitting layer 5G and the blue emitting layer 5B can be measured by the above-described “Measurement Method of Film Thickness of Layer or Zone.” In FIG. 5, the central portion of the green-emitting organic EL device 10G is represented by CL_{G} and the central portion of the blue-emitting organic EL device 10B is represented by CL_{B}.

In the organic EL display device 1A according to the exemplary embodiment, the green-emitting organic EL device 10G has a resonator structure whose order of interference is first-order between the light reflection layer 2 and the semitransmissive electrode 7. Specifically, the green-emitting organic EL device 10G has a resonator structure whose order of interference is first-order between the light reflection layer 2G and the semitransmissive electrode 7G. A distance d2 between the light reflection layer 2G and the semitransmissive electrode 7G in the green-emitting organic EL device 10G corresponds to a sum of a thickness of the hole transporting zone 4G, a thickness of the green emitting layer 5G, and a thickness of the electron transporting zone 6G.

In the organic EL display device 1A according to the exemplary embodiment, the green-emitting organic EL device 10G has a resonator structure. In the description of the above resonator structure in the first exemplary embodiment, as for the green-emitting organic EL device 10G having the resonator structure, the organic EL display device 1, the light reflection layer 2, the semitransmissive electrode 7, the hole transporting zone 4, the emitting layer 5, and the electron transporting zone 6 can be read as the organic EL display device 1A, the light reflection layer 2G, the semitransmissive electrode 7G, the hole transporting zone 4G, the green emitting layer 5G, and the electron transporting zone 6G, respectively.

### Green Emitting Layer

The green emitting layer 5G contains a delayed fluorescent compound DF_{G}.

In an exemplary embodiment, it is preferable that the green emitting layer 5G further contains a fluorescent compound FL_{G}. Herein, a “fluorescent compound” is a compound exhibiting no delayed fluorescence. Accordingly, the fluorescent compound FL_{G} is a compound exhibiting no delayed fluorescence.

When the green emitting layer 5G contains the delayed fluorescent compound DF_{G} and the fluorescent compound FL_{G}, the singlet energy S₁(DF_{G}) of the delayed fluorescent compound DF_{G} and the singlet energy S₁(FL_{G}) of the fluorescent compound FL_{G} preferably satisfy a relationship of Numerical Formula 2A below.

S₁(DF_{G})>S₁(FL_{G}) (Numerical Formula 2A)

When the green emitting layer 5G contains the fluorescent compound FL_{G}, the compound FL_{G} is preferably a green fluorescent compound.

In the green emitting layer 5G, the fluorescent compound FL_{G} is preferably a dopant material (also referred to as a guest material, emitter or luminescent material), and the delayed fluorescent compound DF_{G} is preferably a host material (also referred to as a matrix material).

The green emitting layer 5G preferably does not contain a phosphorescent material.

The green emitting layer 5G preferably does not contain a heavy metal complex and a phosphorescent rare-earth metal complex. Examples of the heavy-metal complex herein include iridium complex, osmium complex, and platinum complex.

It is also preferable that the green emitting layer 5G does not contain a metal complex.

### Content Ratio of Compound in Green Emitting Layer

In the green emitting layer 5G of the exemplary embodiment, the content ratio of the fluorescent compound FL_{G} is preferably in a range from 0.01 mass % to 10 mass %, and the content ratio of the delayed fluorescent compound DF_{G} is preferably in a range from 80 mass % to 99.99 mass %. The upper limit of the total content ratios of the fluorescent compound FL_{G} and the delayed fluorescent compound DF_{G} in the green emitting layer 5G is 100 mass %. It should not be excluded that in the exemplary embodiment, the green emitting layer 5G contains a material other than the fluorescent compound FL_{G} and the delayed fluorescent compound DF_{G}.

The green emitting layer 5G may contain a single type of the fluorescent compound FL_{G} or may contain two or more types of the fluorescent compound FL_{G}. The green emitting layer 5G may contain a single type of the delayed fluorescent compound DF_{G} or may contain two or more types of the delayed fluorescent compound DF_{G}.

Herein, the green light emission refers to light emission whose main peak wavelength of fluorescence spectrum is in a range from 500 nm to 560 nm.

When the fluorescent compound FL_{G} is a green fluorescent compound, a main peak wavelength of the fluorescent compound FL_{G} is preferably in a range from 500 nm to 560 nm, more preferably in a range from 500 nm to 540 nm, further preferably in a range from 510 nm to 530 nm.

In the exemplary embodiment, a difference ΔST(DF_{G}) between the lowest singlet energy S₁(DF_{G}) of the delayed fluorescent compound DF_{G} and an energy gap T_{77K}(DF_{G}) at 77K of the delayed fluorescent compound DF_{G} is preferably less than 0.3 eV, more preferably less than 0.2 eV, further preferably less than 0.1 eV. In other words, ΔST(DF_{G}) preferably satisfies a relationship of a numerical formula 20, a numerical formula 21, or a numerical formula 22 below.

ΔST(DF_{G})=S₁(DF_{G})−T_{77K}(DF_{G})<0.3 eV (Numerical Formula 20)

ΔST(DF_{G})=S₁(DF_{G})−T_{77K}(DF_{G})<0.2 eV (Numerical Formula 21)

ΔST(DF_{G})=S₁(DF_{G})−T_{77K}(DF_{G})<0.1 eV (Numerical Formula 22)

### TADF Mechanism

In the green-emitting organic EL device 10G of the exemplary embodiment, the compound DF_{G} is preferably a compound having a small ΔST(DF_{G}), so that inverse intersystem crossing from the triplet energy level of the compound DF_{G} to the singlet energy level thereof is easily caused by a heat energy given from the outside. An energy state conversion mechanism to perform spin exchange from the triplet state of electrically excited excitons within the organic EL device to the singlet state by inverse intersystem crossing is referred to as the TADF Mechanism.

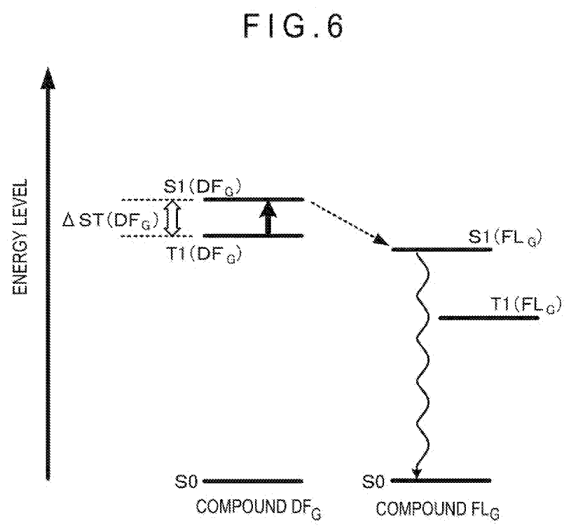

FIG. 6 shows an example of a relationship between energy levels of the compound DF_{G} and the compound FL_{G} in the green emitting layer 5G. Symbols in FIG. 6 are described as follows.

S0 represents a ground state.

S1(DF_{G}) represents the lowest singlet state of the compound DF_{G}.

T1(DF_{G}) represents the lowest triplet state of the compound DF_{G}.

S1(FL_{G}) represents the lowest singlet state of the compound FL_{G}.

T1(FL_{G}) represents the lowest triplet state of the compound FL_{G}.

A dashed arrow directed from S1(DF_{G}) to S1(FL_{G}) in FIG. 6 represents Förster energy transfer from the lowest singlet state of the compound DF_{G} to the lowest singlet state of the compound FL_{G}. In the exemplary embodiment, a difference between the lowest singlet state S1 and the lowest triplet state T1 is defined as ΔST.

As shown in FIG. 6, when a compound having a small ΔST(DF_{G}) is used as the compound DF_{G}, inverse intersystem crossing from the lowest triplet state T1(DF_{G}) to the lowest singlet state S1(DF_{G}) can be caused by a heat energy. Subsequently, Förster energy transfer from the lowest singlet state S1(DF_{G}) of the compound DF_{G} to the compound FL_{G} occurs to generate the lowest singlet state S1(FL_{G}). Consequently, fluorescence from the lowest singlet state S1(FL_{G}) of the compound FL_{G} can be observed. It is inferred that the internal quantum efficiency can be theoretically raised up to 100% also by using delayed fluorescence by the TADF mechanism.

### Blue-Emitting Organic EL Device

The blue-emitting organic EL device 10B in the organic EL display device 1A includes the blue emitting layer 5B as the emitting layer 5. In FIG. 5, the blue emitting layer 5B is denoted by B.

The blue-emitting organic EL device 10B of the second exemplary embodiment is the same as the blue-emitting organic EL device 10B of the first exemplary embodiment and therefore the explanation thereof is omitted.

### Hole Transporting Zone

The hole transporting zone 4 is at least interposed between the transparent electrode 3 and the emitting layer 5.

The hole transporting zone 4 is provided at a constant film thickness in a shared manner across the blue-emitting organic EL device 10B and the green-emitting organic EL device 10G.

The hole transporting zone 4 is a common zone and is provided at a constant film thickness in a shared manner across the blue-emitting organic EL device 10B and the green-emitting organic EL device 10G. Since the hole transporting zone 4 is a common zone, the hole transporting zone 4 in the green-emitting organic EL device 10G and the blue-emitting organic EL device 10B can be manufactured without replacing a mask or the like. As a result, productivity of the organic EL display device 1A is improved.

In the organic EL display device 1A, the film thickness of the hole transporting zone 4 is preferably in a range from 10 nm or more and less than 25 nm, more preferably in a range from 10 nm to 20 nm. Specifically, in the organic EL display device 1A, it is preferable that the film thickness of the hole transporting zone 4B in the blue-emitting organic EL device 10B is 10 nm or more and less than 25 nm and the film thickness of the hole transporting zone 4G in the green-emitting organic EL device 10G is 10 nm or more and less than 25 nm, and it is more preferable that the film thickness of the hole transporting zone 4B is in a range from 10 nm to 20 nm and the film thickness of the hole transporting zone 4G is in a range from 10 nm to 20 nm.

The film thickness of the hole transporting zone 4 in the organic EL display device 1A can be measured by the above-described “Measurement Method of Film Thickness of Layer or Zone” in the first exemplary embodiment.

A sum of the film thickness of the transparent electrode 3 and the film thickness of the hole transporting zone 4 in each of the blue-emitting organic EL device 10B and the green-emitting organic EL device 10G is less than 40 nm. Specifically, a sum of the film thickness of the transparent electrode 3B and the film thickness of the hole transporting zone 4B in the blue-emitting organic EL device 10B is less than 40 nm and a sum of the film thickness of the transparent electrode 3G and the film thickness of the hole transporting zone 4G in the green-emitting organic EL device 10G is less than 40 nm. The sum of the film thickness of the transparent electrode 3 and the film thickness of the hole transporting zone 4 is denoted by d_{HT2} in FIG. 5.

That the sum of the film thickness of the transparent electrode 3 and the film thickness of the hole transporting zone 4 in each of the blue-emitting organic EL device 10B and the green-emitting organic EL device 10G is less than 40 nm can improve the viewing angle.

The sum of the film thickness of the transparent electrode 3 and the film thickness of the hole transporting zone 4 in each of the blue-emitting organic EL device 10B and the green-emitting organic EL device 10G is preferably 15 nm or more. Specifically, the sum of the film thickness of the transparent electrode 3B and the film thickness of the hole transporting zone 4B in the blue-emitting organic EL device 10B is preferably 15 nm or more and the sum of the film thickness of the transparent electrode 3R and the film thickness of the hole transporting zone 4R in the green-emitting organic EL device 10G is preferably 15 nm or more.

The hole transporting zone 4 in the organic EL display device 1A is also preferably formed of only a single layer.

The hole transporting zone 4 in the organic EL display device 1A is also preferably formed of a plurality of layers.

Examples of layers forming the hole transporting zone 4 in the organic EL display device 1A includes a hole injecting layer, a hole transporting layer, and an electron blocking layer.

When the hole transporting zone 4 in the organic EL display device 1A includes a plurality of layers, each layer of the hole transporting zone 4 is a common layer provided at a constant film thickness in a shared manner across the blue-emitting organic EL device 10B and the green-emitting organic EL device 10G. When the hole transporting zone 4 includes a plurality of layers, all the plurality of layers of the hole transporting zone 4 also preferably contain the same compound.

### Other Arrangements

Since the light reflection layer 2, the transparent electrode 3, the electron transporting zone 6, the semitransmissive electrode 7, and the capping layer in the organic EL display device 1A are respectively the same as the light reflection layer 2, the transparent electrode 3, the electron transporting zone 6, the semitransmissive electrode 7, and the capping layer in the first exemplary embodiment, the explanation of those will be omitted or simplified.

Also in the exemplary embodiment, the light reflection layer 2 is preferably a non-common layer. Specifically, the light reflection layer 2G and the light reflection layer 2B are each preferably a non-common layer.

Also in the exemplary embodiment, the transparent electrode 3 is preferably a non-common layer. Specifically, the transparent electrode 3G and the transparent electrode 3B are each preferably a non-common layer. When the transparent electrode 3G and the transparent electrode 3B are each a non-common layer, the film thickness of the transparent electrode 3G and the film thickness of the transparent electrode 3B are each independently preferably in a range from 5 nm to 15 nm.

It is preferable also in the exemplary embodiment that the film thickness of the electron transporting zone 6 (electron transporting zone 6B) in the blue-emitting organic EL device 10B is smaller than a film thickness of the electron transporting zone 6 (electron transporting zone 6G) in the green-emitting organic EL device 10G. The film thickness of each of the electron transporting zone 6B and the electron transporting zone 6G can be measured in the same manner as the measurement method of the film thickness of the hole transporting zone 4.

Also in the exemplary embodiment, the electron transporting zone 6 may be formed of a single layer or a plurality of layers. Specifically, the electron transporting zone 6G in the green-emitting organic EL device 10G may be a zone formed of a single layer or a zone formed of a plurality of layers. The electron transporting zone 6B in the blue-emitting organic EL device 10B may be a zone formed of a single layer or a zone formed of a plurality of layers.

It is also preferable in the exemplary embodiment that the semitransmissive electrode 7 is a common layer provided in a shared manner across a plurality of organic EL devices (the green-emitting organic EL device and the blue-emitting organic EL device). Specifically, the semitransmissive electrode 7G and the semitransmissive electrode 7B are preferably the common layer in the organic EL display device 1A.

The organic EL display device 1A can be manufactured by substantially the same method as that of the organic EL display device 1 in the first exemplary embodiment except that the green emitting layer 5G is formed in place of the red emitting layer 5R. Accordingly, the explanation of the method is omitted.

According to the exemplary embodiment, the organic EL display device 1A having an improved light extraction efficiency without decreasing the production efficiency, and a small angular dependency of the emission color can be provided.

In the organic EL display device 1A, the hole transporting zone 4 is provided at a constant film thickness in a shared manner across the blue-emitting organic EL device 10B and the green-emitting organic EL device 10G. Accordingly, the organic EL display device 1A can be manufactured without increasing the frequency of the masking as in the device B.

Further, the green emitting layer 5G of the green-emitting organic EL device 10G contains the delayed fluorescent compound DF_{G}. The green-emitting organic EL device 10G has a resonator structure whose order of interference is the first order. The film thickness of the green emitting layer 5G is less than 40 nm. A sum of the film thickness of the transparent electrode 3G and the film thickness of the hole transporting zone 4G in the green-emitting organic EL device 10G is less than 40 nm. As a result, in the green-emitting organic EL device 10G of the organic EL display device 1A, in the green emitting layer 5G, the “maximum emission position” overlaps with a “zero-order interference position” viewed from the light reflection layer 2, resulting in a small angular dependency of the emission color and an improvement in the light extraction efficiency.

Further, as for the blue-emitting organic EL device 106, the angular dependency of the emission color is small and the light extraction efficiency is improved in the same manner as in the explanation of the first exemplary embodiment. It is also considered that the lifetime of the blue-emitting organic EL device 10B is improved in the same manner as in the explanation of the first exemplary embodiment.

### Third Exemplary Embodiment

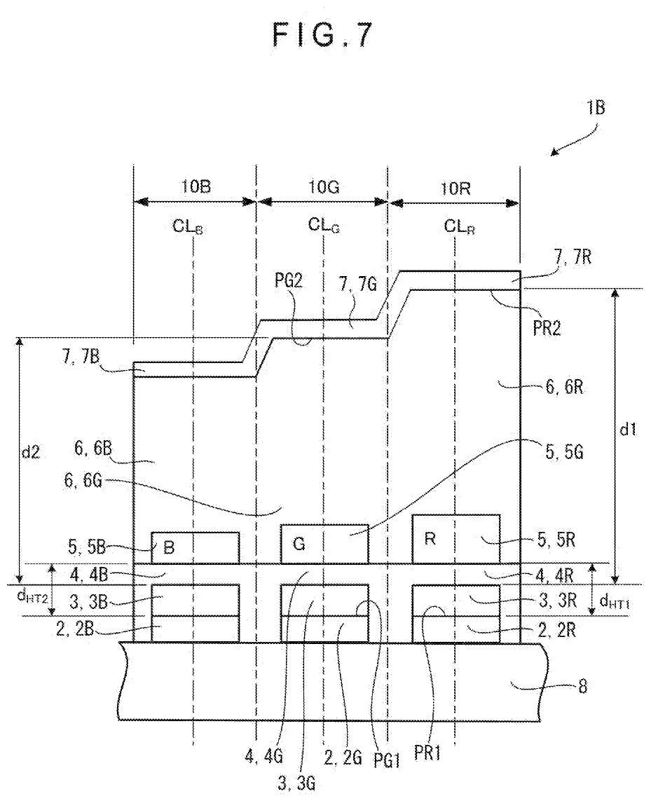

An arrangement of an example of an organic EL display device according to a third exemplary embodiment will be described with reference to FIG. 7.

FIG. 7 shows an organic EL display device 1B.

The organic EL display device 1B includes the blue-emitting organic EL device 10B, the green-emitting organic EL device 10G, and the red-emitting organic EL device 10R as pixels.

The organic EL display device 1B is different from the organic EL display device of the first exemplary embodiment or the second exemplary embodiment in having as pixels three types of organic EL devices, namely, the green-emitting organic EL device 10G of the second exemplary embodiment in addition to the blue-emitting organic EL device 10B and the red-emitting organic EL device 10R of the first exemplary embodiment, and is otherwise the same as in the first exemplary embodiment or the second exemplary embodiment. Accordingly, the same components as those in the first exemplary embodiment or the second exemplary embodiment are denoted by the same reference signs to simplify or omit an explanation of the components.

Each of the blue-emitting organic EL device 10B, the green-emitting organic EL device 10G, and the red-emitting organic EL device 10R includes the light reflection layer 2, transparent electrode 3, hole transporting zone 4, emitting layer 5, electron transporting zone 6, and semitransmissive electrode 7. The hole transporting zone 4, the emitting layer 5 and the electron transporting zone 6 are herein sometimes referred to as an organic layer.

Each of the blue-emitting organic EL device 10B, the green-emitting organic EL device 10G, and the red-emitting organic EL device 10R includes the light reflection layer 2, transparent electrode 3, hole transporting zone 4, emitting layer 5, electron transporting zone 6, and semitransmissive electrode 7 in this order. In the organic EL display device 1, the blue-emitting organic EL device 10B, the green-emitting organic EL device 10G, and the red-emitting organic EL device 10R as pixels are disposed in parallel on the substrate 8.

In each of the blue-emitting organic EL device 10B, the green-emitting organic EL device 10G, and the red-emitting organic EL device 10R in the organic EL display device 1B, the transparent electrode 3 is in direct contact with the hole transporting zone 4, the hole transporting zone 4 is in direct contact with the emitting layer 5, the emitting layer 5 is in direct contact with the electron transporting zone 6, and the electron transporting zone 6 is in direct contact with the semitransmissive electrode 7.

The organic EL display device 1B includes the blue-emitting organic EL device 10B as a blue pixel, the green-emitting organic EL device 10G as a green pixel, and the red-emitting organic EL device 10R as a red pixel. A voltage is applied to each pixel independently. In the organic EL display device 1B, the blue pixel, the green pixel and the red pixel can be selectively made emit light. The organic EL display device 1B may have, as one unit, a unit consisting of three pixels, that is, one each of the blue pixel, the green pixel, and the red pixel. The organic EL display device 1B may have a plurality of the units. In this case, the plurality of the units each consisting of the blue pixel, the green pixel, and the red pixel may be repeatedly arranged on the substrate. Alternatively, each pixel in each unit may be plural. For example, four pixels including one blue pixel, one green pixel, and two red pixels may form one unit. It should be noted that the organic EL display device of the invention may have a pixel emittable in a color other than the blue pixel, the green pixel, and the red pixel.

The organic EL display device 1B include the blue-emitting organic EL device 10B, the green-emitting organic EL device 10G, and the red-emitting organic EL device 10R, which are the same as the blue-emitting organic EL device 10B, the green-emitting organic EL device 10G, and the red-emitting organic EL device 10R described in the first exemplary embodiment or the second exemplary embodiment, the explanation thereof is omitted or simplified below.

The green emitting layer 5G contains the delayed fluorescent compound DF_{G}. The red emitting layer 5R contains the delayed fluorescent compound DF_{R}.

The film thickness of the red emitting layer 5R is less than 50 nm. The film thickness of the green emitting layer 5G is less than 40 nm.

In the organic EL display device 1B, the film thickness of the red emitting layer 5R is larger than the film thickness of the green emitting layer 5G and the film thickness of the green emitting layer 5G is larger than the film thickness of the blue emitting layer 5B.

In the organic EL display device 1B according to the exemplary embodiment, each of the green-emitting organic EL device 10G and the red-emitting organic EL device 10R has a resonator structure whose order of interference is the first-order between the light reflection layer 2 and the semitransmissive electrode 7. Specifically, the red-emitting organic EL device 10R has a resonator structure whose order of interference is first-order between the light reflection layer 2R and the semitransmissive electrode 7R. A distance d1 between the light reflection layer 2R and the semitransmissive electrode 7R in the red-emitting organic EL device 10R corresponds to a sum of a thickness of the hole transporting zone 4R, a thickness of the red emitting layer 5R, and a thickness of the electron transporting zone 6R. The green-emitting organic EL device 10G has a resonator structure whose order of interference is the first-order between the light reflection layer 2G and the semitransmissive electrode 7G. A distance d2 between the light reflection layer 2G and the semitransmissive electrode 7G in the green-emitting organic EL device 10G corresponds to a sum of a thickness of the hole transporting zone 4G, a thickness of the green emitting layer 5G, and a thickness of the electron transporting zone 6G.

In the organic EL display device 1B according to the exemplary embodiment, each of the green-emitting organic EL device 10G and the red-emitting organic EL device 10R has a resonator structure. In the description of the above resonator structure in the first exemplary embodiment, as for the green-emitting organic EL device 10G and the red-emitting organic EL device 10R each having the resonator structure, the organic EL display device 1, the light reflection layer 2, the semitransmissive electrode 7, the hole transporting zone 4, the emitting layer 5, and the electron transporting zone 6 can be read as the organic EL display device 1B, the light reflection layer 2G or the light reflection layer 2R, the semitransmissive electrode 7G or the semitransmissive electrode 7R, the hole transporting zone 4G or the hole transporting zone 4R, the green emitting layer 5G or the red emitting layer 5R, and the electron transporting zone 6G or electron transporting zone 6R, respectively.

As shown in FIG. 7, a reflection end surface of the light reflection layer 2G close to the green emitting layer 5G in the green-emitting organic EL device 10G was defined as a first end PG1, a reflection end surface of the semitransmissive electrode 7G close to the green emitting layer 5G was defined as a second end PG2, a reflection end surface of the light reflection layer 2R close to the red emitting layer 5R in the red-emitting organic EL device 10R was defined as a first end PR1, and a reflection end surface of the semitransmissive electrode 7R close to the red emitting layer 5R was defined as a second end PR2. In the description of the resonator structure in the first exemplary embodiment: as for the green-emitting organic EL device 10G, the first end P1 and the second end P2 can be read and applied as the first end PG1 and the second end PG2; and as for the red-emitting organic EL device 10R, the first end P1 and the second end P2 can be read and applied as the first end PR1 and the second end PR2.

### Hole Transporting Zone

In the organic EL display device 1B, the hole transporting zone 4 is provided at a constant film thickness in a shared manner across the blue-emitting organic EL device 10B, the green-emitting organic EL device 10G, and the red-emitting organic EL device 10R.

In the organic EL display device 1B, the film thickness of the hole transporting zone 4 is preferably in a range from 10 nm or more and less than 25 nm, more preferably in a range from 10 nm to 20 nm. Specifically, in the organic EL display device 1B, it is preferable that the film thickness of the hole transporting zone 4B in the blue-emitting organic EL device 10B is 10 nm or more and less than 25 nm, the film thickness of the hole transporting zone 4G in the green-emitting organic EL device 10G is 10 nm or more and less than 25 nm, and the film thickness of the hole transporting zone 4R in the red-emitting organic EL device 10R is 10 nm or more and less than 25 nm, and it is more preferable that the film thickness of the hole transporting zone 4B is in a range from 10 nm to 20 nm, the film thickness of the hole transporting zone 4G is in a range from 10 nm to 20 nm, and the film thickness of the hole transporting zone 4R is in a range from 10 nm to 20 nm.

The film thickness of the hole transporting zone 4 in the organic EL display device 1B can be measured by the above-described “Measurement Method of Film Thickness of Layer or Zone” in the first exemplary embodiment.

In the organic EL display device 1B, the sum of the film thickness of the transparent electrode 3 and the film thickness of the hole transporting zone 4 in each of the blue-emitting organic EL device 10B, the green-emitting organic EL device 10G, and the red-emitting organic EL device 10R is less than 40 nm. Specifically, the sum of the film thickness of the transparent electrode 3B and the film thickness of the hole transporting zone 4B in the blue-emitting organic EL device 10B is less than 40 nm, the sum of the film thickness of the transparent electrode 3G and the film thickness of the hole transporting zone 4G in the green-emitting organic EL device 10G is less than 40 nm, and the sum of the film thickness of the transparent electrode 3R and the film thickness of the hole transporting zone 4R in the red-emitting organic EL device 10R is less than 40 nm. The sum of the film thickness of the transparent electrode 3 and the film thickness of the hole transporting zone 4 is denoted by d_{HT1} or d_{HT2} in FIG. 7.

That the sum of the film thickness of the transparent electrode 3 and the film thickness of the hole transporting zone 4 in each of the blue-emitting organic EL device 10B, the green-emitting organic EL device 10G, and the red-emitting organic EL device 10R is less than 40 nm can improve the viewing angle.

The sum of the film thickness of the transparent electrode 3 and the film thickness of the hole transporting zone 4 in each of the blue-emitting organic EL device 10B, the green-emitting organic EL device 10G, and the red-emitting organic EL device 10R is preferably 15 nm or more. Specifically, it is preferable that the sum of the film thickness of the transparent electrode 3B and the film thickness of the hole transporting zone 4B in the blue-emitting organic EL device 10B is 15 nm or more, the sum of the film thickness of the transparent electrode 3G and the film thickness of the hole transporting zone 4G in the green-emitting organic EL device 10G is 15 nm or more, and the sum of the film thickness of the transparent electrode 3R and the film thickness of the hole transporting zone 4R in the red-emitting organic EL device 10R is 15 nm or more.

The hole transporting zone 4 in the organic EL display device 1B is also preferably formed of only a single layer.

The hole transporting zone 4 in the organic EL display device 1B is also preferably formed of a plurality of layers.

Examples of layers forming the hole transporting zone 4 in the organic EL display device 1B includes a hole injecting layer, a hole transporting layer, and an electron blocking layer.

When the hole transporting zone 4 in the organic EL display device 1B includes a plurality of layers, each layer of the hole transporting zone 4 is a common layer provided at a constant film thickness in a shared manner across the blue-emitting organic EL device 10B, the green-emitting organic EL device 10G, and the red-emitting organic EL device 10R. When the hole transporting zone 4 includes a plurality of layers, all the plurality of layers of the hole transporting zone 4 also preferably contain the same compound.

### Other Arrangements

Since the light reflection layer 2, the transparent electrode 3, the electron transporting zone 6, the semitransmissive electrode 7, and the capping layer in the organic EL display device 1B are respectively the same as the light reflection layer 2, the transparent electrode 3, the electron transporting zone 6, the semitransmissive electrode 7, and the capping layer in the first exemplary embodiment or the second exemplary embodiment, the explanation of those will be omitted or simplified.

Also in the exemplary embodiment, the light reflection layer 2 is preferably a non-common layer. Specifically, the light reflection layer 2R, the light reflection layer 2G, and the light reflection layer 2B are each preferably a non-common layer.

Also in the exemplary embodiment, the transparent electrode 3 is preferably a non-common layer. Specifically, the transparent electrode 3R, the transparent electrode 3G, and the transparent electrode 3B are each preferably a non-common layer. When the transparent electrode 3R, the transparent electrode 3G, and the transparent electrode 3B are each a non-common layer, the transparent electrode 3R, the transparent electrode 3G, and the transparent electrode 3B are each independently preferably in a range from 5 nm to 15 nm.

In the exemplary embodiment, it is preferable that the film thickness of the electron transporting zone 6 (electron transporting zone 6B) in the blue-emitting organic EL device 10B is smaller than the film thickness of the electron transporting zone 6 (electron transporting zone 6G) in the green-emitting organic EL device 10G, and the film thickness of the electron transporting zone 6 (electron transporting zone 6G) in the green-emitting organic EL device 10G is smaller than the film thickness of the electron transporting zone 6 (electron transporting zone 6R) in the red-emitting organic EL device 10R. The film thickness of each of the electron transporting zone 6B, the electron transporting zone 6G, and the electron transporting zone 6R can be measured in the same manner as the measurement method of the film thickness of the hole transporting zone 4.

Also in the exemplary embodiment, the electron transporting zone 6 may be formed of a single layer or a plurality of layers. Specifically, the electron transporting zone 6R in the red-emitting organic EL device 10R may be a zone formed of a single layer or a zone formed of a plurality of layers. The electron transporting zone 6G in the green-emitting organic EL device 10G may be a zone formed of a single layer or a zone formed of a plurality of layers. The electron transporting zone 6B in the blue-emitting organic EL device 10B may be a zone formed of a single layer or a zone formed of a plurality of layers.

It is preferable in the exemplary embodiment that the semitransmissive electrode 7 is a common layer provided in a shared manner across a plurality of organic EL devices (the red-emitting organic EL device, the green-emitting organic EL device, and the blue-emitting organic EL device). Specifically, the semitransmissive electrode 7R, the semitransmissive electrode 7G, and the semitransmissive electrode 7B are preferably the common layer in the organic EL display device 1B.

The organic EL display device 1B can be manufactured by substantially the same method as that of the organic EL display device 1 in the first exemplary embodiment except that the green-emitting organic EL device 10G is further formed in the same manner as in the second exemplary embodiment. Accordingly, the explanation of the method is omitted.

According to the exemplary embodiment, the organic EL display device 1B having an improved light extraction efficiency without decreasing the production efficiency, a small angular dependency of the emission color, and a long lifetime of the blue-emitting organic EL device as a pixel can be provided.

In the organic EL display device 1B, the hole transporting zone 4 is provided at a constant film thickness in a shared manner across the blue-emitting organic EL device 10B, the green-emitting organic EL device 10G, and the red-emitting organic EL device 10R. Accordingly, the organic EL display device 1B can be manufactured without increasing the frequency of the masking as in the device B.

Further, the green emitting layer 5G of the green-emitting organic EL device 10G contains the delayed fluorescent compound DF_{G}. The green-emitting organic EL device 10G has a resonator structure whose order of interference is the first order. The film thickness of the green emitting layer 5G is less than 40 nm. A sum of the film thickness of the transparent electrode 3G and the film thickness of the hole transporting zone 4G in the green-emitting organic EL device 10G is less than 40 nm. As a result, in the green-emitting organic EL device 10G of the organic EL display device 1B, in the green emitting layer 5G, the “maximum emission position” overlaps with a “zero-order interference position” viewed from the light reflection layer 2, resulting in a small angular dependency of the emission color and an improvement in the light extraction efficiency.

Further, the red emitting layer 5R of the red-emitting organic EL device 10R contains the delayed fluorescent compound DF_{R}. The red-emitting organic EL device 10R has a resonator structure whose order of interference is the first order. The film thickness of the red emitting layer 5R is less than 50 nm. A sum of the film thickness of the transparent electrode 3R and the film thickness of the hole transporting zone 4R in the red-emitting organic EL device 10R is less than 40 nm. As a result, in the red-emitting organic EL device 10R of the organic EL display device 1, in the red emitting layer 5R, the “maximum emission position” overlaps with a “zero-order interference position” viewed from the light reflection layer 2, resulting in a small angular dependency of the emission color and an improvement in the light extraction efficiency.

Further, as for the blue-emitting organic EL device 10B, the angular dependency of the emission color is small and the light extraction efficiency is improved in the same manner as in the explanation of the first exemplary embodiment. It is also considered that the lifetime of the blue-emitting organic EL device 10B is improved in the same manner as in the explanation of the first exemplary embodiment.

### Fourth Exemplary Embodiment

An organic EL display device according to a fourth exemplary embodiment is different from the organic EL device according to the third exemplary embodiment in that the red emitting layer 5R further contains a compound SH_{R}. The organic EL display device according to the fourth exemplary embodiment is otherwise the same as those in the first exemplary embodiment and the third exemplary embodiment.

The compound SH_{R} is a compound different from the delayed fluorescent compound DF_{R} and the fluorescent compound FL_{R}. In this exemplary embodiment, the fluorescent compound FL_{R} is preferably a dopant material and the delayed fluorescent compound DF_{R} is preferably a host material.

It is preferable that singlet energy S₁(DF_{R}) of the delayed fluorescent compound DF_{R} and singlet energy S1(SH_{R}) of the compound SH_{R} preferably satisfy a relationship of a numerical formula (Numerical Formula 1B).

S₁(SH_{R})>S₁(DF_{R}) (Numerical Formula 1B)

The singlet energy S₁(DF_{R}) of the delayed fluorescent compound DF_{R}, the singlet energy S₁(FL_{R}) of the fluorescent compound FL_{R}, and the singlet energy S₁(SH_{R}) of the compound SH_{R} more preferably satisfy a relationship of a numerical formula (Numerical Formula 1C).

S₁(SH_{R})>S₁(DF_{R})>S₁(FL_{R}) (Numerical Formula 1C)

The compound SH_{R} may be a delayed fluorescent compound or a compound that does not exhibit delayed fluorescence.

The compound SH_{R}, which is not particularly limited, is preferably a compound other than an amine compound. Although the compound SH_{R} may be, for instance, a derivative selected from the group consisting of a carbazole derivative, dibenzofuran derivative, and dibenzothiophene derivative, the compound SH_{R} is not limited to the derivatives.

In the red emitting layer 5R, an electron affinity level Af(DF_{R}) of the delayed fluorescent compound DF_{R} and an electron affinity level Af(SH_{R}) of the compound SH_{R} preferably satisfy a relationship of a numerical formula (Numerical Formula 1D).

Af(SH_{R})<Af(DF_{R}) (Numerical Formula 1D)

With the numerical formula (Numerical Formula 1D) being satisfied, it is considered that electrons injected into the red emitting layer 5R are trapped by the delayed fluorescent compound DF_{R}, causing the recombination region in the red emitting layer 5R to be likely to be localized close to the electron transporting zone 6R.

In the red emitting layer 5R, an energy gap T_{77K}(SH_{R}) at 77K of the compound SH_{R} is preferably larger than an energy gap T_{77K}(FL_{R}) at 77K of the fluorescent compound FL_{R}.

In the red emitting layer, the energy gap T_{77K}(SH_{R}) at 77K of the compound SH_{R} is preferably larger than an energy gap T_{77K}(DF_{R}) at 77K of the delayed fluorescent compound DF_{R}.

In the red emitting layer 5R, the compound SH_{R}, the delayed fluorescent compound DF_{R}, and the fluorescent compound FL_{R} preferably satisfy a relationship of a numerical formula (Numerical Formula 1E).

T_{77K}(SH_{R})>T_{77K}(DF_{R})>T_{77K}(FL_{R}) (Numerical Formula 1E)

When the organic EL device of the exemplary embodiment emits light, it is preferable that the dopant material contained in each emitting layer mainly emits light.

When the emitting layer is the red emitting layer, it is preferable that the fluorescent compound FL_{R} contained in the red emitting layer mainly emits light.

### Content Ratio of Compound in Red Emitting Layer

In the red emitting layer 5R of the organic EL display device of the exemplary embodiment, the content ratio of the fluorescent compound FL_{R} is preferably in a range from 0.01 mass % to 10 mass %, more preferably in a range from 0.01 mass % to 5 mass %, further preferably in a range from 0.01 mass % to 1 mass %.

The content ratio of the delayed fluorescent compound DF_{R} is preferably in a range from 10 mass % to 80 mass %, more preferably in a range from 10 mass % to 60 mass %, further preferably in a range from 20 mass % to 60 mass %.

The content ratio of the compound SH_{R} is preferably in a range from 10 mass % to 80 mass %.

The upper limit of the total content ratio of the fluorescent compound FL_{R}, the delayed fluorescent compound DF_{R}, and the compound SH_{R} in the red emitting layer is 100 mass %. It should not be excluded that in the exemplary embodiment, the red emitting layer may contain a material other than the fluorescent compound FL_{R}, the delayed fluorescent compound DF_{R}, and the compound SH_{R}.

The red emitting layer 5R may contain a single type of the fluorescent compound FL_{R} or may contain two or more types of the fluorescent compound FL_{R}. The red emitting layer 5R may contain a single type of the delayed fluorescent compound DF_{R} or may contain two or more types of the delayed fluorescent compound DF_{R}. The red emitting layer 5R may contain a single type of the compound SH_{R} or may contain two or more types of the compound SH_{R}.

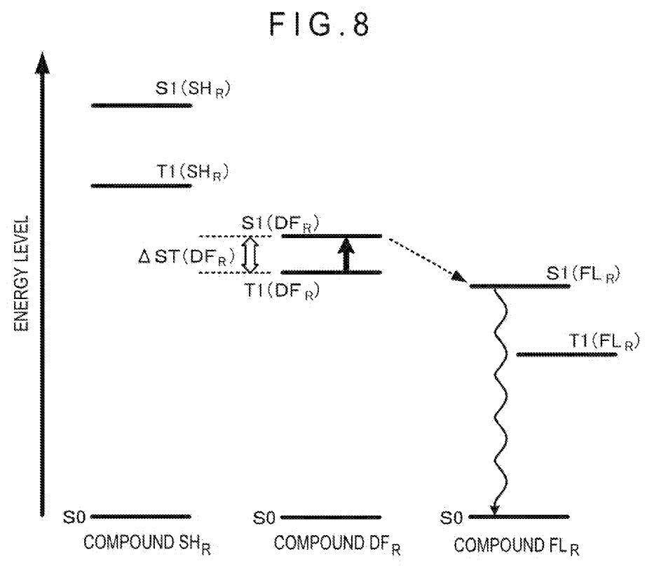

FIG. 8 shows an example of a relationship between energy levels of the fluorescent compound FL_{R}, the delayed fluorescent compound DF_{R}, and the compound SH_{R} in the red emitting layer 5R.

Symbols in FIG. 8 are described as follows.

S0 represents a ground state.

S1(FL_{R}) represents the lowest singlet state of the compound FL_{R}.

T1(FL_{R}) represents the lowest triplet state of the compound FL_{R}.

S1(DF_{R}) represents the lowest singlet state of the compound DF_{R}.

T1(DF_{R}) represents the lowest triplet state of the compound DF_{R}.

S1(SH_{R}) represents the lowest singlet state of the compound SH_{R}.

T1(SH_{R}) represents the lowest triplet state of the compound SH_{R}.

A dashed arrow directed from S1(DF_{R}) to S1(FL_{R}) in FIG. 8 represents Förster energy transfer from the lowest singlet state of the delayed fluorescent compound DF_{R} to the lowest singlet state of the fluorescent compound FL_{R}.

As shown in FIG. 8, when a compound having a small ΔST(DF_{R}) is used as the delayed fluorescent compound DF_{R}, inverse intersystem crossing from the lowest triplet state T1(DF_{R}) to the lowest singlet state S1(DF_{R}) can be caused by a heat energy. Subsequently, Forster energy transfer from the lowest singlet state S1(DF_{R}) of the delayed fluorescent compound DF_{R} to the fluorescent compound FL_{R} occurs to generate the lowest singlet state S1(FL_{R}). Consequently, fluorescence from the lowest singlet state S1(FL_{R}) of the fluorescent compound FL_{R} can be observed. It is inferred that the internal quantum efficiency can be theoretically raised up to 100% also by using delayed fluorescence by the TADF mechanism.

The organic EL device according to the fourth exemplary embodiment can further improve a luminous efficiency in addition to the effects produced in the first exemplary embodiment and the third exemplary embodiment.

### Fifth Exemplary Embodiment

An organic EL display device according to a fifth exemplary embodiment is different from the organic EL devices according to the second, third, and fourth exemplary embodiments in that the green emitting layer 5G further contains a compound SH_{G}. The organic EL display device according to the fourth exemplary embodiment is otherwise the same as those in the second, third, and fourth exemplary embodiments.

The compound SH_{G} is a compound different from a delayed fluorescent compound DF_{G} and a fluorescent compound FL_{G}. In this exemplary embodiment, the fluorescent compound FL_{G} is preferably a dopant material and the delayed fluorescent compound DF_{G} is preferably a host material.

It is preferable that singlet energy S₁(DF_{G}) of the delayed fluorescent compound DF_{G} and singlet energy S₁(SH_{G}) of the compound SH_{G} preferably satisfy a relationship of a numerical formula (Numerical Formula 2B).

S₁(SH_{G})>S₁(DF_{G}) (Numerical Formula 2B)

The singlet energy S₁(DF_{G}) of the delayed fluorescent compound DF_{G}, the singlet energy S₁(FL_{G}) of the fluorescent compound FL_{G}, and the singlet energy S₁(SH_{G}) of the compound SH_{G} more preferably satisfy a relationship of a numerical formula (Numerical Formula 2C).

S₁(SH_{G})>S₁(DF_{G})>S₁(FL_{G}) (Numerical Formula 2C)

The compound SH_{G} may be a delayed fluorescent compound or a compound that does not exhibit delayed fluorescence.

The compound SH_{G}, which is not particularly limited, is preferably a compound other than an amine compound. Although the compound SH_{G} may be, for instance, a derivative selected from the group consisting of a carbazole derivative, dibenzofuran derivative, and dibenzothiophene derivative, the compound SH_{G} is not limited to the derivatives.

In the green emitting layer 5G, an electron affinity level Af(DF_{G}) of the delayed fluorescent compound DF_{G} and an electron affinity level Af(SH_{G}) of the compound SH_{G} preferably satisfy a relationship of a numerical formula (Numerical Formula 2D).

Af(SH_{G})<Af(DF_{G}) (Numerical Formula 2D)

With the numerical formula (Numerical Formula 2D) being satisfied, it is considered that electrons injected into the green emitting layer 5G are trapped by the delayed fluorescent compound DF_{G}, causing the recombination region in the green emitting layer 5G to be likely to be localized close to the electron transporting zone 6G.

In the green emitting layer 5G, an energy gap T_{77K}(SH_{G}) at 77K of the compound SH_{G} is preferably larger than an energy gap T_{77K}(FL_{G}) at 77K of the fluorescent compound FL_{G}.

In the green emitting layer, the energy gap T_{77K}(SH_{G}) at 77K of the compound SH_{G} is preferably larger than an energy gap T_{77K}(DF_{G}) at 77K of the delayed fluorescent compound DF_{G}.

In the green emitting layer 5G, the compound SH_{G}, the delayed fluorescent compound DF_{G}, and the fluorescent compound FL_{G} preferably satisfy a relationship of a numerical formula (Numerical Formula 2E).

T_{77K}(SH_{G})>T_{77K}(DF_{G})>T_{77K}(FL_{G}) (Numerical Formula 2E)

When the organic EL device of the exemplary embodiment emits light, it is preferable that the dopant material contained in each emitting layer mainly emits light.

When the emitting layer is the green emitting layer, it is preferable that the fluorescent compound FL_{G} contained in the green emitting layer mainly emits light.

### Content Ratio of Compound in Green Emitting Layer

In the green emitting layer 5G of the organic EL display device of the exemplary embodiment, the content ratio of the fluorescent compound FL_{G} is preferably in a range from 0.01 mass % to 10 mass %, more preferably in a range from 0.01 mass % to 5 mass %, further preferably in a range from 0.01 mass % to 1 mass %.

The content ratio of the delayed fluorescent compound DF_{G} is preferably in a range from 10 mass % to 80 mass %, more preferably in a range from 10 mass % to 60 mass %, further preferably in a range from 20 mass % to 60 mass %.

The content ratio of the compound SH_{G} is preferably in a range from 10 mass % to 80 mass %.

The upper limit of the total content ratio of the fluorescent compound FL_{G}, the delayed fluorescent compound DF_{G}, and the compound SH_{G} in the green emitting layer is 100 mass %. It should not be excluded that in the exemplary embodiment, the green emitting layer may contain a material other than the fluorescent compound FL_{G}, the delayed fluorescent compound DF_{G}, and the compound SH_{G}.

The green emitting layer 5G may contain a single type of the fluorescent compound FL_{G} or may contain two or more types of the fluorescent compound FL_{G}. The green emitting layer 5G may contain a single type of the delayed fluorescent compound DF_{G} or may contain two or more types of the delayed fluorescent compound DF_{G}. The green emitting layer 5G may contain a single type of the compound SH_{G} or may contain two or more types of the compound SH_{G}.

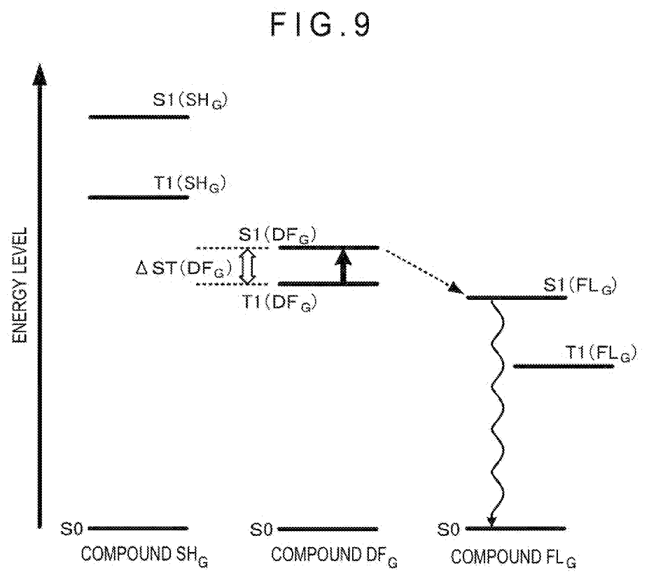

FIG. 9 shows an example of a relationship between energy levels of the fluorescent compound FL_{G}, the delayed fluorescent compound DF_{G}, and the compound SH_{G} in the green emitting layer 5G.

Symbols in FIG. 9 are described as follows.

S0 represents a ground state.

S1(FL_{G}) represents the lowest singlet state of the compound FL_{G}.

T1(FL_{G}) represents the lowest triplet state of the compound FL_{G}.

S1(DF_{G}) represents the lowest singlet state of the compound DF_{G}.

T1(DF_{G}) represents the lowest triplet state of the compound DF_{G}.

S1(SH_{G}) represents the lowest singlet state of the compound SH_{G}.

T1(SH_{G}) represents the lowest triplet state of the compound SH_{G}.

Also in the green emitting layer of the green-emitting organic EL device according to the fifth exemplary embodiment, energy transfer as shown in FIG. 9 occurs in the same manner as in the red emitting layer of the red-emitting organic EL device according to the fourth exemplary embodiment. It is considered that the organic EL display device according to the fifth exemplary embodiment can also increase the internal quantum efficiency theoretically to 100% by using delayed fluorescence by the TADF mechanism.

The organic EL display device according to the fifth exemplary embodiment can further improve a luminous efficiency in addition to the effects produced in the second, third, and fourth exemplary embodiments.

### Sixth Exemplary Embodiment

### Electronic Device

An electronic device according to the exemplary embodiment is installed with the organic EL display device according to one of the above exemplary embodiments. Examples of the electronic device include a display component (e.g., an organic EL panel module), TV, mobile phone, tablet and personal computer. Moreover, the organic EL display device is also usable as a light-emitting unit serving as the electronic device. Examples of the light-emitting unit include an illuminator and a vehicle light.

### Compound Used in Emitting Layer of Organic EL Display Device

The compound used in the emitting layer of the organic EL display device will be described.

### Delayed Fluorescent Compound

Any compound exhibiting delayed fluorescence is usable as the delayed fluorescent compound.

The delayed fluorescent compound is exemplified by a compound represented by a formula (1) below.

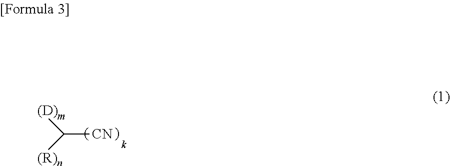

In the formula (1): L is a substituted or unsubstituted aromatic hydrocarbon group having 6 to 30 ring carbon atoms, or a substituted or unsubstituted aromatic heterocyclic group having 5 to 30 ring atoms;

CN is a cyano group;

k is an integer of 1 or more and represents the number of a cyano group bonded to L;

D is a group represented by a formula (10) or a formula (11) below;

m is an integer of 1 or more and represents the number of D bonded to L;

when m is an integer of 2 or more, a plurality of D are mutually the same or different;

R is a hydrogen atom or a substituent, or a pair of adjacent ones of R are bonded to each other to form a ring;

n is 0 or an integer of 1 or more and represents the number of R bonded to L;

when n is an integer of 2 or more, a plurality of R are mutually the same or different;

R serving as a substituent is a halogen atom, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkyl halide group having 1 to 30 carbon atoms, a substituted or unsubstituted alkylsilyl group having 3 to 30 carbon atoms, or a substituted or unsubstituted arylsilyl group having 6 to 60 ring carbon atoms; and R serving as a substituted or unsubstituted heterocyclic group having 5 to 30 ring atoms is a pyridyl group, pyrimidinyl group, pyrazinyl group, pyridazynyl group, triazinyl group, quinolyl group, isoquinolinyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, isoindolyl group, benzimidazolyl group, indazolyl group, imidazopyridinyl group, benzotriazolyl group, furyl group, thienyl group, oxazolyl group, thiazolyl group, isoxazolyl group, isothiazolyl group, oxadiazolyl group, thiadiazolyl group, benzofuranyl group, benzothienyl group, benzoxazolyl group, benzothiazolyl group, benzoisoxazolyl group, benzoisothiazolyl group, benzooxadiazolyl group, benzothiadiazolyl group, dibenzofuranyl group, dibenzothienyl group, piperidinyl group, pyrrolidinyl group, piperazinyl group, morpholyl group, phenazinyl group, phenothiazinyl group, or phenoxazinyl group.

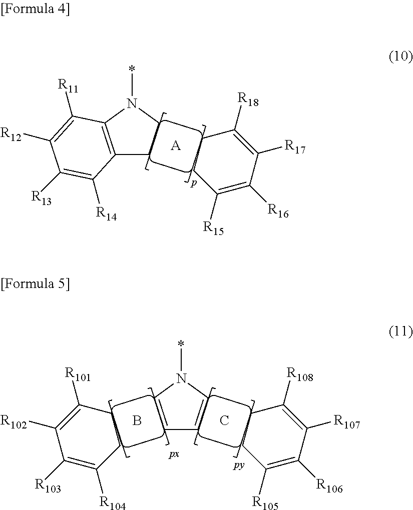

In the formula (10):

R₁₁ to R₁₈ are each independently a hydrogen atom or a substituent, or at least one pair of a pair of R₁₁ and R₁₂, a pair of R₁₂ and R₁₃, a pair of R₁₃ and R₁₄, a pair of R₁₅ and R₁₆, a pair of R₁₆ and R₁₇, and a pair of R₁₇ and R₁₈ are bonded to each other to form a ring;

R₁₁ to R₁₈ serving as a substituent are each independently a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkyl halide group having 1 to 30 carbon atoms, a substituted or unsubstituted alkylsilyl group having 3 to 30 carbon atoms, a substituted or unsubstituted arylsilyl group having 6 to 60 ring carbon atoms, a substituted or unsubstituted alkoxy group having 1 to 30 carbon atoms, a substituted or unsubstituted aryloxy group having 6 to 30 ring carbon atoms, a substituted or unsubstituted alkylamino group having 2 to 30 carbon atoms, a substituted or unsubstituted arylamino group having 6 to 60 ring carbon atoms, a substituted or unsubstituted alkylthio group having 1 to 30 carbon atoms, or a substituted or unsubstituted arylthio group having 6 to 60 ring carbon atoms;

A is a cyclic structure represented by a formula (10a) or a formula (10b) below;

the cyclic structure A can be fused to an adjacent cyclic structure;

p is 0, 1, 2, 3 or 4 and represents the number of the cyclic structure A;

when p is 2, 3 or 4, a plurality of cyclic structures A are mutually the same or different; and

* represents a bonding position to L in the formula (1).

In the formula (11):

R₁₀₁ to R₁₀₈ are each independently a hydrogen atom or a substituent, or at least one pair of a pair of R₁₀₁ and R₁₀₂, a pair of R₁₀₂ and R₁₀₃, a pair of R₁₀₃ and R₁₀₄, a pair of R₁₀₅ and R₁₀₆, a pair of R₁₀₆ and R₁₀₇, and a pair of R₁₀₇ and R₁₀₈ are bonded to each other to form a ring;

R₁₀₁ to R₁₀₈ serving as a substituent each independently represent the same as R₁₁ to R₁₈ serving as a substituent;

B and C are each independently the cyclic structure represented by the formula (10a) or the formula (10b) below;

the cyclic structure B can be fused to an adjacent cyclic structure;

px is 1, 2, 3 or 4 and represents the number of the cyclic structure B;

when px is 2, 3 or 4, a plurality of cyclic structures B are mutually the same or different;

the cyclic structure C can be fused to an adjacent cyclic structure;

py is 1, 2, 3 or 4 and represents the number of the cyclic structure C;

when py is 2, 3 or 4, a plurality of cyclic structures C are mutually the same or different; and

* represents a bonding position to L in the formula (1).

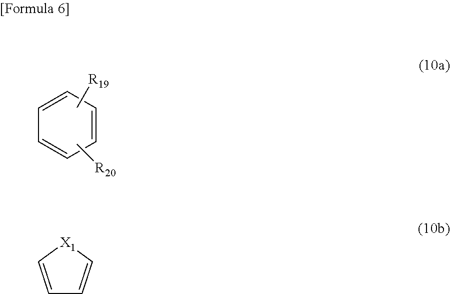

In the formula (10a):

R₁₉ and R₂₀ are each independently a hydrogen atom or a substituent, or a pair of R₁₀ and R₂₀ are bonded to each other to form a ring; and

R₁₉ and R₂₀ serving as a substituent each independently represent the same as R₁₁ to R₁₈ serving as a substituent.

In the formula (10b):

X₁ is CR₁₁₁R₁₁₂, NR₁₁₃, a sulfur atom, or an oxygen atom;

R₁₁₁ and R₁₁₂ are each independently a hydrogen atom or a substituent, or a pair of R₁₁₁ and R₁₁₂ are bonded to each other to form a ring;

R₁₁₃ is a hydrogen atom or a substituent; and

R₁₁₁, R₁₁₂ and R₁₁₃ serving as a substituent each independently represent the same as R₁₁ to R₁₈ serving as a substituent.

When p is 0 in the formula (10), the group represented by the formula (10) is represented by a formula (10A),

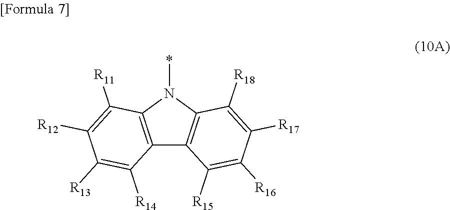

In the formula (10A), R₁₁ to R₁₈ each independently represent the same as R₁₁₁ to R₁₈ in the formula (10).

* represents a bonding position to L in the formula (1).

Specific examples of the delayed fluorescent compound are shown below. However, the invention is not limited to the specific examples.

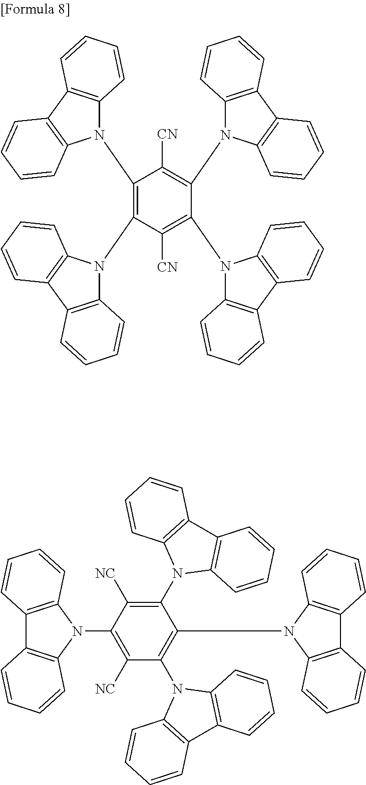 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

### Fluorescent Compound

Any compound exhibiting fluorescence, even if not exhibiting delayed fluorescence, is usable as the fluorescent compound.

The fluorescent compound used in at least one of the green emitting layer or the red emitting layer is exemplified by a compound represented by a formula (20).

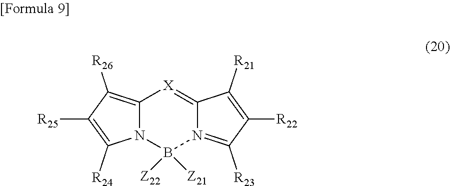

In the formula (20): X is a nitrogen atom, or a carbon atom bonded to Y;

Y is a hydrogen atom or a substituent;

R₂₁ to R₂₆ are each independently a hydrogen atom or a substituent, or at least one of a pair of R₂₁ and R₂₂, a pair of R₂₂ and R₂₃, a pair of R₂₄ and R₂₅, or a pair of R₂₅ and R₂₆ are mutually bonded to form a ring;

Y and R₂₁ to R₂₆ serving as the substituents are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted aralkyl group having 7 to 30 carbon atoms, a substituted or unsubstituted heteroaryl group having 5 to 30 ring atoms, a halogen atom, a carboxy group, a substituted or unsubstituted ester group, a substituted or unsubstituted carbamoyl group, a substituted or unsubstituted amino group, a nitro group, a cyano group, a substituted or unsubstituted silyl group, and a substituted or unsubstituted siloxanyl group;

Z₂₁ and Z₂₂ are each independently a substituent, or are mutually bonded to form a ring; and

Z₂₁ and Z₂₂ serving as the substituents are each independently selected from the group consisting of a halogen atom, a substituted or unsubstituted alkyl group having 1 to 30 carbon atoms, a substituted or unsubstituted alkyl halide group having 1 to 30 carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms.

Examples of the fluorescent compound include compounds shown below. However, the invention is not limited to the specific examples,

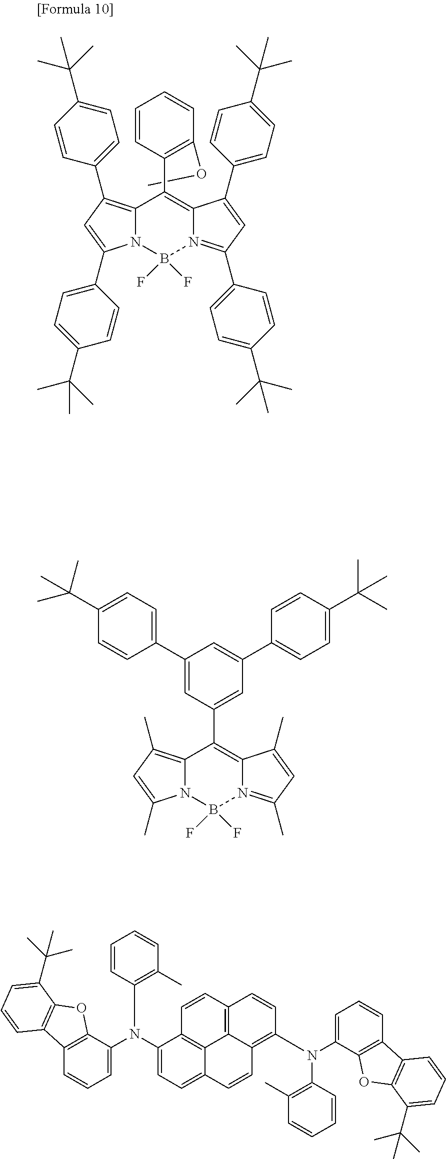

### Compound as Third Component

Examples of compound contained as a third component such as the compound SH_{R} and the compound SH_{G} and other than the delayed fluorescent compound and the fluorescent compound in the emitting layer include compounds shown below. However, the invention is not limited to the specific examples.

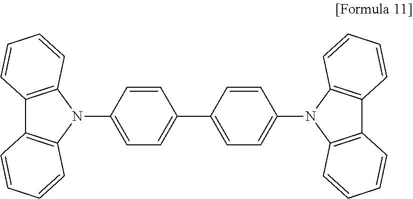 [SMILES: c1ccc2c(c1)c1ccccc1n2-c1ccc(-c2ccc(-n3c4ccccc4c4ccccc43)cc2)cc1]

### Other Explanations

Herein, the phrase “Rx and Ry are mutually bonded to form a ring” means, for instance, that Rx and Ry include a carbon atom, a nitrogen atom, an oxygen atom, a sulfur atom or a silicon atom, the atom(s) contained in Rx (a carbon atom, a nitrogen atom, an oxygen atom, a sulfur atom or a silicon atom) and the atom(s) contained in Ry (a carbon atom, a nitrogen atom, an oxygen atom, a sulfur atom or a silicon atom) are bonded via a single bond(s), a double bond(s), a triple bond, and/or a divalent linking group(s) to form a ring having 5 or more ring atoms (specifically, a heterocycle or an aromatic hydrocarbon ring). x represents a number, a character or a combination of a number and a character, y represents a number, a character or a combination of a number and a character.

The divalent linking group is not limited. Examples of the divalent linking group include —O—, —CO—, —CO₂—, —S—, —SO—, —SO₂—, —NH—, —NRa—, and a group provided by a combination of two or more of these linking group.

Specific examples of the heterocyclic ring include a cyclic structure (heterocyclic ring) obtained by removing a bond from a “heteroaryl group Sub₂” exemplarily shown in the later-described “Description of Each Substituent in Formula.” The heterocyclic ring may have a substituent.

Specific examples of the heterocyclic ring include cyclic structures (heterocyclic rings) obtained by removing a bond from an “aryl group Sub₂” exemplarily shown in the later-described “Description of Each Substituent in Formula.” The aromatic hydrocarbon ring may have a substituent.

Examples of Ra include a substituted or unsubstituted alkyl group Sub₃ having 1 to 30 carbon atoms, a substituted or unsubstituted aryl group Sub₁ having 6 to 30 ring carbon atoms, and a substituted or unsubstituted heteroaryl group Sub₂ having 5 to 30 ring atoms, which are exemplarily shown in the later-described “Description of Each Substituent in Formula,”

Rx and Ry are mutually bonded to form a ring, which means, for instance, that: an atom contained in Rx₁ and an atom contained in Ry₁ in a molecular structure represented by a formula (E1) below form a ring (cyclic structure) E represented by a formula (E2); an atom contained in Rx₁ and an atom contained in Ry in a molecular structure represented by a formula (F1) below form a ring (cyclic structure) F represented by a formula (F2); an atom contained in Rx₁ and an atom contained in Ry₁ in a molecular structure represented by a formula (G1) below form a ring (cyclic structure) G represented by a formula (G2); an atom contained in Rx₁ and an atom contained in Ry₁ in a molecular structure represented by a formula (H1) below form a ring (cyclic structure) H represented by a formula (H2); and an atom contained in Rx₁ and an atom contained in Rye in a molecular structure represented by a formula (11) below form a ring (cyclic structure) I represented by a formula (12).

In the formulae (E1) to (I1), * each independently represent a bonding position to another atom in a molecule. The two * in the formulae (E1), (F1), (G1), (H1) and (I1) correspond to two * in the formulae (E2), (F2), (G2), (H2) and (I2), respectively.

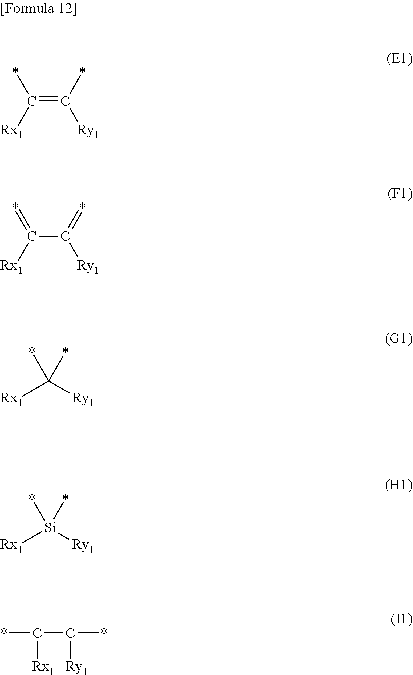

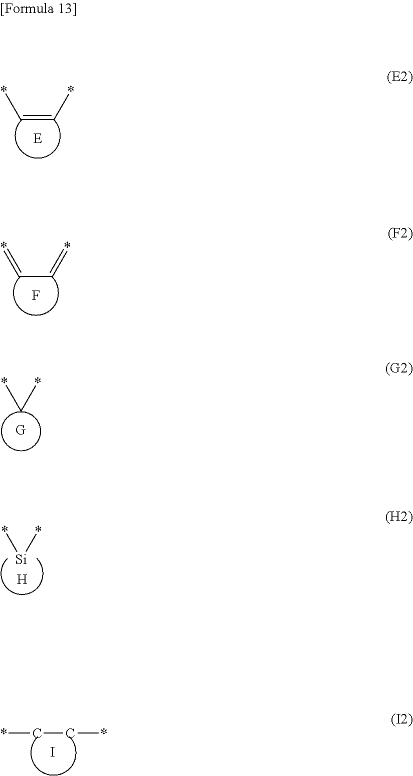

In the molecular structures represented by the formulae (E2) to (I2), E to I each represent a cyclic structure (the ring having 5 or more ring atoms). In the formulae (E2) to (I2), * each independently represent a bonding position to another atom in a molecule. The two * in the formula (E2) correspond to two * in the formula (E1). Similarly, two * in each of the formulae (F2) to (I2) correspond one-to-one to two * in in each of the formulae (F1) to (I1).

For instance, in the formula (E1), when Rx₁ and Ry₁ are mutually bonded to form the ring E in the formula (E2) and the ring E is an unsubstituted benzene ring, the molecular structure represented by the formula (E1) is a molecular structure represented by a formula (E3) below. Here, two * in the formula (E3) each independently correspond two * in the formulae (E2) and (E1).

For instance, in the formula (E1), when Rx₁ and Ry₁ are mutually bonded to form the ring E in the formula (E2) and the ring E is an unsubstituted pyrrole ring, the molecular structure represented by the formula (E1) is a molecular structure represented by a formula (E4) below. Here, two * in the formula (E4) each independently correspond two * in the formulae (E2) and (E1). In the formulae (E3) and (E4), * each independently represent a bonding position to another atom in a molecule.

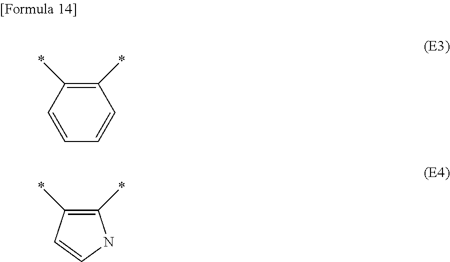 [SMILES: *c1ccccc1* ; *c1cc[nH]c1*]

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridinyl group has 5 ring carbon atoms, and a furanyl group has 4 ring carbon atoms. When a benzene ring and/or a naphthalene ring is substituted by a substituent (e.g., an alkyl group), the number of carbon atoms of the alkyl group is not counted in the number of the ring carbon atoms. When a fluorene ring is substituted by a substituent (e.g., a fluorene ring) (i.e., a spirofluorene ring is included), the number of carbon atoms of the fluorene ring as the substituent is not counted in the number of the ring carbon atoms of the fluorene ring.

Herein, the ring atoms refer to the number of atoms forming a ring of a compound (e.g., a monocyclic compound, fused-ring compound, crosslinking compound, carbon ring compound, and heterocyclic compound) in which the atoms are bonded to each other to form the ring (e.g., monocyclic ring, fused ring, ring assembly), Atom(s) not forming a ring and atom(s) included in a substituent when the ring is substituted by the substituent are not counted in the number of the ring atoms. Unless specifically described, the same applies to the “ring atoms” described later. For instance, a pyridine ring has six ring atoms, a quinazoline ring has ten ring atoms, and a furan ring has five ring atoms. A hydrogen atom(s) and/or an atom(s) of a substituent which are bonded to carbon atoms of a pyridine ring and/or quinazoline ring are not counted in the ring atoms. When a fluorene ring is substituted by a substituent (e.g., a fluorene ring) (i.e., a spirofluorene ring is included), the number of atoms of the fluorene ring as the substituent is not counted in the number of the ring atoms of the fluorene ring.

### Description of Each Substituent in Formulae

Next, each of substituents in formulae herein will be described.

The aryl group (occasionally referred to as an aromatic hydrocarbon group) herein is exemplified by an aryl group Sub₁. The aryl group Sub is at least one group selected from the group consisting of a phenyl group, biphenyl group, terphenyl group, naphthyl group, anthryl group, phenanthryl group, fluorenyl group, pyrenyl group, chrysenyl group, fluoranthenyl group, benz[a]anthryl group, benzo[c]phenanthryl group, triphenylenyl group, benzo[k]fluoranthenyl group, benzo[g]chrysenyl group, benzo[b]triphenylenyl group, picenyl group, and perylenyl group.

Herein, the aryl group Sub₁ preferably has 6 to 30 ring carbon atoms, more preferably 6 to 20 ring carbon atoms, further preferably 6 to 14 ring carbon atoms, further more preferably 6 to 12 ring carbon atoms. Among the aryl group Sub₁, a phenyl group, biphenyl group, naphthyl group, phenanthryl group, terphenyl group and fluorenyl group are preferable. A carbon atom in a position 9 of each of 1-fluorenyl group, 2-fluorenyl group, 3-fluorenyl group and 4-fluorenyl group is preferably substituted by a substituted or unsubstituted alkyl group Sub₃ or a substituted or unsubstituted aryl group Sub₁ described later herein.

The heteroaryl group (occasionally referred to as a heterocyclic group, heteroaromatic cyclic group or aromatic heterocyclic group) herein is exemplified by a heterocyclic group Sub₂. The heterocyclic group Sub₂ is a group containing, as a hetero atom(s), at least one atom selected from the group consisting of nitrogen, sulfur, oxygen, silicon, selenium atom and germanium atom. The heterocyclic group Sub₂ preferably contains, as a hetero atom(s), at least one atom selected from the group consisting of nitrogen, sulfur and oxygen.

The heterocyclic group Sub₂ herein are, for instance, at least one group selected from the group consisting of a pyridyl group, pyrimidinyl group, pyrazinyl group, pyridazinyl group, triazinyl group, quinolyl group, isoquinolinyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothienyl group, benzoxazolyl group, benzothiazolyl group, benzisoxazolyl group, benzisothiazolyl group, benzoxadiazolyl group, benzothiadiazolyl group, dibenzofuranyl group, dibenzothienyl group, piperidinyl group, pyrrolidinyl group, piperazinyl group, morpholyl group, phenazinyl group, phenothiazinyl group, and phenoxazinyl group.

Herein, the heterocyclic group Sub₂ preferably has 5 to 30 ring atoms, more preferably 5 to 20 ring atoms, further preferably 5 to 14 ring atoms. Among the above heterocyclic group Sub₂, a 1-dibenzofuranyl group, 2-dibenzofuranyl group, 3-dibenzofuranyl group, 4-dibenzofuranyl group, 1-dibenzothienyl group, 2-dibenzothienyl group, 3-dibenzothienyl group, 4-dibenzothienyl group, 1-carbazolyl group, 2-carbazolyl group, 3-carbazolyl group, 4-carbazolyl group, and 9-carbazolyl group are further more preferable. A nitrogen atom in position 9 of 1-carbazolyl group, 2-carbazolyl group, 3-carbazolyl group and 4-carbazolyl group is preferably substituted by the substituted or unsubstituted aryl group Sub₁ or the substituted or unsubstituted heterocyclic group Sub₂ described herein.

Herein, the heterocyclic group Sub₂ may be a group derived from any one of partial structures represented by formulae (XY-1) to (XY-18) below.

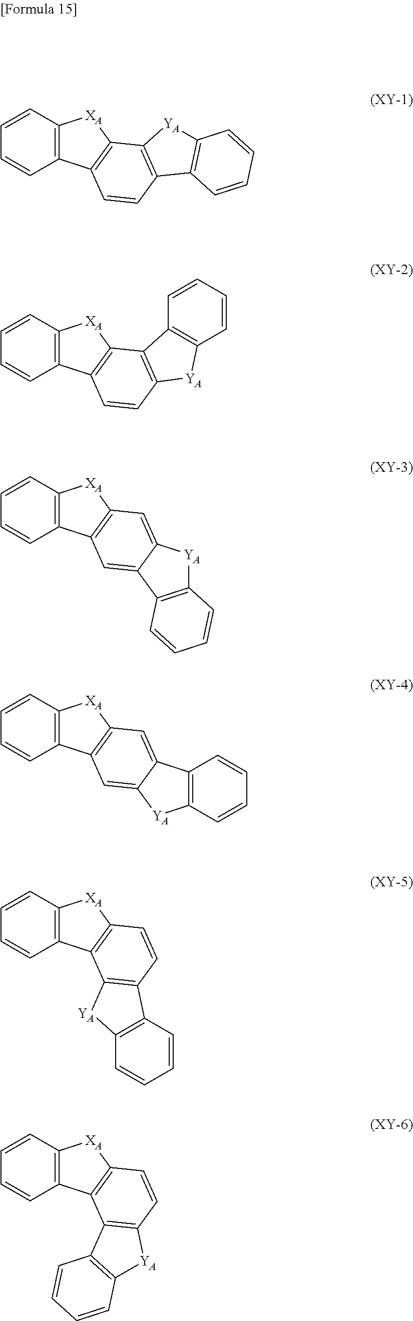

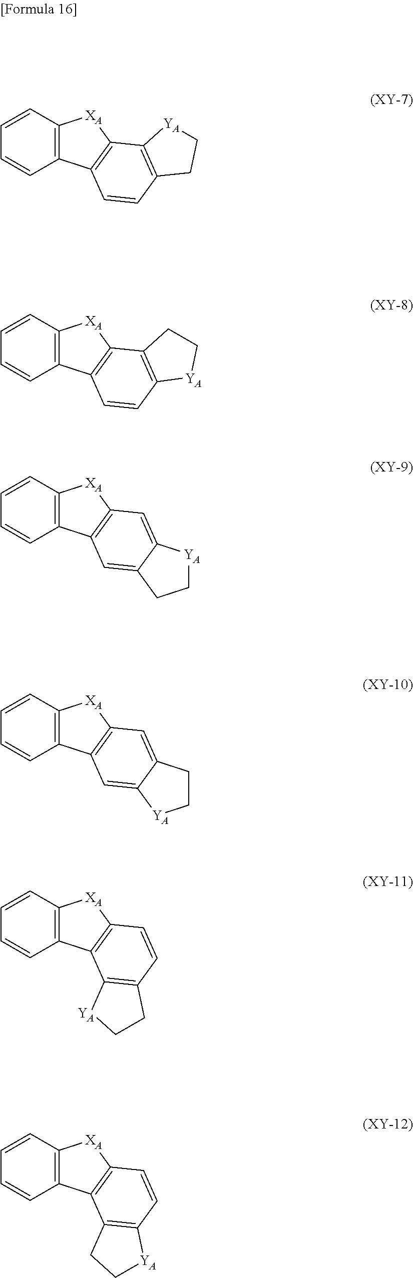

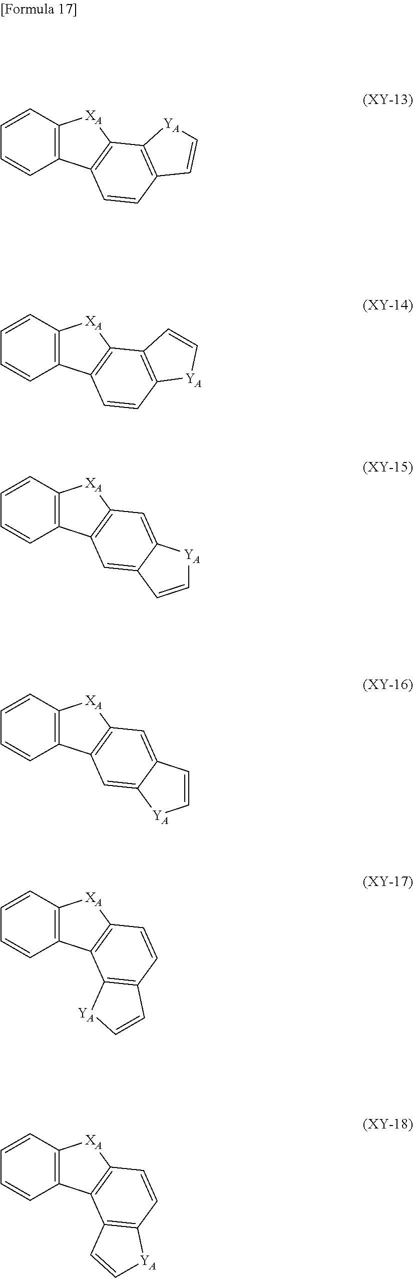

In the formulae (XY-1) to (XY-18), X_{A} and Y_{A} are each independently a hetero atom, preferably an oxygen atom, sulfur atom, selenium atom, silicon atom, or germanium atom. Each of the partial structures represented by the respective formulae (XY-1) to (XY-18) has a bond at any position to provide a heterocyclic group. The heterocyclic group may be substituted.

Herein, the heterocyclic group Sub₂ may be a group represented by one of formulae (XY-19) to (XY-22) below. Moreover, the position of the bond may be changed as needed.

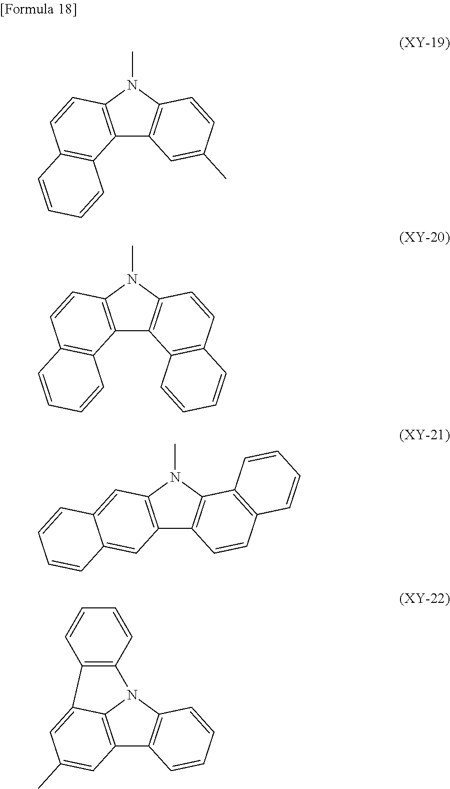

The alkyl group herein may be any one of a linear alkyl group, branched alkyl group and cyclic alkyl group.

The alkyl group herein is exemplified by an alkyl group Sub₃.

The linear alkyl group herein is exemplified by a linear alkyl group Sub₃₁.

The branched alkyl group herein is exemplified by a branched alkyl group Sub₃₂.

The cyclic alkyl group herein is exemplified by a cyclic alkyl group Sub₃₃.

For instance, the alkyl group Sub₃ is at least one group selected from the group consisting of the linear alkyl group Sub₃₁, branched alkyl group Sub₃₂, and cyclic alkyl group Sub₃₃.

The linear alkyl group Sub₃₁ or branched alkyl group Sub₃₂ is exemplified by at least one group selected from the group consisting of a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, amyl group, isoamyl group, 1-methylpentyl group, 2-methylpentyl group, 1-pentylhexyl group, 1-butylpentyl group, 1-heptyloctyl group, and 3-methylpentyl group.

Herein, the linear alkyl group Sub₃₁ or branched alkyl group Sub₃₂ preferably has 1 to 30 carbon atoms, more preferably 1 to 20 carbon atoms, further preferably 1 to 10 carbon atoms, further more preferably 1 to 6 carbon atoms. The linear alkyl group Sub₃₁ or branched alkyl group Sub₃₂ is further more preferably a methyl group, ethyl group, propyl group, isopropyl group, n-butyl group, s-butyl group, isobutyl group, t-butyl group, n-pentyl group, n-hexyl group, amyl group, isoamyl group and neopentyl group.

Herein, the cyclic alkyl group Sub₃₃ is exemplified by a cycloalkyl group Sub₃₃₁.

The cycloalkyl group Sub₃₃₁ herein is exemplified by at least one group selected from the group consisting of a cyclopropyl group, cyclobutyl group, cyclopentyl group, cyclohexyl group, 4-methylcyclohexyl group, adamantyl group and norbornyl group. The cycloalkyl group Sub₃₃₁ preferably has 3 to 30 ring carbon atoms, more preferably 3 to 20 ring carbon atoms, further preferably 3 to 10 ring carbon atoms, further more preferably 5 to 8 ring carbon atoms. Among the cycloalkyl group Sub₃₃₁, a cyclopentyl group and a cyclohexyl group are further more preferable.

Herein, an alkyl halide group is exemplified by an alkyl halide group Sub₄. The alkyl halide group Sub₄ is provided by substituting the alkyl group Sub₃ with at least one halogen atom, preferably at least one fluorine atom.

Herein, the alkyl halide group Sub₄ is exemplified by at least one group selected from the group consisting of a fluoromethyl group, difluoromethyl group, trifluoromethyl group, fluoroethyl group, trifluoromethylmethyl group, trifluoroethyl group, and pentafluoroethyl group.

Herein, a substituted silyl group is exemplified by a substituted silyl group Sub₅, The substituted silyl group Sub₅ is exemplified by at least one group selected from the group consisting of an alkylsilyl group Sub₅₁ and an arylsilyl group Sub₅₂.

Herein, the alkylsilyl group Sub₅₁ is exemplified by a trialkylsilyl group Sub₅₁₁ having the above-described alkyl group Sub₃.

The trialkylsilyl group Sub₅₁₁ is exemplified by at least one group selected from the group consisting of a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyl dimethylsilyl group, propyldimethylsilyl group, and triisopropylsilyl group. Three alkyl groups Sub₃ in the trialkylsilyl group Sub₅₁₁ may be mutually the same or different.

Herein, the arylsilyl group Sub₅₂ is exemplified by at least one group selected from the group consisting of a dialkylarylsilyl group Sub₅₂₁, alkyldiarylsilyl group Sub₅₂₂ and triarylsilyl group Sub₅₂₃.

The dialkylarylsilyl group Sub₅₂₁ is exemplified by a dialkylarylsilyl group including two alkyl groups Sub₃ and one aryl group Sub₁. The dialkylarylsilyl group Sub₅₂₁ preferably has 8 to 30 carbon atoms.

The alkyldiarylsilyl group Sub₅₂₂ is exemplified by an alkyldiarylsilyl group including one alkyl group Sub₃ and two aryl groups Sub₁. The alkyldiarylsilyl group Sub₅₂₂ preferably has 13 to 30 carbon atoms.

The triarylsilyl group Sub₅₂₃ is exemplified by a triarylsilyl group including three aryl groups Sub₁. The triarylsilyl group Sub₅₂₃ preferably has 18 to 30 carbon atoms.

Herein; a substituted or unsubstituted alkyl sulfonyl group is exemplified by an alkyl sulfonyl group Sub₆. The alkyl sulfonyl group Sub₆ is represented by —SO₂Rw. R_{w} in —SO₂R_{w} represents a substituted or unsubstituted alkyl group Sub₃ described above.

Herein; an aralkyl group (occasionally referred to as an arylalkyl group) is exemplified by an aralkyl group Sub₇. An aryl group in the aralkyl group Sub₇ includes, for instance, at least one of the above-described aryl group Sub₁ or the above-described heteroaryl group Sub₂.

The aralkyl group Sub₇ herein is preferably a group having the aryl group Sub₁ and is represented by —Z₃—Z₄. Z₃ is exemplified by an alkylene group corresponding to the above alkyl group Sub₃. Z₄ is exemplified by the above aryl group Sub₁. In this aralkyl group Sub₇; an aryl moiety has 6 to 30 carbon atoms (preferably 6 to 20 carbon atoms, more preferably 6 to 12 carbon atoms) and an alkyl moiety has 1 to 30 carbon atoms (preferably 1 to 20 carbon atoms, more preferably 1 to 10 carbon atoms, further preferably 1 to 6 carbon atoms). The aralkyl group Sub₇ is exemplified by at least one group selected from the group consisting of a benzyl group, 2-phenylpropane-2-yl group, 1-phenylethyl group; 2-phenylethyl group; 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

The alkoxy group herein is exemplified by an alkoxy group Sub₈. The alkoxy group Sub₈ is represented by —OZ₁. Z₁ is exemplified by the above alkyl group Sub₃. The alkoxy group Sub₈ is exemplified by at least one group selected from the group consisting of a methoxy group, ethoxy group, propoxy group, butoxy group, pentyloxy group and hexyloxy group. The alkoxy group Sub₈ preferably has 1 to 30 carbon atoms, more preferably 1 to 20 carbon atoms.

Herein, an alkoxy halide group is exemplified by an alkoxy halide group Sub₉. The alkoxy halide group Sub₉ is provided by substituting the alkoxy group Sub₈ with at least one halogen atom, preferably at least one fluorine atom.

Herein, an aryloxy group (occasionally referred to as an arylalkoxy group) is exemplified by an arylalkoxy group Sub₁₀. An aryl group in the arylalkoxy group Sub₁₀ includes at least one of the aryl group Sub₁ or the heteroaryl group Sub₂.

The arylalkoxy group Sub₁₀ herein is represented by —OZ₂. Z₂ is exemplified by the aryl group Sub₁ or the heteroaryl group Sub₂. The arylalkoxy group Subic) preferably has 6 to 30 ring carbon atoms, more preferably 6 to 20 ring carbon atoms. The arylalkoxy group Sub₁₀ is exemplified by a phenoxy group.

Herein, a substituted amino group is exemplified by a substituted amino group Sub₁₁. The substituted amino group Sub₁₁ is exemplified by at least one group selected from the group consisting of an arylamino group Sub₁₁₁ and an alkylamino group Sub₁₁₂.

An arylamino group Sub₁₁₁ is represented by —NHR_{V1} or —N(R_{V1})₂. R_{V1} is exemplified by the aryl group Sub₁. Two R_{V1} in —N(R_{V1})₂ are mutually the same or different.

An alkylamino group Sub₁₁₂ is represented by —NHR_{V2} or —N(R_{V2})₂. R_{V2} is exemplified by the alkyl group Sub₃. Two R_{V2} in —N(R_{V2})₂ are mutually the same or different.

Herein; the alkenyl group is exemplified by an alkenyl group Sub₁₂. The alkenyl group Sub₁₂, which is linear or branched, is exemplified by at least one group selected from the group consisting of a vinyl group, propenyl group, butenyl group, oleyl group, eicosapentaenyl group, docosahexaenyl group, styryl group, 2,2-diphenylvinyl group, 1,2,2-triphenylvinyl group, and 2-phenyl-2-propenyl group.

The alkynyl group herein is exemplified by an alkynyl group Sub₁₃. The alkynyl group Sub₁₃ may be linear or branched and is at least one group selected from the group consisting of an ethynyl group, a propynyl group and a 2-phenylethynyl group.

The alkylthio group herein is exemplified by an alkylthio group Sub₁₄.

The alkylthio group Sub₁₄ is represented by —SR_{V3}. R_{V3} is exemplified by the alkyl group Sub₃. The alkylthio group Sub₁₄ preferably has 1 to 30 carbon atoms, more preferably 1 to 20 carbon atoms.

The arylthio group herein is exemplified by an arylthio group Sub₁₅.

The arylthio group Sub₁₅ is represented by —SR_{V4}. R_{V4} is exemplified by the aryl group Sub₁. The arylthio group Sub₁₅ preferably has 6 to 30 ring carbon atoms, more preferably 6 to 20 ring carbon atoms.

Herein, examples of the halogen atom include a fluorine atom, a chlorine atom, a bromine atom and an iodine atom, among which a fluorine atom is preferable.

A substituted phosphino group herein is exemplified by a substituted phosphino group Sub₁₆. The substituted phosphino group Sub₁₆ is exemplified by a phenyl phosphanyl group.

An arylcarbonyl group herein is exemplified by an arylcarbonyl group Sub₁₇. The arylcarbonyl group Sub₁₇ is represented by —COY′. Y′ is exemplified by the aryl group Sub₁. Herein, the arylcarbonyl group Sub₁₇ is exemplified by at least one group selected from the group consisting of a phenyl carbonyl group, diphenyl carbonyl group, naphthyl carbonyl group, and triphenyl carbonyl group.

An acyl group herein is exemplified by an acyl group Sub₁₈. The acyl group Sub₁₈ is represented by —COR′. R′ is exemplified by the alkyl group Sub₃. The acyl group Sub₁₈ herein is exemplified by at least one group selected from the group consisting of an acetyl group and a propionyl group.

A substituted phosphoryl group herein is exemplified by a substituted phosphoryl group Sub₁₉. The substituted phosphoryl group Sub₁₉ is represented by a formula (P) below.

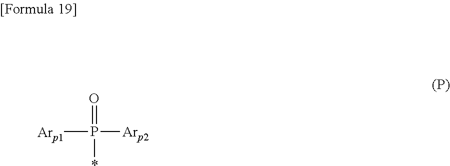

In the formula (P), Ar_{P1} and Ar_{P2} are any one substituent selected from the group consisting of the above alkyl group Sub; and the above aryl group Sub₁.

Herein, an ester group is exemplified by an ester group Sub₂₀. The ester group Sub₂₀ is exemplified by at least one group selected from the group consisting of an alkyl ester group and an aryl ester group.

An alkyl ester group herein is exemplified by an alkyl ester group Sub₂₀₁. The alkyl ester group Sub₂₀₁ is represented by —C(═O)OR^{E}. R^{E} is exemplified by a substituted or unsubstituted alkyl group Sub₃ described above (preferably having 1 to 10 carbon atoms).

An aryl ester group herein is exemplified by an aryl ester group Sub₂₀₂. The aryl ester group Sub₂₀₂ is represented by —C(═O)OR^{Ar}. R^{Ar} is exemplified by a substituted or unsubstituted aryl group Sub₁ described above.

A siloxanyl group herein is exemplified by a siloxanyl group Sub₂₁. The siloxanyl group Sub₂₁ is a silicon compound group through an ether bond. The siloxanyl group Sub₂₁ is exemplified by a trimethylsiloxanyl group.

A carbamoyl group herein is represented by —CONH₂.

A substituted carbamoyl group herein is exemplified by a carbamoyl group Sub₂₂. The carbamoyl group Sub₂₂ is represented by —CONH—Ar^{C} or —CONN—R^{C}. Ar^{C} is exemplified by at least one group selected from the group consisting of the above-described aryl group Sub₁ (preferably 6 to 10 ring carbon atoms) and the above-described heteroaryl group Sub₂ (preferably 5 to 14 ring atoms), Ar^{C} may be a group formed by bonding the aryl group Sub₁ and the heteroaryl group Sub₂.

R^{C} is exemplified by a substituted or unsubstituted alkyl group Sub₃ described above (preferably having 1 to 6 carbon atoms).

Herein, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a ring including a saturated ring, unsaturated ring, or aromatic ring.

Herein, a hydrogen atom includes isotope having different numbers of neutrons, specifically, protium, deuterium and tritium.

Hereinafter, an alkyl group Sub₃ means at least one group of a linear alkyl group Sub₃₁, a branched alkyl group Sub₃₂, or a cyclic alkyl group Sub₃₃ described in “Description of Each Substituent.”

Similarly, a substituted silyl group Sub₅ means at least one group of an alkylsilyl group Sub₅₁ or an arylsilyl group Sub₅₂.

Similarly, a substituted amino group Sub₁₁ means at least one group of an arylamino group Sub₁₁₁ or an alkylamino group Sub₁₁₂.

Herein, a substituent for a “substituted or unsubstituted” group is exemplified by a substituent R_{F1}. The substituent R_{F1} is at least one group selected from the group consisting of an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₈, alkoxy halide group Sub₉, arylalkoxy group Sub₁₀, substituted amino group Sub₁₁, alkenyl group Sub₁₂, alkynyl group Sub₁₃, alkylthio group Sub₁₄, arylthio group Sub₁₅, substituted phosphino group Sub₁₆, arylcarbonyl group Sub₁₇, acyl group Sub₁₈, substituted phosphoryl group Sub₁₉, ester group Sub₂₀, siloxanyl group Sub₂₁, carbamoyl group Sub₂₂, unsubstituted amino group, unsubstituted silyl group, halogen atom, cyano group, hydroxy group, thiol group, nitro group, and carboxy group.

Herein, the substituent R_{F1} for a “substituted or unsubstituted” group may be a diaryl boron group (Ar_{B1}Ar_{B2}B—).Ar_{B1} and Ar_{B2} are exemplified by the above-described aryl group Sub₁. Ar_{B1} and Ar_{B2} in Ar_{B1}Ar_{B2}B— are the same or different.

Specific examples and preferable examples of the substituent RFI are the same as those of the substituents described in “Description of Each Substituent” (e.g., an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₆, alkoxy halide group Sub₉, arylalkoxy group Sub₁₀, substituted amino group Sub₁₁, alkenyl group Sub₁₂, alkynyl group Sub₁₃, alkylthio group Sub₁₄, arylthio group Sub₁₅, substituted phosphino group Sub₁₆, arylcarbonyl group Sub₁₇, acyl group Sub₁₈, substituted phosphoryl group Sub₁₉, ester group Sub₂₀, siloxanyl group Sub₂₁, and carbamoyl group Sub₂₂).

The substituent R_{F1} for a “substituted or unsubstituted” group may be further substituted by at least one group (hereinafter, also referred to as a substitutent R_{F2}) selected from the group consisting of an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₈, alkoxy halide group Sub₉, arylalkoxy group Subic), substituted amino group Sub₁₁, alkenyl group Sub₁₂, alkynyl group Sub₁₃, alkylthio group Sub₁₄, arylthio group Sub₁₅, substituted phosphine group Sub₁₆, arylcarbonyl group Sub₁₇, acyl group Sub₁₈, substituted phosphoryl group Sub₁₉, ester group Sub₂₀, siloxanyl group Sub₂₁, carbamoyl group Sub₂₂, unsubstituted amino group, unsubstituted silyl group, halogen atom, cyano group, hydroxy group, thiol group, nitro group, and carboxy group. Moreover, a plurality of substituents R_{F2} may be bonded to each other to form a ring.

“Unsubstituted” for a “substituted or unsubstituted” group means that a group is not substituted by the above-described substituent R_{F1} but bonded with a hydrogen atom.

Herein, “XX to YY carbon atoms” in the description of “substituted or unsubstituted ZZ group having XX to YY carbon atoms” represent carbon atoms of an unsubstituted ZZ group and do not include carbon atoms of the substituent R_{F1} of the substituted ZZ group.

Herein, “XX to YY atoms” in the description of “substituted or unsubstituted ZZ group having XX to YY atoms” represent atoms of an unsubstituted ZZ group and do not include atoms of the substituent R_{F1} of the substituted ZZ group.

The same description as the above applies to “substituted or unsubstituted” in compounds or partial structures thereof described herein.

Herein, when substituents are bonded to each other to form a ring, the ring is structured to be a saturated ring, an unsaturated ring, an aromatic hydrocarbon ring or a hetero ring.

Herein, examples of the aromatic hydrocarbon group in the linking group include a divalent or multivalent group obtained by eliminating one or more atoms from the above monovalent aryl group Sub₁.

Herein, examples of the heterocyclic group in the linking group include a divalent or multivalent group obtained by eliminating one or more atoms from the above monovalent heteroaryl group Sub₂.

Herein, numerical ranges represented by “x to y” represents a range whose lower limit is the value (x) recited before “to” and whose upper limit is the value (y) recited after “to.”

### Modification of Embodiment(s)

The scope of the invention is not limited by the above-described exemplary embodiments but includes any modification and improvement as long as such modification and improvement are compatible with the invention.

The organic EL display device 1 or the organic EL display device 1A is described according to the exemplary embodiment in which the blue-emitting organic EL device 10B and the red-emitting organic EL device 10R or the green-emitting organic EL device 10G are disposed in parallel on the substrate 8. However, the invention is not limited to the exemplary embodiment. In the organic EL display device according to an exemplary embodiment of the invention, it is only required that at least the blue-emitting organic EL device and one of the red-emitting organic EL device and the green-emitting organic EL device as pixels are disposed in parallel on the substrate. Alternatively, in the organic EL display device according to an exemplary embodiment of the invention, it is only required that at least the blue-emitting organic EL device and the green-emitting organic EL device as pixels are disposed in parallel on the substrate. Alternatively, in the organic EL display device according to an exemplary embodiment of the invention, it is only required that at least the blue-emitting organic EL device, the red-emitting organic EL device and the green-emitting organic EL device as pixels are disposed in parallel on the substrate, and an organic EL device having another emission color may be disposed.

In the organic EL display device, the organic EL device having the resonator structure is not limited to the organic EL devices described in the above exemplary embodiments.

For instance, in the organic EL display device according to the first exemplary embodiment; not only the red-emitting organic EL device but also the blue-emitting organic EL device may have the resonator structure whose order of interference is first-order between the light reflection layer and the semitransmissive electrode. Also in the organic EL display devices according to the second to fifth exemplary embodiments, the blue-emitting organic EL device may also have the resonator structure whose order of interference is first-order between the light reflection layer and the semitransmissive electrode. In the organic EL display device, a region between the light reflection layer and the semitransmissive electrode refers to a zone including the hole transporting zone, the emitting layer, and the electron transporting zone without including the light reflection layer, the transparent electrode, and the semitransmissive electrode. The distance d1 between the light reflection layer and the semitransmissive electrode in the organic EL display device corresponds to a sum of a thickness of the hole transporting zone, a thickness of the emitting layer, and a thickness of the electron transporting zone.

The green-emitting organic EL device 10G and the green emitting layer 5G in the third, fourth, and fifth exemplary embodiment are the green-emitting organic EL device 10G and the green emitting layer 5G described in the second exemplary embodiment. However, in another exemplary embodiment of the invention, the green-emitting organic EL device 10G and the green emitting layer 5G are not limited thereto. For instance, in an exemplary embodiment, an organic EL device serving as a green emittable pixel is in a form of the green-emitting organic EL device in the third, fourth, and fifth exemplary embodiments. For instance, the green-emitting organic EL device in this exemplary embodiment does not need to include the delayed fluorescent compound DF_{G} in the green emitting layer and does not need to have the resonator structure whose order of interference is first-order between the light reflection layer and the semitransmissive electrode.

Specific structure, shape and the like of the components in the invention may be designed in any manner as long as an object of the invention can be achieved.

### EXAMPLES

Example(s) of the invention will be described below. However, the invention is not limited to Example(s).

### Compounds

Structures of compounds used for manufacturing organic EL devices in Examples and Comparatives are shown below.

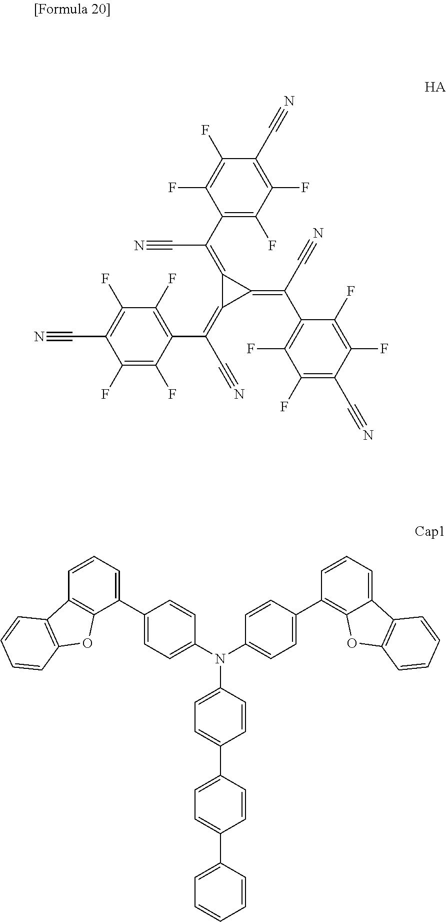 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

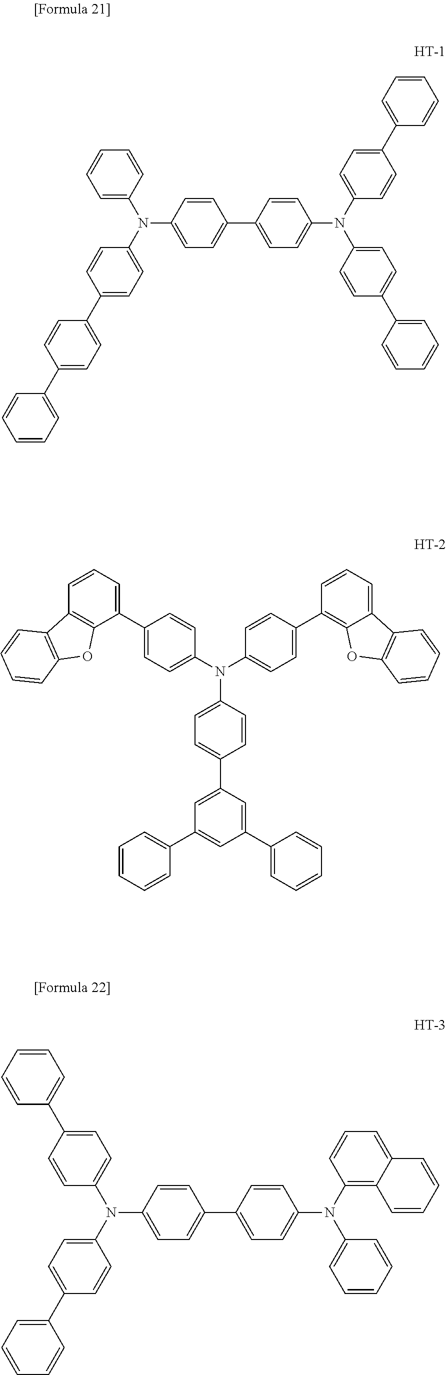 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1 ; c1ccc(-c2ccc(N(c3ccc(-c4ccccc4)cc3)c3ccc(-c4ccc(N(c5ccccc5)c5cccc6ccccc56)cc4)cc3)cc2)cc1]

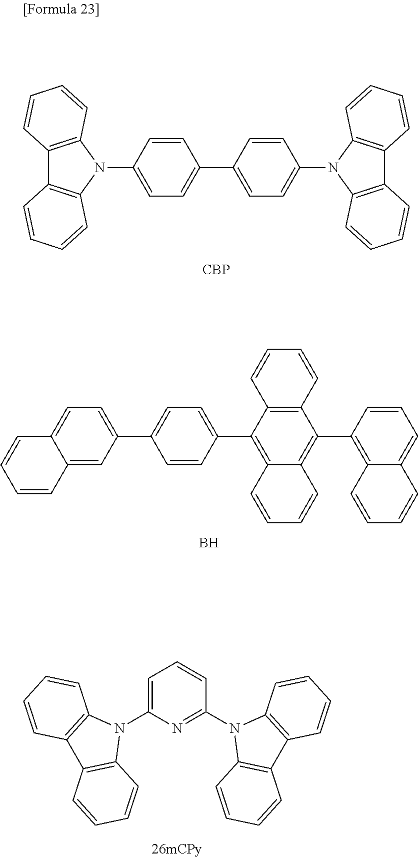

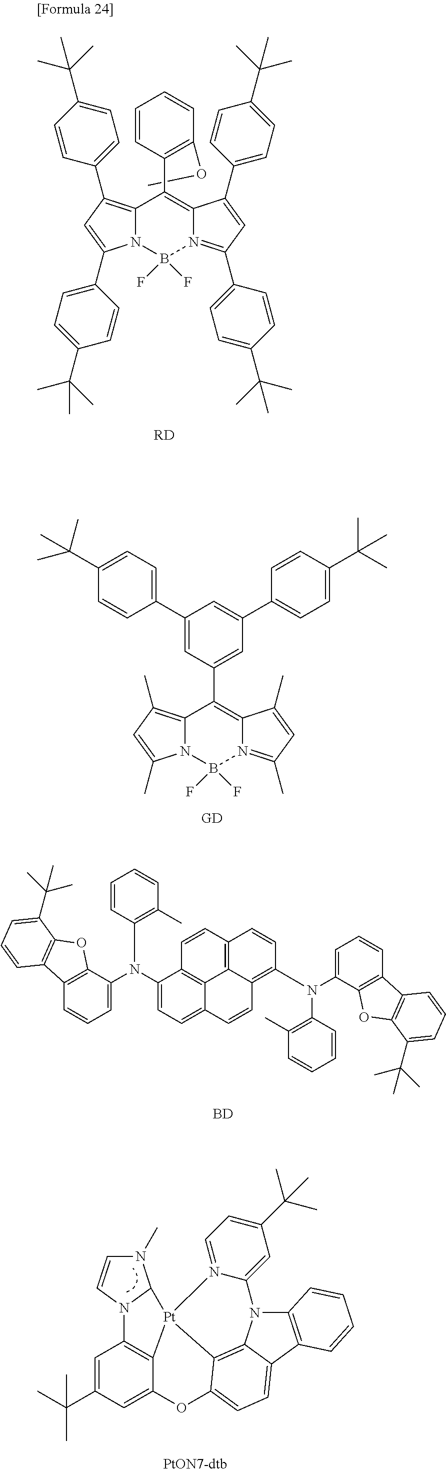

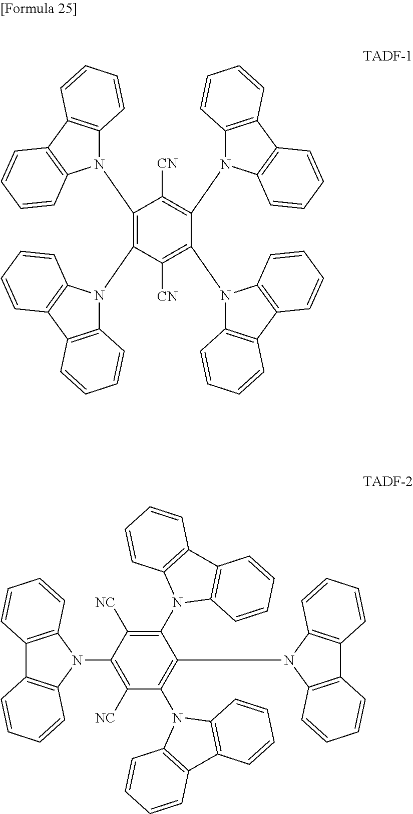 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

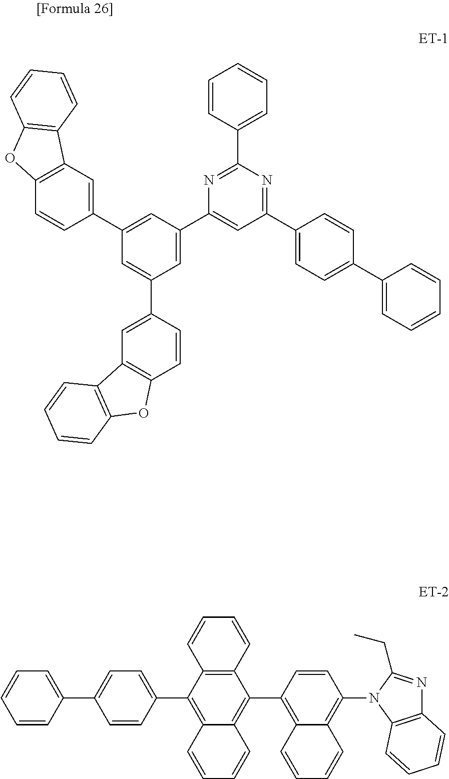 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1 ; CCc1nc2ccccc2n1-c1ccc(-c2c3ccccc3c(-c3ccc(-c4ccccc4)cc3)c3ccccc23)c2ccccc12]

### Manufacture of Organic EL Display Device

Organic EL display devices were manufactured and evaluated as follows.

### Example 1

Firstly, an APC (Ag—Pd—Cu) layer (i.e., a silver alloy layer) was formed as a film by sputtering on a glass substrate as a substrate for manufacturing a device. A film thickness of the APC layer was 100 nm. The APC layer corresponds to a reflection layer.

Next, an indium zinc oxide (IZO) film with a film thickness of 10 nm was formed on the APC layer. This zinc oxide film corresponds to a transparent electrode.

Subsequently, the zinc oxide film was patterned by etching using a resist pattern as a mask using a normal lithography technique to form a lower electrode (anode).

In order to drive a panel, TFT may be formed on a lower side of the anode, and a flattened film formed of an organic material for flattening an unevenness of an upper surface of the TFT and an output end of the TFT may be connected to the lower electrode (anode) through a contact hole for electrical connection.

The substrate formed with the lower electrode was ultrasonic-cleaned in isopropyl alcohol for five minutes, and then UV-ozone-cleaned for 30 minutes.

Subsequent to the UV-ozone-cleaning, a hole injecting layer in a form of a common layer was formed on the lower electrode with use of a compound HT-1 and a compound HA through vacuum deposition. The compound HT-1 and the compound HA were 98 mass % and 2 mass %, respectively, in mass ratio in the hole injecting layer. A film thickness of the hole injecting layer was 10 nm.

Next, a hole transporting layer in a form of a common layer was formed on the hole injecting layer through vacuum deposition. A compound HT-2 was used for forming the hole transporting layer. A film thickness of the hole transporting layer was 5 nm.

The hole injecting layer and the hole transporting layer are collectively referred to as a hole transporting zone.

Subsequently, vapor deposition was performed in separate colors on the same substrate using a mask corresponding to an emission pattern.

For a red pixel, a compound CBP, a compound RD, and a compound TADF-1 were used to form a red emitting layer having a film thickness of 40 nm. The mass ratios of the compound CBP, the compound RD, and the compound TADF-1 in the red emitting layer were 79 mass %, 1 mass %, and 20 mass %, respectively.

For a green pixel, the compound CBP, a compound GD, and a compound TADF-2 were used to form a green emitting layer having a film thickness of 30 nm.

The mass ratios of the compound CBP, the compound GD, and the compound TADF-2 in the green emitting layer were 79 mass %, 1 mass %, and 20 mass %, respectively.

For a blue pixel, a compound BH and a compound BD were used to form a blue emitting layer having a film thickness of 20 nm. The mass ratios of the compound BH and the compound BD in the blue emitting layer were 95 mass % and 5 mass %, respectively.

The red emitting layer, the green emitting layer, and the blue emitting layer were formed on the hole transporting zone.

Next, a hole blocking layer and an electron transporting layer were formed on each of the red emitting layer for the red pixel and the green emitting layer for the green pixel.

When forming the hole blocking layer and the electron transporting layer, through vacuum deposition using a mask, for the red pixel, a compound ET-1 was used to form the hole blocking layer having a film thickness of 10 nm, and subsequently a compound ET-2 was used to form the electron transporting layer having a film thickness of 95 nm. Two layers (with a total film thickness of 105 nm) of the hole blocking layer and the electron transporting layer in a red pixel were provided in order to adjust an optical interference distance.

Also when forming the hole blocking layer and the electron transporting layer of the green pixel, through vacuum deposition using a mask, for the green pixel, the compound ET-1 was used to form the hole blocking layer having a film thickness of 10 nm, and subsequently the compound ET-2 was used to form the electron transporting layer having a film thickness of 25 nm, Two layers (with a total film thickness of 35 nm) of the hole blocking layer and the electron transporting layer in the green pixel were provided in order to adjust an optical interference distance.

No layer for adjusting the optical interference distance was formed on the blue emitting layer of the blue pixel.

Next, on the layers of the red pixel and the green pixel for adjusting the optical interference distance and on the emitting layer of the blue pixel, the compound ET-2 was used to form an electron transporting layer as a common layer having a film thickness of 150 nm through vacuum deposition.

Next, using a mask for the cathode electrode instead, LiF was applied onto an electron transporting layer to form an electron injecting layer as a common layer having a film thickness of 1 nm.

The hole blocking layer, the electron transporting layer, and the electron injecting layer are collectively referred to as an electron transporting zone.

Next, an electrode (cathode) as a common layer having a film thickness of 12 nm and a mass ratio of Mg:Ag being 1:9 was formed on the electron injecting layer. A compound Cap1 was used to form an organic capping layer as a common layer having a film thickness of 70 nm.

In the manufacture of the organic EL display device in Example 1, mask vapor deposition was required for forming the emitting layer and forming the hole blocking layer and the electron transporting layer provided for adjusting the optical interference distance. The mask vapor deposition required for forming organic function layers was performed five times.

Each of the red pixel, green pixel and blue pixel of the organic EL display device in Example 1 has a resonator structure whose order of interference is first-order between the light reflection layer and the semitransmissive electrode.

An emission position of each of the red pixel, green pixel and blue pixel of the organic EL display device in Example 1 is at a zero-order interference position viewed from the anode.

A current efficiency at a square angle and a current efficiency at an angle of 45 degrees to the red pixel, green pixel and blue pixel of the organic EL display device in Example 1 were measured at a current density of 10 mA/cm².

As a result of the measurement, a high efficiency was obtained in the red pixel and the green pixel of the emission from the emitting layer containing the delayed fluorescent compound and in the blue pixel of a typical fluorescence. Moreover, a difference in the luminous efficiency between the current efficiency at the square angle and the current efficiency at the angle of 45 degrees (angular dependency on an emission color) was small.

### Example 2

An organic EL display device in Example 2 was manufactured in the same manner as in Example 1 except that the formation of the hole injecting layer and the hole transporting layer in the manufacture of the organic EL display device in Example 1 was changed as follows.

In Example 2, subsequent to the UV-ozone-cleaning, a hole injecting layer in a form of a common layer was formed on the lower electrode with use of the compound HT-2 and the compound HA through vacuum deposition. The compound HT-2 and the compound HA were 90 mass % and 10 mass %, respectively, in mass ratio in the hole injecting layer. A film thickness of the hole injecting layer was 5 nm.

Next, a hole transporting layer in a form of a common layer was formed on the hole injecting layer through vacuum deposition. A compound HT-2 was used for forming the hole transporting layer. A film thickness of the hole transporting layer was 10 nm.

The hole injecting layer and the hole transporting layer are collectively referred to as a hole transporting zone.

A current efficiency at a square angle and a current efficiency at an angle of 45 degrees to the red pixel, green pixel and blue pixel of the organic EL display device in Example 2 were measured at a current density of 10 mA/cm².

### Example 3

An organic EL display device in Example 3 was manufactured in the same manner as in Example 1 except that the formation of the blue emitting layer in the manufacture of the organic EL display device in Example 1 was changed as follows.

In Example 3, after the formation of the hole transporting zone, the red emitting layer and the green emitting layer, a compound 26mCPy and a compound PtON7-dtb were used to form a blue emitting layer having a film thickness of 20 nm. The compound 26mCPy and the compound PtON7-dtb were 90 mass % and 10 mass %, respectively, in mass ratio in the blue emitting layer.

A current efficiency at a square angle and a current efficiency at an angle of 45 degrees to the red pixel, green pixel and blue pixel of the organic EL display device in Example 3 were measured at a current density of 10 mA/cm².

### Comparative 1

An organic EL display device in Comparative 1 was manufactured as follows.

Comparative 1 was performed from the formation of the APC (Ag—Pd—Cu) layer on the substrate to the UV-ozone-cleaning in the same manner as in Example 1.

Subsequent to the UV-ozone-cleaning, a hole injecting layer in a form of a common layer was formed on the lower electrode with use of the compound HT-1 and the compound HA through vacuum deposition. The compound HT-1 and the compound HA were 98 mass % and 2 mass %, respectively, in mass ratio in the hole injecting layer. A film thickness of the hole injecting layer was 10 nm.

Next, a first hole transporting layer in a form of a common layer was formed on the hole injecting layer with use of the compound HT-1 through vacuum deposition. A film thickness of the first hole transporting layer was 123 nm.

Subsequently, vapor deposition in separate colors was performed on the same substrate using a mask corresponding to an emission pattern. A layer for adjusting the optical interference distance was formed on each of the first hole transporting layer of the red pixel and the first hole transporting layer of the green pixel.

As the layer for adjusting the optical interference distance in the red pixel, the compound HT-1 was used to form a layer having a film thickness of 90 nm using a mask through vacuum deposition.

As the layer for adjusting the optical interference distance in the green pixel, the compound HT-1 was used to form a layer having a film thickness of 30 nm using a mask through vacuum deposition.

No layer for adjusting the optical interference distance was formed on the first hole transporting layer of the blue pixel.

Next, on the first hole transporting layer in the blue pixel and the layers for adjusting the optical interference distance in the red and green pixels, a second hole transporting layer in a form of a common layer was formed with use of the compound HT-2 through vacuum deposition. A film thickness of the second hole transporting layer was 10 nm.

In Comparative 1, the hole injecting layer, the first hole transporting layer, the layers for adjusting the optical interference distance, and the second hole transporting layer are collectively referred to as the hole transporting zone.

Subsequently, vapor deposition in separate colors was performed on the same substrate using a mask corresponding to an emission pattern.

For a red pixel, a compound CBP, a compound RD, and a compound TADF-1 were used to form a red emitting layer having a film thickness of 40 nm. The concentrations of the compound CBP, the compound RD, and the compound TADF-1 in the red emitting layer were 79 mass %, 1 mass %, and 20 mass %, respectively.

For a green pixel, the compound CBP, a compound GD, and a compound TADF-2 were used to form a green emitting layer having a film thickness of 30 nm. The mass ratios of the compound CBP, the compound GD, and the compound TADF-2 in the green emitting layer were 79 mass %, 1 mass %, and 20 mass %, respectively.

For a blue pixel, a compound BH and a compound BD were used to form a blue emitting layer having a film thickness of 20 nm. The mass ratios of the compound BH and the compound BD in the blue emitting layer were 95 mass % and 5 mass %, respectively.

The red emitting layer, the green emitting layer, and the blue emitting layer were formed on the hole transporting zone.

Next, on each of the red emitting layer of the red pixel, the green emitting layer of the green pixel, and the blue emitting layer of the blue pixel, a first electron transporting layer in a form of a common layer was formed with use of the compound ET-1 through vacuum deposition. A film thickness of the first electron transporting layer was 10 nm.

Next, on the first electron transporting layer in a form of the common layer over the red, green and blue pixels, a second electron transporting layer in a form of a common layer was formed with use of the compound ET-2 through vacuum deposition. A film thickness of the second electron transporting layer was 20 nm.

Next, using a mask for the cathode electrode instead, LiF was applied onto the second electron transporting layer as the common layer to form an electron injecting layer as a common layer having a film thickness of 1 nm.

The first electron transporting layer, the second electron transporting layer, and the electron injecting layer are collectively referred to as an electron transporting zone.

Next, an electrode (cathode) as a common layer having a film thickness of 12 nm and a mass ratio of Mg:Ag being 1:9 was formed on the electron injecting layer. A compound Cap1 was used to form an organic capping layer as a common layer having a film thickness of 70 nm.

In the manufacture of the organic EL display device in Comparative 1, mask vapor deposition was required for forming the layers provided for adjusting the optical interference distance and for forming the emitting layer. The mask vapor deposition required for forming organic function layers was performed five times.

Each of the red pixel, green pixel and blue pixel of the organic EL display device in Comparative 1 has a resonator structure whose order of interference is first-order between the light reflection layer and the semitransmissive electrode.

An emission position of the blue pixel of the organic EL display device in Comparative 1 is at a first-order interference position viewed from the anode.

A current efficiency at a square angle and a current efficiency at an angle of 45 degrees to the red pixel, green pixel and blue pixel of the organic EL display device in Comparative 1 were measured at a current density of 10 mA/cm².

As a result of the measurement, the efficiency of the red pixel and the green pixel emitting light from the emitting layer having the delayed fluorescent compound was lowered, in which the light is emitted from a side of the emitting layer where the recombination positions of holes and electrons are close to the electron transporting zone. Moreover, a difference in the luminous efficiency between the current efficiency at the square angle and the current efficiency at the angle of 45 degrees of the red pixel and the green pixel was large.

The red pixel and the green pixel of the organic EL display device in Comparative 1 have a film thickness adjusted by having the additional hole transporting layer other than the common layer. Accordingly, the respective emitting layers of the red pixel and the green pixel, as long as being a phosphorescent emitting layer, are supposed to overlap with the first-order interference position. However, the respective emitting layers of the red pixel and the green pixel in Comparative 1 are a delayed fluorescent layer containing a delayed fluorescent compound. Accordingly, the respective emitting layers of the red pixel and the green pixel are shifted from the first-order interference position. As a result, a light extraction efficiency of each of the red pixel and the green pixel is lower than that in Example 1.

### Comparative 2

An organic EL display device in Comparative 2 was manufactured as follows.

Comparative 1 was performed from the formation of the APC (Ag—Pd—Cu) layer on the substrate to the UV-ozone-cleaning in the same manner as in Example 1.

Subsequent to the UV-ozone-cleaning, a hole injecting layer in a form of a common layer was formed on the lower electrode with use of the compound HT-1 and the compound HA through vacuum deposition. The compound HT-1 and the compound HA were 98 mass % and 2 mass %, respectively, in mass ratio in the hole injecting layer. A film thickness of the hole injecting layer was 10 nm.

Next, a first hole transporting layer in a form of a common layer was formed on the hole injecting layer with use of the compound HT-1 through vacuum deposition. A film thickness of the first hole transporting layer was 123 nm.

Subsequently, vapor deposition in separate colors was performed on the same substrate using a mask corresponding to an emission pattern. A layer for adjusting the optical interference distance was formed on each of the first hole transporting layer of the red pixel and the first hole transporting layer of the green pixel.

As the layer for adjusting the optical interference distance in the red pixel, the compound HT-1 was used to form a layer having a film thickness of 60 nm using a mask through vacuum deposition.

As the layer for adjusting the optical interference distance in the green pixel, the compound HT-1 was used to form a layer having a film thickness of 15 nm using a mask through vacuum deposition.

No layer for adjusting the optical interference distance was formed on the first hole transporting layer of the blue pixel.

Next, on the first hole transporting layer in the blue pixel and the layers for adjusting the optical interference distance in the red and green pixels, a second hole transporting layer in a form of a common layer was formed with use of the compound HT-2 through vacuum deposition. A film thickness of the second hole transporting layer was 10 nm.

In Comparative 2, the hole injecting layer, the first hole transporting layer, the layers for adjusting the optical interference distance, and the second hole transporting layer are collectively referred to as the hole transporting zone.

Subsequently, vapor deposition in separate colors was performed on the same substrate using a mask corresponding to an emission pattern.

For a red pixel, a compound CBP, a compound RD, and a compound TADF-1 were used to form a red emitting layer having a film thickness of 40 nm. The concentrations of the compound CBP, the compound RD, and the compound TADF-1 in the red emitting layer were 79 mass %, 1 mass %, and 20 mass %, respectively.

For a green pixel, the compound CBP, a compound GD, and a compound TADF-2 were used to form a green emitting layer having a film thickness of 30 nm. The mass ratios of the compound CBP, the compound GD, and the compound TADF-2 in the green emitting layer were 79 mass %, 1 mass %, and 20 mass %, respectively.

For a blue pixel, a compound BH and a compound BD were used to form a blue emitting layer having a film thickness of 20 nm. The mass ratios of the compound BH and the compound BD in the blue emitting layer were 95 mass % and 5 mass %, respectively.

The red emitting layer, the green emitting layer, and the blue emitting layer were formed on the hole transporting zone.

Subsequently, vapor deposition in separate colors was performed on the same substrate using a mask corresponding to an emission pattern. A layer for adjusting the optical interference distance was formed on each of the red emitting layer of the red pixel and the green emitting layer of the green pixel.

As the layers for adjusting the optical interference distance, through vacuum deposition using a mask, for the red pixel, the compound ET-1 was used to form the hole blocking layer having a film thickness of 10 nm, and subsequently the compound ET-2 was used to form the electron transporting layer having a film thickness of 20 nm. A total film thickness of two layers of the hole blocking layer and the electron transporting layer in the red pixel was 30 nm.

As the layers for adjusting the optical interference distance, through vacuum deposition using a mask, for the green pixel, the compound ET-1 was used to form the hole blocking layer having a film thickness of 10 nm, and subsequently the compound ET-2 was used to form the electron transporting layer having a film thickness of 5 nm. A total film thickness of two layers of the hole blocking layer and the electron transporting layer in the green pixel was 15 nm.

No layer for adjusting the optical interference distance was formed on the blue emitting layer of the blue pixel.

Next, on the layers of the red pixel and the green pixel for adjusting the optical interference distance and on the emitting layer of the blue pixel, the compound ET-2 was used to form the electron transporting layer as a common layer having a film thickness of 30 nm through vacuum deposition.

Next, using a mask for the cathode electrode instead, LiF was used to form an electron injecting layer as a common layer having a film thickness of 1 nm.

The hole blocking layer, the electron transporting layer, and the electron injecting layer are collectively referred to as an electron transporting zone.

Next, an electrode (cathode) as a common layer having a film thickness of 12 nm and a mass ratio of Mg:Ag being 1:9 was formed on the electron injecting layer. A compound Cap1 was used to form an organic capping layer as a common layer having a film thickness of 70 nm.

in the manufacture of the organic EL display device in Comparative 2, mask vapor deposition was required for forming the layers provided for adjusting the optical interference distance and for forming the emitting layer. The mask vapor deposition required for forming organic function layers was performed seven times. Specifically, in comparison between Example 1 and Comparative 1, the number of the mask vapor deposition was increased by two since the layers for adjusting the optical interference distance were added.

Each of the red pixel, green pixel and blue pixel of the organic EL display device in Comparative 2 has a resonator structure whose order of interference is first-order between the light reflection layer and the semitransmissive electrode. An emission position of each of the red pixel, green pixel and blue pixel of the organic EL display device in Comparative 2 is at a first-order interference position viewed from the anode. The respective emitting layers of the red pixel and the green pixel in Comparative 2 are a delayed fluorescent layer. Accordingly, in the red pixel and the green pixel of the organic EL display device in Comparative 2, assuming that the respective emission positions are close to the cathode, an additional layer is provided to each of the hole transporting zone and the electron transporting zone so that the emission positions overlap with the first-order interference position.

A current efficiency at a square angle and a current efficiency at an angle of 45 degrees to the red pixel, green pixel and blue pixel of the organic EL display device in Comparative 2 were measured at a current density of 10 mA/cm². The results are shown in Table 1.

### Comparative 3

An organic EL display device in Comparative 3 was manufactured as follows.

Comparative 1 was performed from the formation of the APC (Ag—Pd—Cu) layer on the substrate to the UV-ozone-cleaning in the same manner as in Example 1.

Subsequent to the UV-ozone-cleaning, a hole injecting layer in a form of a common layer was formed on the lower electrode with use of the compound HT-1 and the compound HA through vacuum deposition. The compound HT-1 and the compound HA were 98 mass % and 2 mass %, respectively, in mass ratio in the hole injecting layer. A film thickness of the hole injecting layer was 10 nm.

Next, a first hole transporting layer in a form of a common layer was formed on the hole injecting layer with use of the compound HT-1 through vacuum deposition. A film thickness of the first hole transporting layer was 123 nm.

Next, the second hole transporting layer in a form of a common layer was formed on the hole injecting layer with use of the compound HT-2 through vacuum deposition. A film thickness of the second hole transporting layer was 10 nm.

The hole injecting layer, the first hole transporting layer and the second hole transporting layer are collectively referred to as the hole transporting zone.

Subsequently, vapor deposition in separate colors was performed on the same substrate using a mask corresponding to an emission pattern.

For a red pixel, the compound CBP, the compound RD, and the compound TADF-1 were used to form the red emitting layer having a film thickness of 100 nm. The concentrations of the compound CBP, the compound RD, and the compound TADF-1 in the red emitting layer were 79 mass %, 1 mass %, and 20 mass %, respectively.

For a green pixel, the compound CBP, the compound GD, and the compound TADF-2 were used to form a green emitting layer having a film thickness of 45 nm. The mass ratios of the compound CBP, the compound GD, and the compound TADF-2 in the green emitting layer were 79 mass %, 1 mass %, and 20 mass %, respectively.

For a blue pixel, a compound BH and a compound BD were used to form a blue emitting layer having a film thickness of 20 nm. The mass ratios of the compound BH and the compound BD in the blue emitting layer were 95 mass % and 5 mass %, respectively.

The red emitting layer, the green emitting layer, and the blue emitting layer were formed on the hole transporting zone.

Subsequently, vapor deposition in separate colors was performed on the same substrate using a mask corresponding to an emission pattern. A layer for adjusting the optical interference distance was formed on each of the red emitting layer of the red pixel and the green emitting layer of the green pixel.

As the layers for adjusting the optical interference distance, through vacuum deposition using a mask, for the red pixel, the compound ET-1 was used to form the hole blocking layer having a film thickness of 10 nm, and subsequently the compound ET-2 was used to form the electron transporting layer having a film thickness of 20 nm. A total film thickness of two layers of the hole blocking layer and the electron transporting layer in the red pixel was 30 nm.

As the layers for adjusting the optical interference distance, through vacuum deposition using a mask, for the green pixel, the compound ET-1 was used to form the hole blocking layer having a film thickness of 10 nm, and subsequently the compound ET-2 was used to form the electron transporting layer having a film thickness of 5 nm. A total film thickness of two layers of the hole blocking layer and the electron transporting layer in the green pixel was 15 nm.

No layer for adjusting the optical interference distance was formed on the blue emitting layer of the blue pixel.

Next, on the layers of the red pixel and the green pixel for adjusting the optical interference distance and on the emitting layer of the blue pixel, the compound ET-2 was used to form the electron transporting layer as a common layer having a film thickness of 30 nm through vacuum deposition.

Next, using a mask for the cathode electrode instead, LiF was used to form an electron injecting layer as a common layer having a film thickness of 1 nm.

The hole blocking layer, the electron transporting layer, and the electron injecting layer are collectively referred to as an electron transporting zone.

Next, an electrode (cathode) as a common layer having a film thickness of 12 nm and a mass ratio of Mg:Ag being 1:9 was formed on the electron injecting layer, A compound Cap1 was used to form an organic capping layer as a common layer having a film thickness of 70 nm.

In the manufacture of the organic EL display device in Comparative 3, mask vapor deposition was required for forming the emitting layer and forming the layer for adjusting the optical interference distance. The mask vapor deposition required for forming organic function layers was performed five times.

Each of the red pixel, green pixel and blue pixel of the organic EL display device in Comparative 3 has a resonator structure whose order of interference is first-order between the light reflection layer and the semitransmissive electrode.

An emission position of each of the red pixel, green pixel and blue pixel of the organic EL display device in Comparative 3 is at a first-order interference position viewed from the anode. The respective emitting layers of the red pixel and the green pixel in Comparative 3 are a delayed fluorescent layer. Accordingly, in the red pixel and the green pixel of the organic EL display device in Comparative 3, assuming that the respective emission positions are close to the cathode, a thick emitting layer is provided so that the emission positions overlap with the respective first-order interference positions.

A current efficiency at a square angle and a current efficiency at an angle of 45 degrees to the red pixel, green pixel and blue pixel of the organic EL display device in Comparative 3 were measured at a current density of 10 mA/cm².

In the manufacture of the organic EL display device in Comparative 3, the number of the layers provided for adjusting the optical interference distance was decreased and the film thickness of the emitting layer was increased as compared with Comparative 2, whereby the mask vapor deposition was performed five times the same as in Example 1 and Comparative 1.

However, the increased film thickness of the emitting layer caused the luminous efficiency of the organic EL device to be significantly lowered.

### Comparative 4

An organic EL display device in Comparative 4 was manufactured in the same manner as in Example 1 except that the formation of the hole injecting layer and the hole transporting layer in the manufacture of the organic EL display device in Example 1 was changed to the formation of the first hole transporting layer and the second hole transporting layer as follows.

In Comparative 4, subsequent to the UV-ozone-cleaning, the first hole transporting layer in a form of a common layer was formed on the lower electrode with use of the compound HT-3 through vacuum deposition. A film thickness of the first hole transporting layer was 100 nm.

Next, the second hole transporting layer in a form of a common layer was formed on the first hole transporting layer through vacuum deposition. The compound HT-2 was used for forming the second hole transporting layer. A film thickness of the second hole transporting layer was 5 nm.

The first hole transporting layer and the second hole transporting layer are collectively referred to as the hole transporting zone.

A current efficiency at a square angle and a current efficiency at an angle of 45 degrees to the red pixel, green pixel and blue pixel of the organic EL display device in Comparative 4 were measured at a current density of 10 mA/cm².

### Evaluation of Organic EL Display Device

The organic EL display devices manufactured in Examples and Comparatives were evaluated as follows. Evaluation results are shown in Table 1.

### Current Efficiency

Voltage was applied on the device in each color such that a current density became 10 mA/cm², where spectral radiance spectrum was measured by a spectroradiometer CS-2000 (manufactured by Konica Minolta, Inc.). The current efficiency (cd/A) was calculated based on the obtained spectral-radiance spectra, assuming that the spectra was provided under a Lambertian radiation.

A current efficiency at an angle of 0 degrees is defined as a current efficiency E₀. A current efficiency at an angle of 45 degrees is defined as a current efficiency E₄₅. The unit of the current efficiency is cd/A.

Table 1 shows values of the current efficiency of the red pixel in Examples 2 to 3 and Comparatives 1 to 4, values of the current efficiency of the red pixel in Examples 2 to 3 and Comparatives 1 to 4, provided that the current efficiencies E₀ and E45 of the red pixel in Example 1 are defined as 100. For example; the current efficiency E₀ is calculated by a numerical formula of {(current efficiency E₀ of a target red pixel)/(current efficiency E₀ of a red pixel of Example 1)}×100. The current efficiency E₄₅ is calculated by a numerical formula of {(current efficiency E₄₅ of a target red pixel) (current efficiency E₄₅ of a red pixel of Example 1)}×100. The current efficiencies E₀ and E₄₅ of each of the green pixel and the blue pixel are also calculated in the same manner as those of the red pixel.

Table 1 also shows a current efficiency ratio E₄₅/E₀ of each pixel, which is obtained by dividing the measurement value of the current efficiency E₄₅ by the measurement value of the current efficiency E₀.

TABLE 1

| | | Current Efficiency | | Current |
|---|---|---|---|---|
| | | [cd/A] | | Efficiency |
| | | E0 | E45 | Ratio [−] |
| | Pixel | (at angle of 0°) | (at angle of 45°) | E45/E0 |
| Example 1 | Red | 100 | 100 | 0.94 |
| | Green | 100 | 100 | 0.31 |
| | Blue | 100 | 100 | 0.36 |
| Example 2 | Red | 101 | 101 | 0.94 |
| | Green | 100 | 100 | 0.31 |
| | Blue | 98 | 98 | 0.36 |
| Example 3 | Red | 100 | 100 | 0.94 |
| | Green | 100 | 100 | 0.31 |
| | Blue | 120 | 128 | 0.39 |
| Comparative 1 | Red | 71 | 65 | 0.86 |
| | Green | 71 | 66 | 0.28 |
| | Blue | 85 | 56 | 0.24 |
| Comparative 2 | Red | 117 | 68 | 0.55 |
| | Green | 63 | 63 | 0.31 |
| | Blue | 84 | 53 | 0.23 |
| Comparative 3 | Red | 82 | 48 | 0.55 |
| | Green | 44 | 44 | 0.31 |
| | Blue | 85 | 53 | 0.23 |
| Comparative 4 | Red | 1 | 2 | 1.60 |
| | Green | 2 | 3 | 0.50 |
| | Blue | 6 | 38 | 2.28 |

### Evaluation of Compounds

Values of physical properties of the compounds used in Examples and Comparatives were measured by the following method.

### Delayed Fluorescence Properties

### Delayed Fluorescence of Compound TADF-1

Delayed fluorescence properties were checked by measuring transient photoluminescence (PL) using a device shown in FIG. 2. The compound TADF-1 was dissolved in toluene to prepare a dilute solution with an absorbance of 0.05 or less at the excitation wavelength to eliminate the contribution of self-absorption. In order to prevent quenching due to oxygen, the sample solution was frozen and degassed and then sealed in a cell with a lid under an argon atmosphere to obtain an oxygen-free sample solution saturated with argon.

The fluorescence spectrum of the above sample solution was measured with a spectrofluorometer FP-8600 (manufactured by JASCO Corporation), and the fluorescence spectrum of a 9,10-diphenylanthracene ethanol solution was measured under the same conditions. Using the fluorescence area intensities of both spectra, the total fluorescence quantum yield is calculated by an equation (1) in Morris et al, J. Phys. Chem. 80 (1976) 969.

Prompt emission was observed immediately when the excited state was achieved by exciting the compound TADF-1 with a pulse beam (i.e., a beam emitted from a pulse laser) having a wavelength to be absorbed by the compound TADF-1, and Delay emission was observed not immediately when the excited state was achieved but after the excited state was achieved. The delayed fluorescence in Examples means that an amount of Delay Emission is 5% or more with respect to an amount of Prompt Emission. Specifically, provided that the amount of Prompt emission is denoted by X_{P} and the amount of Delay emission is denoted by X_{D}, the delayed fluorescence means that a value of X_{D}/X_{P} is 0.05 or more.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using a device different from one described in Reference Document 1 or one shown in FIG. 2.

It was confirmed that the amount of Delay Emission was 5% or more with respect to the amount of Prompt Emission in the compound TADF-1.

Specifically, it was found that a value of X_{D}/X_{P} was 0.05 or more in the compound TADF-1.

### Delayed Fluorescence of Compound TADF-2

The compound TADF-2 was checked in terms of delayed fluorescence in the same manner as above except that the compound TADF-2 was used in place of the compound TADF-1.

A value of X_{D}/X_{P} was 0.05 or more in the compound TADF-2.

### Singlet Energy S₁

Singlet Energy S₁ of a measurement target compound was measured according to the above-described solution method. Measurement results are shown in Table 2.

TABLE 2

| Compound | S₁ [eV] |
|---|---|
| TADF-1 | 2.38 |
| TADF-2 | 2.62 |
| CBP | 3.52 |
| BH | 3.01 |
| RD | 2.02 |
| GD | 2.39 |
| BD | 2.78 |

### Energy Gap at 77K

Energy gap T_{77K} at 77K of each of the compounds TADF-1 and TADF-2 was measured according to the above-described solution method.

### ΔST

ΔST was calculated based on the measured singlet energy S₁ and energy gap T_{77K}. It was confirmed that ΔST of each of the compound TADF-1 and the compound TADF-2 was less than 0.01 eV.

### Main Peak Wavelength

A 5-μmol/L toluene solution of each of the compounds (measurement target) was prepared and put in a quartz cell. A fluorescence spectrum (ordinate axis: fluorescence intensity, abscissa axis: wavelength) of each of the samples was measured at a normal temperature (300K). In Examples, the fluorescence spectrum was measured using a spectrophotometer (F-7000 manufactured by Hitachi, Ltd). It should be noted that the fluorescence spectrum measuring device may be different from the above device. A peak wavelength of the fluorescence spectrum exhibiting the maximum luminous intensity was defined as a main peak wavelength.

A main peak wavelength of the compound RD was 609 nm.

A main peak wavelength of the compound GD was 516 nm.

A main peak wavelength of the compound BD was 449 nm.

### EXPLANATION OF CODES

1, 1A, 1B, . . . organic EL display device
10B . . . blue-emitting organic EL device
10G . . . green-emitting organic EL device
10R . . . red-emitting organic EL device
2, 2B, 2G, 2R . . . light reflection layer
3, 3B, 3G, 3R . . . transparent electrode
4, 4B, 4G, 4R . . . hole transporting zone
5 . . . emitting layer
5B . . . blue emitting layer
5G . . . green emitting layer
5R . . . red emitting layer
6, 6B, 6G, 6R . . . electron transporting zone
7, 7B, 7G, 7R . . . semitransmissive electrode
8 . . . substrate

1. An organic EL display device comprising: a blue-emitting organic EL device and a red-emitting organic EL device as pixels, wherein
each of the blue-emitting organic EL device and the red-emitting organic EL device comprises in this order a light reflection layer, a transparent electrode, a hole transporting zone, an emitting layer, an electron transporting zone, and a semitransmissive electrode,
in each of the blue-emitting organic EL device and the red-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the red-emitting organic EL device comprises a red emitting layer as the emitting layer,
the blue emitting layer comprises a fluorescent compound FL_{B} or a phosphorescent compound PL_{B},
the red emitting layer comprises a delayed fluorescent compound DF_{R},
the hole transporting zone is provided at a constant film thickness in a shared manner across the blue-emitting organic EL device and the red-emitting organic EL device,
the red-emitting organic EL device comprises a resonator structure whose order of interference is first-order between the light reflection layer and the semitransmissive electrode,
a film thickness of the red emitting layer is less than 50 nm, and
a sum of a film thickness of the transparent electrode and a film thickness of the hole transporting zone in each of the blue-emitting organic EL device and the red-emitting organic EL device is less than 40 nm.

2. An organic EL display device comprising: a blue-emitting organic EL device and a red-emitting organic EL device as pixels, wherein
each of the blue-emitting organic EL device and the red-emitting organic EL device comprises in this order a light reflection layer, a transparent electrode, a hole transporting zone, an emitting layer, an electron transporting zone, and a semitransmissive electrode,
in each of the blue-emitting organic EL device and the red-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the red-emitting organic EL device comprises a red emitting layer as the emitting layer,
the blue emitting layer comprises a fluorescent compound FL_{B},
the red emitting layer comprises a delayed fluorescent compound DF_{R},
the hole transporting zone is provided at a constant film thickness in a shared manner across the blue-emitting organic EL device and the red-emitting organic EL device,
the red-emitting organic EL device comprises a resonator structure whose order of interference is first-order between the light reflection layer and the semitransmissive electrode,
a film thickness of the red emitting layer is less than 50 nm, and
a sum of a film thickness of the transparent electrode and a film thickness of the hole transporting zone in each of the blue-emitting organic EL device and the red-emitting organic EL device is less than 40 nm.

3. The organic EL display device according to claim 1, wherein
a thickness of the electron transporting zone in the blue-emitting organic EL device is smaller than a thickness of the electron transporting zone in the red-emitting organic EL device.

4. The organic EL display device according to claim 1, wherein
the sum of the film thickness of the transparent electrode and the film thickness of the hole transporting zone in each of the blue-emitting organic EL device and the red-emitting organic EL device is 15 nm or more.

5. An organic EL display device comprising: a blue-emitting organic EL device; a green-emitting organic EL device; and a red-emitting organic EL device as pixels, wherein
each of the blue-emitting organic EL device, the green-emitting organic EL device, and the red-emitting organic EL device comprises in this order a light reflection layer, a transparent electrode, a hole transporting zone, an emitting layer, an electron transporting zone, and a semitransmissive electrode,
in each of the blue-emitting organic EL device, the green-emitting organic EL device, and the red-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the green-emitting organic EL device comprises a green emitting layer as the emitting layer,
the red-emitting organic EL device comprises a red emitting layer as the emitting layer,
the blue emitting layer comprises a fluorescent compound FL_{B} or a phosphorescent compound PL_{B},
the red emitting layer comprises a delayed fluorescent compound DF_{R},
the hole transporting zone is provided at a constant film thickness in a shared manner across the blue-emitting organic EL device, the green-emitting organic EL device, and the red-emitting organic EL device,
the red-emitting organic EL device comprises a resonator structure whose order of interference is first-order between the light reflection layer and the semitransmissive electrode,
a film thickness of the red emitting layer is less than 50 nm, and
a sum of a film thickness of the transparent electrode and a film thickness of the hole transporting zone in each of the blue-emitting organic EL device, the green-emitting organic EL device, and the red-emitting organic EL device is less than 40 nm.

6. An organic EL display device comprising: a blue-emitting organic EL device; a green-emitting organic EL device; and a red-emitting organic EL device as pixels, wherein
each of the blue-emitting organic EL device, the green-emitting organic EL device, and the red-emitting organic EL device comprises in this order a light reflection layer, a transparent electrode, a hole transporting zone, an emitting layer, an electron transporting zone, and a semitransmissive electrode,
in each of the blue-emitting organic EL device, the green-emitting organic EL device, and the red-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the green-emitting organic EL device comprises a green emitting layer as the emitting layer,
the red-emitting organic EL device comprises a red emitting layer as the emitting layer,
the blue emitting layer comprises a fluorescent compound FL_{B},
the red emitting layer comprises a delayed fluorescent compound DF_{R},
the hole transporting zone is provided at a constant film thickness in a shared manner across the blue-emitting organic EL device, the green-emitting organic EL device, and the red-emitting organic EL device,
the red-emitting organic EL device comprises a resonator structure whose order of interference is first-order between the light reflection layer and the semitransmissive electrode,
a film thickness of the red emitting layer is less than 50 nm, and
a sum of a film thickness of the transparent electrode and a film thickness of the hole transporting zone in each of the blue-emitting organic EL device, the green-emitting organic EL device, and the red-emitting organic EL device is less than 40 nm.

7. The organic EL display device according to claim 5, wherein
the green emitting layer comprises a delayed fluorescent compound DF_{G},
the green-emitting organic EL device comprises a resonator structure whose order of interference is first-order between the light reflection layer and the semitransmissive electrode, and
a film thickness of the green emitting layer is less than 40 nm.

8. The organic EL display device according to claim 7, wherein
the green emitting layer comprises a fluorescent compound FL_{G}, and
singlet energy S₁(DF_{G}) of the delayed fluorescent compound DF_{G} and singlet energy S₁(FL_{G}) of the fluorescent compound FLG satisfy a relationship of a numerical formula (Numerical Formula 2A),
S₁(DF_{G})>S₁(FL_{G}) (Numerical Formula 2A).

9. The organic EL display device according to claim 8, wherein
the green emitting layer comprises a compound SH_{G}, and
the singlet energy S₁(DF_{G}) of the delayed fluorescent compound DF_{G} and singlet energy S₁(SH_{G}) of the compound SH_{G} satisfy a relationship of a numerical formula (Numerical Formula 2B),
S₁(SH_{G})>S₁(DF_{G}) (Numerical Formula 2B).

10. The organic EL display device according to claim 5, wherein
a thickness of the electron transporting zone in the blue-emitting organic EL device is smaller than a thickness of the electron transporting zone in the green-emitting organic EL device, and
the thickness of the electron transporting zone in the green-emitting organic EL device is smaller than a thickness of the electron transporting zone in the red-emitting organic EL device.

11. The organic EL display device according to claim 5, wherein
the sum of the film thickness of the transparent electrode and the film thickness of the hole transporting zone in each of the blue-emitting organic EL device, the green-emitting organic EL device, and the red-emitting organic EL device is 15 nm or more.

12. The organic EL display device according to claim 5, wherein
the electron transporting zone in the green organic EL device comprises a plurality of layers.

13. The organic EL display device according to claim 1, wherein
the red emitting layer further comprises a fluorescent compound FL_{R}, and
singlet energy S₁(DF_{R}) of the delayed fluorescent compound DF_{R} and singlet energy S₁(FL_{R}) of the fluorescent compound FL_{R} satisfy a relationship of a numerical formula (Numerical Formula 1A),
S₁(DF_{R})>S₁(FL_{R}) (Numerical Formula 1A).

14. The organic EL display device according to claim 13, wherein
the red emitting layer further comprises a compound SH_{R}, and
the singlet energy S₁(DF_{R}) of the delayed fluorescent compound DF_{R} and singlet energy S₁(SH_{R}) of the compound SH_{R} satisfy a relationship of a numerical formula (Numerical Formula 1B),
S₁(SH_{R})>S₁(DF_{R}) (Numerical Formula 1B).

15. The organic EL display device according to claim 1, wherein
the electron transporting zone in the red organic EL device comprises a plurality of layers.

16. An organic EL display device comprising: a blue-emitting organic EL device and a green-emitting organic EL device as pixels, wherein
each of the blue-emitting organic EL device and the green-emitting organic EL device comprises in this order:
a light reflection layer,
a transparent electrode,
a hole transporting zone,
an emitting layer,
an electron transporting zone, and
a semitransmissive electrode,
in each of the blue-emitting organic EL device and the green-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the green-emitting organic EL device comprises a green emitting layer as the emitting layer,
the blue emitting layer comprises a fluorescent compound FL_{B} or a phosphorescent compound PL_{B},
the green emitting layer comprises a delayed fluorescent compound DF_{G},
the hole transporting zone is provided at a constant film thickness in a shared manner across the blue-emitting organic EL device and the green-emitting organic EL device,
the green-emitting organic EL device comprises a resonator structure whose order of interference is first-order between the light reflection layer and the semitransmissive electrode,
a film thickness of the green emitting layer is less than 40 nm, and
a sum of a film thickness of the transparent electrode and a film thickness of the hole transporting zone in each of the blue-emitting organic EL device and the green-emitting organic EL device is less than 40 nm.

17. An organic EL display device comprising: a blue-emitting organic EL device and a green-emitting organic EL device as pixels, wherein
each of the blue-emitting organic EL device and the green-emitting organic EL device comprises in this order:
a light reflection layer,
a transparent electrode,
a hole transporting zone,
an emitting layer,
an electron transporting zone, and
a semitransmissive electrode,
in each of the blue-emitting organic EL device and the green-emitting organic EL device,
the light reflection layer is in direct contact with the transparent electrode,
the transparent electrode is in direct contact with the hole transporting zone,
the hole transporting zone is in direct contact with the emitting layer,
the emitting layer is in direct contact with the electron transporting zone,
the electron transporting zone is in direct contact with the semitransmissive electrode,
the blue-emitting organic EL device comprises a blue emitting layer as the emitting layer,
the green-emitting organic EL device comprises a green emitting layer as the emitting layer,
the blue emitting layer comprises a fluorescent compound FL_{B},
the green emitting layer comprises a delayed fluorescent compound DF_{G},
the hole transporting zone is provided at a constant film thickness in a shared manner across the blue-emitting organic EL device and the green-emitting organic EL device,
the green-emitting organic EL device comprises a resonator structure whose order of interference is first-order between the light reflection layer and the semitransmissive electrode,
a film thickness of the green emitting layer is less than 40 nm, and
a sum of a film thickness of the transparent electrode and a film thickness of the hole transporting zone in each of the blue-emitting organic EL device and the green-emitting organic EL device is less than 40 nm.

18. The organic EL display device according to claim 16, wherein
the green emitting layer comprises a fluorescent compound FL_{G}, and
singlet energy S₁(DF_{G}) of the delayed fluorescent compound DF_{G} and singlet energy S₁(FL_{G}) of the fluorescent compound FL_{G} satisfy a relationship of a numerical formula (Numerical Formula 2A),
S₁(DF_{G})>S₁(FL_{G}) (Numerical Formula 2A).

19. The organic EL display device according to claim 18, wherein
the green emitting layer comprises a compound SH_{G}, and
the singlet energy S₁(DF_{G}) of the delayed fluorescent compound DF_{G} and singlet energy S₁(SH_{G}) of the compound SH_{G} satisfy a relationship of a numerical formula (Numerical Formula 2B),
S₁(SH_{G})>S₁(DF_{G}) (Numerical Formula 2B).

20. The organic EL display device according to claim 16, wherein
a thickness of the electron transporting zone in the blue-emitting organic EL device is smaller than a thickness of the electron transporting zone in the green-emitting organic EL device.

21. The organic EL display device according to claim 16, wherein
the sum of the film thickness of the transparent electrode and the film thickness of the hole transporting zone in each of the blue-emitting organic EL device and the green-emitting organic EL device is 15 nm or more.

22. The organic EL display device according to claim 16, wherein
the electron transporting zone in the green organic EL device comprises a plurality of layers.

23. The organic EL display device according to claim 1, wherein
the film thickness of the transparent electrode is 15 nm or less.

24. The organic EL display device according to claim 1, wherein
the film thickness of the transparent electrode is 5 nm or more.

25. The organic EL display device according to claim 1, wherein
the film thickness of the hole transporting zone is 10 nm or more and less than 25 nm.

26. The organic EL display device according to claim 1, wherein
the hole transporting zone consists of a single layer.

27. The organic EL display device according to claim 1, wherein
the hole transporting zone comprises a plurality of layers, and
all the plurality of layers in the hole transporting zone comprise the same compound.

28. The organic EL display device according to claim 1, wherein
the electron transporting zone in the blue organic EL device comprises a plurality of layers.

29. An electronic device comprising the organic EL display device according to claim 1.
